(19) United States
(12) Patent Application Publication
(10) Pub. No.: US 2016/0284857 A1
(43) Pub. Date: Sep. 29, 2016

(54) Transistor and Electronic Device

(71) Applicant: Semiconductor Energy Laboratory Co., Ltd., Kanagawa-ken (JP)

(72) Inventors: Shunpei YAMAZAKI, Tokyo (JP); Akihisa SHIMOMURA, Atsugi (JP)

(73) Assignee: Semiconductor Energy Laboratory Co., Ltd., Kanagawa-ken (JP)

(21) Appl. No.: 15/079,549

(22) Filed: Mar. 24, 2016

(30) Foreign Application Priority Data
Mar. 27, 2015 (JP) 2015-066660

(51) Int. Cl. H01L 29/786; H01L 29/04

(52) U.S. Cl. CPC H01L 29/7869; H01L 29/045

(57) ABSTRACT

A semiconductor device with favorable electrical characteristics or a highly reliable semiconductor device is provided. The semiconductor device is a transistor including a first oxide film. The first oxide film contains indium, an element M, and zinc. The first oxide film includes a region in which the atomic ratio of indium to the element M and zinc satisfies indium:element M:zinc=xb:yb:zb For xb:yb:zb, (1−α1):(1+α1):m1 or (1−α2):(1+α2):m2 is satisfied, where α1 is greater than or equal to −0.43 and less than or equal to 0.18, α2 is greater than or equal to −0.78 and less than or equal to 0.42, and m1 and m2 are each greater than 0.7 and less than or equal to 1.

### TECHNICAL FIELD

The present invention relates to an object, a method, or a manufacturing method. The present invention relates to a process, a machine, manufacture, or a composition of matter. In particular, one embodiment of the present invention relates to a semiconductor device, a display device, a light-emitting device, a power storage device, a memory device, a driving method thereof, or a manufacturing method thereof.

In this specification and the like, a semiconductor device generally means a device that can function by utilizing semiconductor characteristics. A transistor and a semiconductor circuit are embodiments of semiconductor devices. An arithmetic device, a memory device, an imaging device, an electro-optical device, a power generation device (including a thin film solar cell, an organic thin film solar cell, and the like), and an electronic device may each include a semiconductor device.

### BACKGROUND ART

Non-Patent Document 1 and Non-Patent Document 2 disclose crystal structures of In₂O₃—Ga₂ZnO₄—ZnO-based compounds. Non-Patent Document 1 discloses a homologous series represented by In₁₋ₓGa₁₊ₓO₃(ZnO)ₘ(−1≦x≦1, and m is a natural number). Furthermore, Non-Patent Document 1 discloses a solid solution range of the homologous series. For example, in the solid solution range of the homologous series in the case where m is 1, x ranges from −0.33 to 0.08, and in the solid solution range of the homologous series in the case where m is 2, x ranges from −0.68 to 0.32.

A compound represented by AB₂O₄(A and B are metal elements) is known as a compound having a spinel crystal structure. In addition, Non-Patent Document 1 discloses an example of InₓZn_{y}Ga_{z}O_{w}, and when x, y, and z are set such that a composition in the neighborhood of ZnGa₂O₄ is obtained, that is, when x, y, and z are close to 0, 1, and 2, respectively, a spinel crystal structure is likely to be formed or mixed.

A technique in which a transistor is formed using a semiconductor material has been attracting attention. The transistor is applied to a wide range of electronic devices, such as an integrated circuit (IC) or an image display device (also simply referred to as a display device). A silicon-based semiconductor material is widely known as a semiconductor material which can be used for a transistor. As another material, an oxide semiconductor has been attracting attention.

For example, a technique for forming a transistor using zinc oxide or an In—Ga—Zn oxide semiconductor as an oxide semiconductor is disclosed (see Patent Documents 1 and 2).

In recent years, demand for integrated circuits in which semiconductor elements such as miniaturized transistors are integrated with high density has risen with an increase in performance and reductions in size and weight of electronic devices.

### REFERENCE

### Patent Document

[Patent Document 1] Japanese Published Patent Application No. 2007-123861
[Patent Document 2] Japanese Published Patent Application No. 2007-096055

### Non-Patent Document

[Non-Patent Document 1]M. Nakamura, N. Kimizuka, and T. Mohri, “The Phase Relations in the In₂O₃—Ga₂ZnO₄—ZnO System at 1350° C.,” J. Solid State Chem., 1991, Vol. 93, pp. 298-315.
[Non-Patent Document 2]N. Kimizuka, M. Isobe, and M. Nakamura, “Syntheses and Single-Crystal Data of Homologous Compounds, In₂O₃(ZnO)ₘ (m=3, 4, and 5), InGaO₃(ZnO)₃, and Ga₂O₃(ZnO)ₘ (m=7, 8, 9, and 16) in the In₂O₃—ZnGa₂O₄—ZnO System,” J. Solid State Chem., 1995, Vol. 116, pp. 170-178.

### DISCLOSURE OF INVENTION

An object of one embodiment of the present invention is to provide a semiconductor device with favorable electrical characteristics. Another object is to provide a highly reliable semiconductor device.

Another object is to provide a favorable transistor with small variation in characteristics. Another object is to provide a semiconductor device including a memory element with favorable retention characteristics. Another object is to provide a semiconductor device that is suitable for miniaturization. Another object is to provide a semiconductor device with a reduced circuit area. Another object is to provide a semiconductor device with a novel structure.

Note that the description of these objects does not disturb the existence of other objects. One embodiment of the present invention need not achieve all the objects. Other objects will be apparent from and can be derived from the description of the specification, the drawings, the claims, and the like.

One embodiment of the present invention is a transistor including a first oxide film. The first oxide film contains indium, an element M, and zinc. The first oxide film includes a region in which the atomic ratio of indium to the element M and zinc satisfies indium:element M:zinc=x_{b}:y_{b}:z_{b}. For x_{b}:y_{b}:z_{b}, (1−α₁):(1+α₂):m₁, (1−α₂):(1+α₂):2m₂, (1−α₃):(1+α₃):3m₃, (1−α₄):(1+α₄):4m₄, or (1−α₅):(1+α₅):5m₅ is satisfied, where α₁ is greater than or equal to −0.43 and less than or equal to 0.18, α₂ is greater than or equal to −0.78 and less than or equal to 0.42, α₃ is greater than or equal to −1 and less than or equal to 0.56, α₄ is greater than or equal to −1 and less than or equal to 0.64, α₅ is greater than or equal to −1 and less than or equal to 0.82, and m₁ to m₅ are each greater than 0.7 and less than or equal to 1.

Another embodiment of the present invention is a transistor including a first oxide film. The first oxide film contains indium, an element M, and zinc. The first oxide film includes a region in which the atomic ratio of indium to the element M and zinc satisfies indium:element M:zinc=x_{b}:y_{b}:z_{b}, where x_{b} is 4, y_{b} is greater than or equal to 1.8 and less than or equal to 2.2, and z_{b} is greater than 2.1 and less than or equal to 3.

Another embodiment of the present invention is a transistor including a first oxide film. The first oxide film contains indium, an element M, and zinc. The first oxide film includes a region in which the atomic ratio of indium to the element M and zinc satisfies indium:element M:zinc=x_{b}:y_{b}:z_{b}, where x_{b} is 5, y_{b} is greater than or equal to 0.9 and less than or equal to 1.1, and z_{b} is greater than 4.2 and less than or equal to 6.

Another embodiment of the present invention is a transistor including a first oxide film. The first oxide film includes a first region and a second region. The first region has c-axis alignment. The c-axis is parallel to a normal vector of a top surface or a formation surface of the first oxide film. The second region does not have the c-axis alignment. The second region contains indium, an element M, and zinc. The second region includes a region in which the atomic ratio of indium to the element M and zinc satisfies indium:element Mzinc=x_{b}:y_{b}:z_{b}. For x_{b}:y_{b}:z_{b}, (1−α₁):(1+α₁):m₁, (1−α₂):(1+α₂):2m₂, (1−α₃):(1+α₃):3m₃, (1−α₄):(1+α₄):4m₄, or (1−α₅):(1+α₅):5m₅ is satisfied, where α₁ is greater than or equal to −0.43 and less than or equal to 0.18, α₂ is greater than or equal to −0.78 and less than or equal to 0.42, α₃ is greater than or equal to −1 and less than or equal to 0.56, α₄ is greater than or equal to −1 and less than or equal to 0.64, α₅ is greater than or equal to −1 and less than or equal to 0.82, and m₁ to m₅ are each greater than 0.7 and less than or equal to 1.

Another embodiment of the present invention is a transistor including a first oxide film. The first oxide film includes a first region and a second region. The first region has c-axis alignment. The c-axis is parallel to a normal vector of a top surface or a formation surface of the first oxide film. The second region does not have the c-axis alignment. The second region contains indium, an element M, and zinc. The second region includes a region in which the atomic ratio of indium to the element M and zinc satisfies indium:element M:zinc=x_{b}:y_{b}:z_{b}, where x_{b} is 4, y_{b} is greater than or equal to 1.8 and less than or equal to 2.2, and z_{b} is greater than 2.1 and less than or equal to 3.

Another embodiment of the present invention is a transistor including a first oxide film. The first oxide film includes a first region and a second region. The first region has c-axis alignment. The second region does not have the c-axis alignment. The second region contains indium, an element M, and zinc. The second region includes a region in which the atomic ratio of indium to the element M and zinc satisfies indium:element M:zinc=x_{b}:y_{b}:z_{b}, where x_{b} is 5, y_{b} is greater than or equal to 0.9 and less than or equal to 1.1, and z_{b} is greater than 4.2 and less than or equal to 6.

Another embodiment of the present invention is a transistor including a first oxide film. The first oxide film is deposited by a sputtering method. A target used in the sputtering method contains indium, an element M, and zinc. The target includes a region in which the atomic ratio of indium to the element M and zinc satisfies indium:element M:zinc=x_{b}:y_{b}:z_{b}, where x_{b} is 5, y_{b} is greater than or equal to 0.9 and less than or equal to 1.1, and z_{b} is greater than 6.3 and less than or equal to 7.7.

In the above structure, the transistor preferably includes a second oxide film. The second oxide film preferably includes a region in contact with the top surface of the first oxide film. The second oxide film preferably contains indium, the element M, and zinc. The second oxide film preferably includes a region in which the atomic ratio of indium to the element M and zinc satisfies indium:element M:zinc=x_{c}:y_{c}:z_{c}, where x_{c} is 1, y_{c} is greater than or equal to 2.7 and less than or equal to 3.3, and z_{c} is greater than or equal to 1 and less than or equal to 3.

In the above structure, the transistor preferably includes a third oxide film. The third oxide film preferably includes a region in contact with a bottom surface of the first oxide film. The third oxide film preferably contains indium, the element M, and zinc. The third oxide film preferably includes a region in which the atomic ratio of indium to the element M and zinc satisfies indium:element M:zinc=xₐ:yₐ:zₐ, where xₐ is 1, yₐ is greater than or equal to 2.7 and less than or equal to 3.3, and zₐ is greater than or equal to 1 and less than or equal to 3.

In the above structure, the element M is preferably at least one element selected from gallium, aluminum, yttrium, and tin.

In the above structure, the element M is preferably gallium.

Another embodiment of the present invention is an electronic device including the above transistor.

According to one embodiment of the present invention, a semiconductor device with favorable electrical characteristics can be provided. Furthermore, a highly reliable semiconductor device can be provided.

A favorable transistor with small variation in characteristics can be provided. A semiconductor device including a memory element with favorable retention characteristics can be provided. A semiconductor device that is suitable for miniaturization can be provided. A semiconductor device with a reduced circuit area can be provided. A semiconductor device with a novel structure can be provided. Note that the description of these effects does not disturb the existence of other effects. One embodiment of the present invention does not necessarily have all the effects. Other effects will be apparent from and can be derived from the description of the specification, the drawings, the claims, and the like.

### BRIEF DESCRIPTION OF DRAWINGS

FIG. 1 illustrates atomic ratios of an oxide of one embodiment of the present invention.

FIG. 2 illustrates atomic ratios of an oxide of one embodiment of the present invention.

FIG. 3 illustrates atomic ratios of an oxide of one embodiment of the present invention.

FIG. 4 illustrates atomic ratios of an oxide of one embodiment of the present invention.

FIGS. 5A and 5B illustrate an atomic ratio.

FIGS. 6A to 6C each illustrate a transistor of one embodiment of the present invention.

FIG. 7 illustrates an energy band structure.

FIGS. 8A to 8D illustrate a transistor of one embodiment of the present invention.

FIGS. 9A to 9F each illustrate a transistor of one embodiment of the present invention.

FIGS. 10A and 10B illustrate a transistor of one embodiment of the present invention.

FIGS. 11A and 11B illustrate a transistor of one embodiment of the present invention.

FIGS. 12A and 12B illustrate a transistor of one embodiment of the present invention.

FIGS. 13A and 13B illustrate a transistor of one embodiment of the present invention.

FIGS. 14A and 14B each illustrate a transistor of one embodiment of the present invention.

FIGS. 15A and 15B illustrate a transistor of one embodiment of the present invention.

FIGS. 16A and 16B illustrate a transistor of one embodiment of the present invention.

FIGS. 17A and 17B illustrate a transistor of one embodiment of the present invention.

FIGS. 18A to 18F illustrate a method for manufacturing a transistor of one embodiment of the present invention.

FIGS. 19A to 19F illustrate a method for manufacturing a transistor of one embodiment of the present invention.

FIG. 20 illustrates a semiconductor device of one embodiment of the present invention.

FIGS. 21A and 21B illustrate structures of a transistor.

FIGS. 22A to 22C are each a circuit diagram of one embodiment of the present invention.

FIGS. 23A to 23C are each a circuit diagram of one embodiment of the present invention.

FIGS. 24A to 24D are Cs-corrected high-resolution TEM images of a cross section of a CAAC-OS and a cross-sectional schematic view of a CAAC-OS.

FIGS. 25A to 25D are Cs-corrected high-resolution TEM images of a plane of a CAAC-OS.

FIGS. 26A to 26C show XRD structural analysis results of a CAAC-OS and a single crystal oxide semiconductor.

FIGS. 27A and 27B show electron diffraction patterns of a CAAC-OS.

FIG. 28 shows a change in crystal part of an In—Ga—Zn oxide induced by electron irradiation.

FIGS. 29A to 29E are each a circuit diagram illustrating a semiconductor device of one embodiment of the present invention.

FIGS. 30A and 30B illustrate an example of an imaging device.

FIG. 31 illustrates an example of an imaging device.

FIGS. 32A and 32B illustrate an example of an imaging device.

FIGS. 33A to 33D illustrate examples of the pixel structure.

FIGS. 34A and 34B illustrate examples of the pixel structure.

FIGS. 35A to 35C are each a circuit diagram illustrating an example of an imaging device.

FIG. 36 is a cross-sectional view illustrating a structural example of an imaging device.

FIG. 37 is a cross-sectional view illustrating a structural example of an imaging device.

FIGS. 38A to 38C are a circuit diagram, a top view, and a cross-sectional view, respectively, which illustrate a semiconductor device of one embodiment of the present invention.

FIGS. 39A and 39B are a circuit diagram and a cross-sectional view, respectively, which illustrate a semiconductor device of one embodiment of the present invention.

FIG. 40 illustrates a configuration example of a CPU of an embodiment.

FIG. 41 is a circuit diagram of a memory element of an embodiment.

FIG. 42 illustrates a configuration example of an RF tag of an embodiment.

FIGS. 43A to 43F illustrate application examples of an RF tag of an embodiment.

FIGS. 44A to 44H illustrate examples of electronic devices.

### BEST MODE FOR CARRYING OUT THE INVENTION

Embodiments of the present invention will be described in detail with reference to the drawings. Note that the present invention is not limited to the following description, and it is easily understood by those skilled in the art that modes and details can be modified in various ways. Furthermore, the present invention is not construed as being limited to the description of the embodiments below. In the structures of the invention described with reference to the drawings, common reference numerals are used for the same portions in different drawings. Note that the same hatch pattern is applied to similar parts, and the similar parts are not especially denoted by reference numerals in some cases. In the case where the description of a component denoted by a different reference numeral is referred to, the description of the thickness, composition, structure, shape, or the like of the component can be used as appropriate.

Note that the size, the thickness of films (layers), or regions in drawings are sometimes exaggerated for clarity.

A voltage usually refers to a potential difference between a given potential and a reference potential (e.g., a ground potential (GND) or a source potential). Thus, a voltage can be referred to as a potential and vice versa. In general, a potential (a voltage) is a relative value determined depending on the difference from a reference potential. Therefore, for example, a “ground potential” is not necessarily 0 V. For example, in some cases, a “ground potential” is the lowest potential in a circuit. In other cases, a “ground potential” is a substantially intermediate potential in a circuit. In these cases, a positive potential and a negative potential are set using the potential as a reference.

Note that the ordinal numbers such as “first” and “second” are used for convenience and do not denote the order of steps or the stacking order of layers. Therefore, for example, the term “first” can be replaced with the term “second” or “third” as appropriate. In addition, the ordinal numbers in this specification and the like do not correspond to the ordinal numbers which specify one embodiment of the present invention in some cases.

Note that an impurity in a semiconductor refers to, for example, elements other than the main components of the semiconductor. For example, an element with a concentration lower than 0.1 atomic % is an impurity. When a semiconductor contains an impurity, the density of states (DOS) may be increased, the carrier mobility may be decreased, or the crystallinity may be decreased, for example. In the case where the semiconductor is an oxide semiconductor, examples of an impurity which changes characteristics of the semiconductor include Group 1 elements, Group 2 elements, Group 13 elements, Group 14 elements, Group 15 elements, and transition metals other than the main components; specific examples are hydrogen (in water), lithium, sodium, silicon, boron, phosphorus, carbon, and nitrogen. In an oxide semiconductor, an oxygen vacancy may be formed by entry of an impurity such as hydrogen. In the case where the semiconductor is silicon, examples of an impurity which changes characteristics of the semiconductor include oxygen, Group 1 elements except hydrogen, Group 2 elements, Group 13 elements, and Group 15 elements.

In this specification, the expression “A has a shape such that an end portion extends beyond an end portion of B” may indicate the case where at least one end portion of A is positioned on an outer side than at least one end portion of B in a top view or a cross-sectional view. Therefore, the expression “A has a shape such that an end portion extends beyond an end portion of B” can also be expressed as “an end portion of A is positioned on an outer side than an end portion of B in a top view,” for example.

In this specification, the term “parallel” indicates that the angle formed between two straight lines is greater than or equal to −10° and less than or equal to 10°, and accordingly also includes the case where the angle is greater than or equal to −5° and less than or equal to 5°. The term “substantially parallel” indicates that the angle formed between two straight lines is greater than or equal to −30° and less than or equal to 30°. The term “perpendicular” indicates that the angle formed between two straight lines is greater than or equal to 80° and less than or equal to 1000, and accordingly also includes the case where the angle is greater than or equal to 85° and less than or equal to 95°. The term “substantially perpendicular” indicates that the angle formed between two straight lines is greater than or equal to 60° and less than or equal to 120°.

In this specification, trigonal and rhombohedral crystal systems are included in a hexagonal crystal system.

In this specification, the term “semiconductor” can be referred to as an “oxide semiconductor.” As the semiconductor, a Group 14 semiconductor such as silicon or germanium, a compound semiconductor such as silicon carbide, germanium silicide, gallium arsenide, indium phosphide, zinc selenide, or cadmium sulfide, or an organic semiconductor can also be used.

In this specification, a device may refer to, for example, a semiconductor device, a display device, a light-emitting device, a lighting device, a power storage device, a mirror image device, a memory device, or an electro-optical device.

### Embodiment 1

### Structure of Oxide Semiconductor Film

The structure of an oxide semiconductor will be described below.

An oxide semiconductor is classified into a single crystal oxide semiconductor and a non-single-crystal oxide semiconductor. Examples of the non-single-crystal oxide semiconductor include a c-axis aligned crystalline oxide semiconductor (CAAC-OS), a polycrystalline oxide semiconductor, a nanocrystalline oxide semiconductor (nc-OS), an amorphous-like oxide semiconductor (a-like OS), and an amorphous oxide semiconductor.

From another perspective, an oxide semiconductor is classified into an amorphous oxide semiconductor and a crystalline oxide semiconductor. Examples of the crystalline oxide semiconductor include a single crystal oxide semiconductor, a CAAC-OS, a polycrystalline oxide semiconductor, and an nc-OS.

It is known that an amorphous structure is generally defined as being metastable and unfixed, and being isotropic and having no non-uniform structure. In other words, an amorphous structure has a flexible bond angle and a short-range order but does not have a long-range order.

This means that an inherently stable oxide semiconductor cannot be regarded as a completely amorphous oxide semiconductor. Moreover, an oxide semiconductor that is not isotropic (e.g., an oxide semiconductor that has a periodic structure in a microscopic region) cannot be regarded as a completely amorphous oxide semiconductor. Although having a periodic structure in a microscopic region, an a-like OS has an unstable structure including a void. For this reason, an a-like OS has physical properties similar to those of an amorphous oxide semiconductor.

### <CAAC-OS>

First, a CAAC-OS will be described.

A CAAC-OS is one of oxide semiconductors and has a plurality of c-axis aligned crystal parts (also referred to as pellets).

In a combined analysis image (also referred to as a high-resolution transmission electron microscope (TEM) image) of a bright-field image and a diffraction pattern of a CAAC-OS, which is obtained using a TEM, a plurality of pellets can be observed. However, in the high-resolution TEM image, a boundary between pellets, that is, a grain boundary is not clearly observed. Thus, in the CAAC-OS, a reduction in electron mobility due to the grain boundary is less likely to occur.

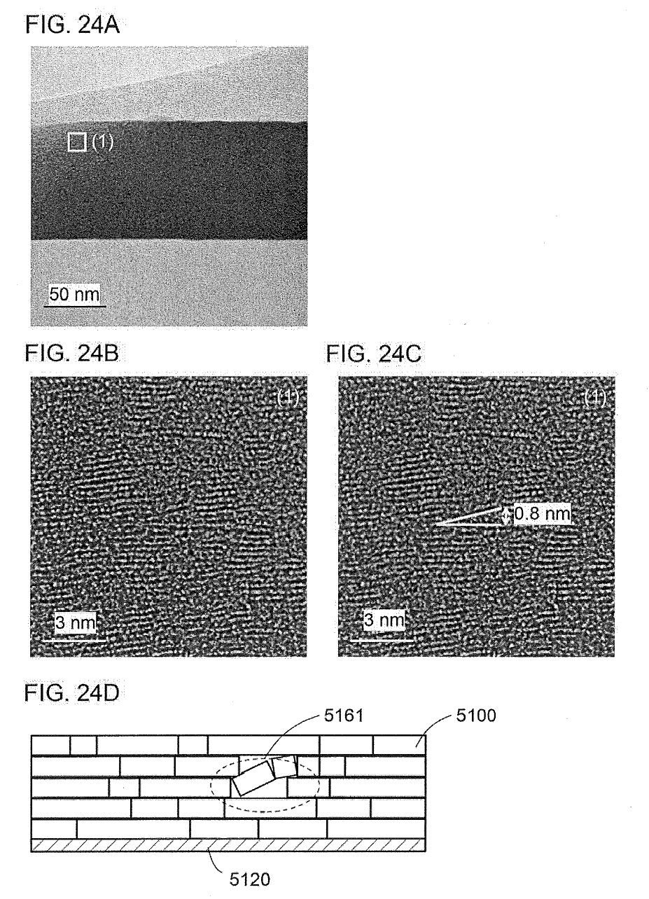

A CAAC-OS observed with a TEM will be described below. FIG. 24A shows a high-resolution TEM image of a cross section of the CAAC-OS which is observed in the direction substantially parallel to the sample surface. The high-resolution TEM image is obtained with a spherical aberration corrector function. The high-resolution TEM image obtained with a spherical aberration corrector function is particularly referred to as a Cs-corrected high-resolution TEM image. The Cs-corrected high-resolution TEM image can be obtained with, for example, an atomic resolution analytical electron microscope JEM-ARM200F manufactured by JEOL Ltd.

FIG. 24B shows an enlarged Cs-corrected high-resolution TEM image of a region (1) in FIG. 24A. FIG. 24B shows that metal atoms are arranged in a layered manner in a pellet. Each metal atom layer has a configuration reflecting unevenness of a surface over which the CAAC-OS is formed (the surface is also referred to as a formation surface) or a top surface of the CAAC-OS, and is arranged parallel to the formation surface or the top surface of the CAAC-OS.

As shown in FIG. 24B, the CAAC-OS has a characteristic atomic arrangement. The characteristic atomic arrangement is denoted by an auxiliary line in FIG. 24C. FIGS. 24B and 24C prove that the size of a pellet is 1 nm or more, or 3 nm or more, and the size of a space caused by tilt of the pellets is approximately 0.8 nm. Therefore, the pellet can also be referred to as a nanocrystal (nc). Furthermore, the CAAC-OS can also be referred to as an oxide semiconductor including c-axis aligned nanocrystals (CANC).

Here, according to the Cs-corrected high-resolution TEM images, the schematic arrangement of pellets 5100 of a CAAC-OS over a substrate 5120 is illustrated by such a structure in which bricks or blocks are stacked (see FIG. 24D). The portion in which the pellets are tilted as observed in FIG. 24C corresponds to a region 5161 in FIG. 24D.

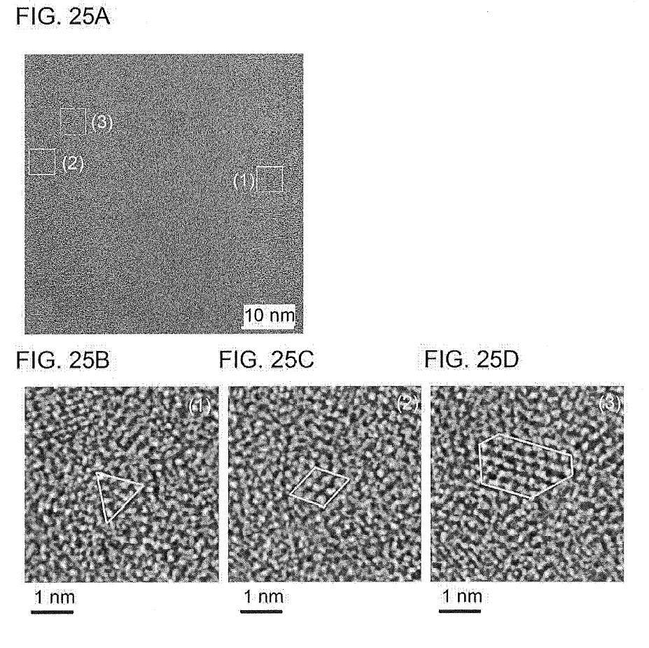

FIG. 25A shows a Cs-corrected high-resolution TEM image of a plane of the CAAC-OS observed in the direction substantially perpendicular to the sample surface. FIGS. 25B, 25C, and 25D are enlarged Cs-corrected high-resolution TEM images of regions (1), (2), and (3) in FIG. 25A, respectively. FIGS. 25B, 25C, and 25D indicate that metal atoms are arranged in a triangular, quadrangular, or hexagonal configuration in a pellet. However, there is no regularity of arrangement of metal atoms between different pellets.

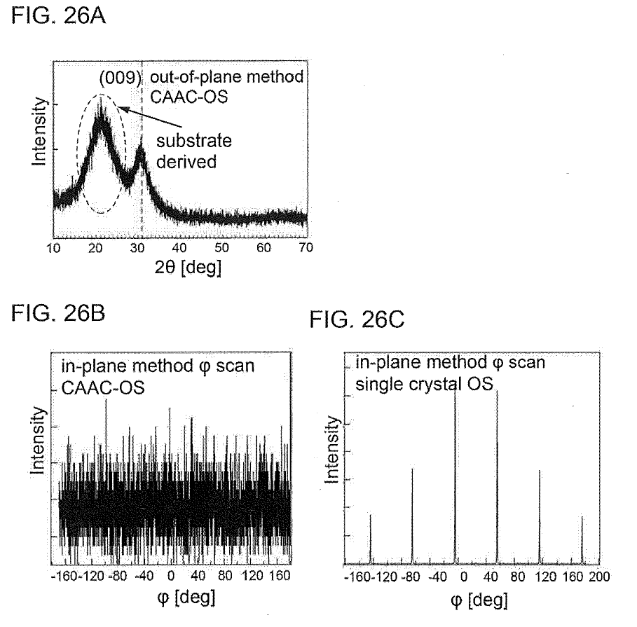

Next, a CAAC-OS analyzed by X-ray diffraction (XRD) will be described. For example, when the structure of a CAAC-OS including an InGaZnO₄ crystal is analyzed by an out-of-plane method, a peak appears at a diffraction angle (2θ) of around 31° as shown in FIG. 26A. This peak is derived from the (009) plane of the InGaZnO₄ crystal, which indicates that crystals in the CAAC-OS have c-axis alignment and that the c-axes are aligned in the direction substantially perpendicular to the formation surface or the top surface of the CAAC-OS.

In structural analysis of the CAAC-OS by an out-of-plane method, another peak may appear when 2θ is around 36°, in addition to the peak at 2θ of around 31°. The peak at 2θ of around 36° indicates that a crystal having no c-axis alignment is included in part of the CAAC-OS. In a preferable CAAC-OS whose structure is analyzed by an out-of-plane method, a peak appears when 2θ is around 31° and no peak appears when 2θ is around 36°.

On the other hand, in structural analysis of the CAAC-OS by an in-plane method in which an X-ray is incident on a sample in the direction substantially perpendicular to the c-axis, a peak appears when 2θ is around 56°. This peak is derived from the (110) plane of the InGaZnO₄ crystal. When the CAAC-OS is subjected to an analysis (q scan) with 2θ fixed at around 56° and with the sample rotated using a normal vector of the sample surface as an axis (φ axis), as shown in FIG. 26B, a peak is not clearly observed. In contrast, when a single crystal oxide semiconductor of InGaZnO₄ is subjected to the φ scan with 2θ fixed at around 56°, as shown in FIG. 26C, six peaks which are derived from crystal planes equivalent to the (110) plane are observed. Accordingly, the structural analysis using XRD shows that the directions of the a-axes and b-axes are irregularly oriented in the CAAC-OS.

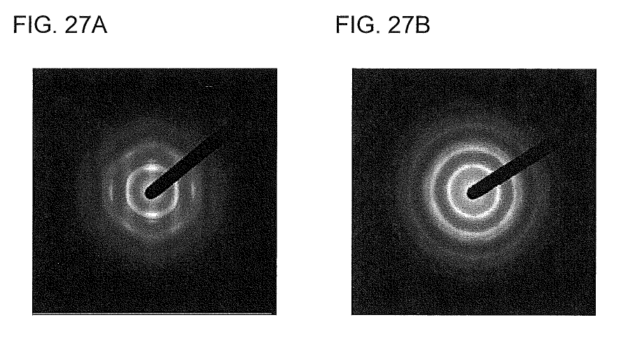

Next, a CAAC-OS analyzed by electron diffraction will be described. For example, when an electron beam with a probe diameter of 300 nm is incident on a CAAC-OS including an InGaZnO₄ crystal in the direction parallel to the sample surface, a diffraction pattern (also referred to as a selected-area transmission electron diffraction pattern) shown in FIG. 27A can be obtained. This diffraction pattern includes spots derived from the (009) plane of an InGaZnO₄ crystal. Thus, the results of electron diffraction also indicate that pellets included in the CAAC-OS have c-axis alignment and that the c-axes are aligned in the direction substantially perpendicular to the formation surface or the top surface of the CAAC-OS. Meanwhile, FIG. 27B shows a diffraction pattern obtained in such a manner that an electron beam with a probe diameter of 300 nm is incident on the same sample in the direction perpendicular to the sample surface. In FIG. 27B, a ring-like diffraction pattern is observed. Thus, the results of electron diffraction also indicate that the a-axes and b-axes of the pellets included in the CAAC-OS do not have regular alignment. The first ring in FIG. 27B is considered to be derived from the (010) plane, the (100) plane, and the like of the InGaZnO₄ crystal. The second ring in FIG. 27B is considered to be derived from the (110) plane and the like.

As described above, the CAAC-OS is an oxide semiconductor with high crystallinity. Entry of impurities, formation of defects, or the like might decrease the crystallinity of an oxide semiconductor. This means that the CAAC-OS has negligible amounts of impurities and defects (e.g., oxygen vacancies).

Note that the impurity means an element other than the main components of the oxide semiconductor, such as hydrogen, carbon, silicon, or a transition metal element. For example, an element (e.g., silicon) having stronger bonding force to oxygen than a metal element included in an oxide semiconductor extracts oxygen from the oxide semiconductor, which results in disorder of the atomic arrangement and reduced crystallinity of the oxide semiconductor. A heavy metal such as iron or nickel, argon, carbon dioxide, or the like has a large atomic radius (or molecular radius), and thus disturbs the atomic arrangement of the oxide semiconductor and decreases crystallinity.

The characteristics of an oxide semiconductor having impurities or defects might be changed by light, heat, or the like. Impurities contained in the oxide semiconductor might serve as carrier traps or carrier generation sources, for example. Furthermore, oxygen vacancies in the oxide semiconductor serve as carrier traps or carrier generation sources when hydrogen is captured therein.

The CAAC-OS having few impurities and oxygen vacancies is an oxide semiconductor with low carrier density (specifically, lower than 8×10¹/cm³, preferably lower than 1×10¹¹/cm³, further preferably lower than 1×10¹⁰/cm³, and is higher than or equal to 1×10⁻⁹/cm³). Such an oxide semiconductor is referred to as a highly purified intrinsic or substantially highly purified intrinsic oxide semiconductor. CAAC-OS has a low impurity concentration and a low density of defect states. Thus, the CAAC-OS can be referred to as an oxide semiconductor having stable characteristics.

<nc-OS>

Next, an nc-OS will be described.

A high-resolution TEM image of an nc-OS has a region in which a crystal part is observed and a region in which a crystal part is not clearly observed. In most cases, the size of a crystal part included in the nc-OS is greater than or equal to 1 nm and less than or equal to 10 nm, or greater than or equal to 1 nm and less than or equal to 3 nm. An oxide semiconductor including a crystal part whose size is greater than 10 nm and less than or equal to 100 nm may be referred to as a microcrystalline oxide semiconductor. In a high-resolution TEM image of the nc-OS, for example, a grain boundary is not clearly observed in some cases. Note that there is a possibility that the origin of the nanocrystal is the same as that of a pellet in a CAAC-OS. Therefore, a crystal part of the nc-OS may be referred to as a pellet in the following description.

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. There is no regularity of crystal orientation between different pellets in the nc-OS. Thus, the orientation of the whole film is not observed. Accordingly, the nc-OS cannot be distinguished from an a-like OS or an amorphous oxide semiconductor, depending on the analysis method. For example, when the nc-OS is analyzed by an out-of-plane method using an X-ray beam having a diameter larger than the size of a pellet, a peak indicating a crystal plane does not appear. Furthermore, a diffraction pattern like a halo pattern is observed when the nc-OS is subjected to electron diffraction using an electron beam with a probe diameter (e.g., 50 nm or more) that is larger than the size of a pellet. Meanwhile, spots are observed in a nanobeam electron diffraction pattern of the nc-OS when an electron beam having a probe diameter close to or smaller than the size of a pellet is used. Moreover, in a nanobeam electron diffraction pattern of the nc-OS, regions with high luminance in a circular (ring) pattern are observed in some cases. In some cases, a plurality of spots is also observed in a ring-like region.

Since there is no regularity of crystal orientation between the pellets (nanocrystals) as mentioned above, the nc-OS can also be referred to as an oxide semiconductor including random aligned nanocrystals (RANC) or an oxide semiconductor including non-aligned nanocrystals (NANC).

The nc-OS is an oxide semiconductor that has higher regularity than an amorphous oxide semiconductor. Therefore, the nc-OS has a lower density of defect states than the a-like OS and the amorphous oxide semiconductor. Note that there is no regularity of crystal orientation between different pellets in the nc-OS. Therefore, the nc-OS has a higher density of defect states than the CAAC-OS.

<a-like OS>

An a-like OS has a structure between the structure of an nc-OS and the structure of an amorphous oxide semiconductor.

In a high-resolution TEM image of the a-like OS, a void may be observed. Furthermore, the high-resolution TEM image has a region in which a crystal part is clearly observed and a region in which a crystal part is not observed.

The a-like OS has an unstable structure because it includes a void. To verify that an a-like OS has an unstable structure as compared with a CAAC-OS and an nc-OS, a change in structure by electron irradiation will be described below.

An a-like OS (sample A), an nc-OS (sample B), and a CAAC-OS (sample C) are prepared as samples subjected to electron irradiation. Each sample is an In—Ga—Zn oxide.

First, a high-resolution cross-sectional TEM image of each sample is obtained. The high-resolution cross-sectional TEM images show that all the samples have crystal parts.

Note that which part is regarded as a crystal part is determined as follows. It is known that a unit cell of the InGaZnO₄ crystal has a structure in which nine layers consisting of three In—O layers and six Ga—Zn—O layers are stacked in the c-axis direction. The distance between the adjacent layers is equivalent to the lattice spacing on the (009) plane (also referred to as d value). The value is calculated to be 0.29 nm from crystal structural analysis. Accordingly, a portion in which the spacing between lattice fringes is greater than or equal to 0.28 nm and less than or equal to 0.30 nm can be regarded as a crystal part of InGaZnO₄. Each lattice fringe corresponds to the a-b plane of the InGaZnO₄ crystal.

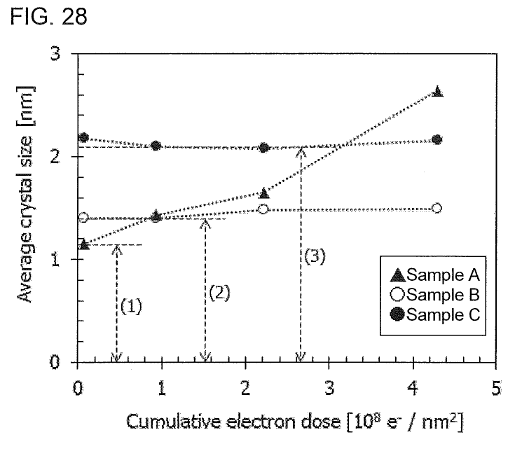

FIG. 28 shows a change in the average size of crystal parts (at 22 points to 45 points) in each sample. Note that the crystal part size corresponds to the length of a lattice fringe. FIG. 28 indicates that the crystal part size in the a-like OS increases with an increase in cumulative electron dose. Specifically, as shown by (1) in FIG. 28, a crystal part of approximately 1.2 nm (also referred to as an initial nucleus) at the start of TEM observation grows to a size of approximately 2.6 nm at a cumulative electron dose of 4.2×10⁸ e⁻/nm². In contrast, the crystal part size in the nc-OS and the CAAC-OS shows little change from the start of electron irradiation to a cumulative electron dose of 4.2×10⁸ e⁻/nm². Specifically, as shown by (2) and (3) in FIG. 28, the average crystal sizes in the nc-OS and the CAAC-OS are approximately 1.4 nm and approximately 2.1 nm, respectively, regardless of the cumulative electron dose.

In this manner, growth of the crystal part in the a-like OS may be induced by electron irradiation. In contrast, in the nc-OS and the CAAC-OS, growth of the crystal part is hardly induced by electron irradiation. That is, the a-like OS has an unstable structure as compared with the nc-OS and the CAAC-OS.

The a-like OS has a lower density than the nc-OS and the CAAC-OS because it includes a void. Specifically, the density of the a-like OS is higher than or equal to 78.6% and lower than 92.3% of the density of the single crystal oxide semiconductor having the same composition. The density of each of the nc-OS and the CAAC-OS is higher than or equal to 92.3% and lower than 100% of the density of the single crystal oxide semiconductor having the same composition. It is difficult to deposit an oxide semiconductor having a density lower than 78% of the density of the single crystal oxide semiconductor.

For example, in the case of an oxide semiconductor having an atomic ratio of In:Ga:Zn=1:1:1, the density of single crystal InGaZnO₄ with a rhombohedral crystal structure is 6.357 g/cm³. Accordingly, in the case of the oxide semiconductor having an atomic ratio of In:Ga:Zn=1:1:1, the density of the a-like OS is higher than or equal to 5.0 g/cm³ and lower than 5.9 g/cm³. For example, in the case of the oxide semiconductor having an atomic ratio of In:Ga:Zn=1:1:1, the density of each of the nc-OS and the CAAC-OS is higher than or equal to 5.9 g/cm³ and lower than 6.3 g/cm³.

Note that there is a possibility that an oxide semiconductor having a certain composition cannot exist in a single crystal state. In this case, single crystal oxide semiconductors with different compositions are combined at an adequate ratio, which makes it possible to calculate the density equivalent to that of a single crystal oxide semiconductor with the desired composition. The density of a single crystal oxide semiconductor having the desired composition can be calculated using a weighted average with respect to the combination ratio of the single crystal oxide semiconductors with different compositions. Note that it is preferable to use as few kinds of single crystal oxide semiconductors as possible to calculate the density.

As described above, oxide semiconductors have various structures and various properties. Note that an oxide semiconductor may be a stacked film including two or more of an amorphous oxide semiconductor, an a-like OS, an nc-OS, and a CAAC-OS, for example.

Moreover, defect states which exist in an oxide semiconductor film and at the interface between the oxide semiconductor film and the outside can cause deterioration of a transistor including the oxide semiconductor film. Therefore, to obtain stable electrical characteristics of the transistor including the oxide semiconductor film, it is important to reduce the number or density of defect states (DOS) in the oxide semiconductor film and in the vicinity of the interface of the oxide semiconductor film.

Note that defect states include shallow-level defect states (also referred to shallow-level DOS or sDOS) and deep-level defect states (also referred to deep-level DOS or dDOS). Here, the shallow-level defect states exist in the vicinity of the energy of the conduction band minimum. “In the vicinity of the energy of the conduction band minimum” refers to a state in which a difference from the energy of the conduction band minimum is, for example, 200 eV or less, preferably 50 meV or less. In the case where the density of defect states shows a wide distribution, for example, “in the vicinity of the energy of the conduction band minimum” refers to a state in which a difference between the peak level of the density of defect states and the energy of the conduction band minimum is 200 eV or less, preferably 50 meV or less.

By reducing sDOS in the oxide semiconductor film and at the interface between the oxide semiconductor film and the outside, the field-effect mobility (also simply referred as mobility or μFE) of the transistor including the oxide semiconductor film can be increased. Furthermore, a change in electrical characteristics of the transistor including the oxide semiconductor film can be reduced.

At least one of impurities (typically hydrogen or moisture), oxygen vacancies, and the density of defect states (sDOS or dDOS) in the oxide semiconductor film is/are preferably reduced. To reduce impurities, oxygen vacancies, or the density of defect states in the oxide semiconductor film, the crystallinity of the oxide semiconductor film is preferably increased.

### [Transistor 490]

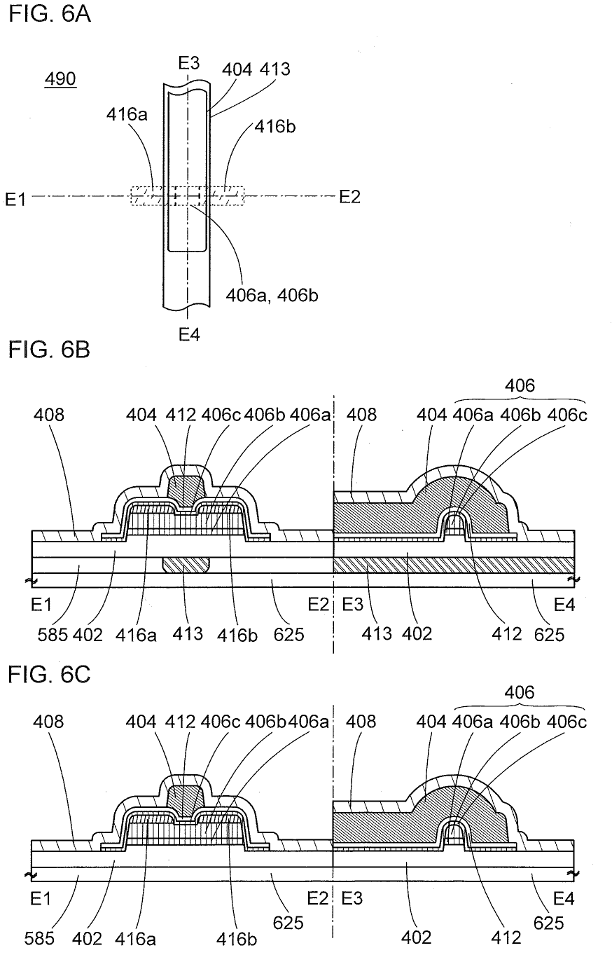

FIGS. 6A to 6C each illustrate an example of a transistor of one embodiment of the present invention. FIG. 6B shows cross-sectional views of a transistor 490 taken along dashed-dotted line E1-E2 and dashed-dotted line E3-E4 in FIG. 6A.

In FIG. 6B, the transistor 490 is formed over a layer 625. The layer 625 may be a substrate or a substrate over which an insulator or a conductor is formed. For the layer 625, refer to the description of a substrate 400 described later.

In the transistor 490 in FIGS. 6A and 6B, an oxide 406 includes three layers: an oxide 406a, an oxide 406b, and an oxide 406c. The transistor 490 includes an insulator 402, the oxide 406a over the insulator 402, the oxide 406b over the oxide 406a, a conductor 416a and a conductor 416b over the oxide 406b, the oxide 406c in contact with a top surface and side surfaces of the oxide 406b, a top surface of the conductor 416a, and a top surface of the conductor 416b, an insulator 412 over the oxide 406c, and an insulator 408 over the insulator 412. In addition, a conductor 404 is preferably formed over a region between the conductor 416a and the conductor 416b (a region which is over the oxide 406 and in which the conductor 416a and the conductor 416b are not formed) with the insulator 412 positioned between the conductor 404 and the region. The transistor 490 in FIGS. 6A and 6B further includes a conductor 413.

The conductor 416a and the conductor 416b preferably function as a source electrode and a drain electrode of the transistor 490. The conductor 404 preferably functions as a gate electrode of the transistor 490. The conductor 413 may also function as a gate electrode of the transistor 490.

For example, the conductor 404 may function as a first gate electrode, and the conductor 413 may function as a second gate electrode. The conductor 404 is not necessarily electrically connected to the conductor 413. Alternatively, for example, the conductor 404 may be electrically connected to the conductor 413. In such a structure, the conductor 404 and the conductor 413 are supplied with the same potential; thus, switching characteristics of the transistor can be improved.

As illustrated in FIG. 6C, the transistor 490 does not necessarily include the conductor 413.

As the oxide 406, for example, an oxide semiconductor containing indium (In) is preferably used. For example, an oxide semiconductor containing indium can have a high carrier mobility (electron mobility). The oxide semiconductor preferably contains an element M.

The element M is preferably aluminum, gallium, yttrium, tin, or the like. Alternatively, the element M can be boron, silicon, titanium, iron, nickel, germanium, zirconium, molybdenum, lanthanum, cerium, neodymium, hafnium, tantalum, tungsten, magnesium, or the like. Note that two or more of the above elements may be used in combination as the element M. The element M is an element having a high bonding energy with oxygen, for example. The element M increases the energy gap of the oxide semiconductor, for example. Furthermore, the oxide semiconductor preferably contains zinc. An oxide semiconductor containing zinc is easily crystallized in some cases.

Note that the oxide 406 is not limited to the oxide containing indium. The oxide 406 may be an oxide which does not contain indium and contains zinc, gallium, and/or tin, such as zinc tin oxide, gallium tin oxide, or gallium oxide.

As the oxide 406, for example, an oxide semiconductor with a wide energy gap is used. For example, the energy gap of the oxide semiconductor used as the oxide 406 is greater than or equal to 2.5 eV and less than or equal to 4.2 eV, preferably greater than or equal to 2.8 eV and less than or equal to 3.8 eV, further preferably greater than or equal to 3 eV and less than or equal to 3.5 eV.

The oxide semiconductor may be deposited by a sputtering method, a chemical vapor deposition (CVD) method (including, but not limited to, a metal organic chemical vapor deposition (MOCVD) method, an atomic layer deposition (ALD) method, a thermal CVD method, or a plasma enhanced chemical vapor deposition (PECVD) method), a molecular beam epitaxy (MBE) method, or a pulsed laser deposition (PLD) method. By a PECVD method, a high-quality film can be formed at a relatively low temperature. By a deposition method that does not use plasma for deposition, such as an MOCVD method, an ALD method, or a thermal CVD method, a film with few defects can be obtained because damage is not easily caused on a surface on which the film is deposited.

Unlike in a deposition method in which particles released from a target or the like are deposited, in a CVD method and an ALD method, a film is formed by reaction at a surface of an object. Thus, a CVD method and an ALD method enable favorable step coverage almost regardless of the shape of an object. In particular, an ALD method enables excellent step coverage and excellent thickness uniformity and can be favorably used for covering a surface of an opening with a high aspect ratio, for example. On the other hand, an ALD method has a relatively low deposition rate; thus, it is sometimes preferable to combine an ALD method with another deposition method with a high deposition rate, such as a CVD method.

When a CVD method or an ALD method is used, the composition of a film to be formed can be controlled with the flow rate ratio of a source gas. For example, by adjusting the flow rate ratio of a source gas in a CVD method or an ALD method, a film with a certain composition can be formed. Moreover, by changing the flow rate ratio of a source gas during deposition by a CVD method or an ALD method, a film whose composition is continuously changed can be formed. In the case where a film is deposited while the flow rate ratio of a source gas is changed, the time for deposition can be shorter than in the case where a film is deposited using a plurality of deposition chambers because time for transfer and pressure adjustment can be saved. Thus, transistors and semiconductor devices can be manufactured with improved productivity in some cases.

For example, in the case where an InGaZnO_{X} (X>0) film is deposited by a thermal CVD method as the oxide 406, trimethylindium (In(CH₃)₃), trimethylgallium (Ga(CH₃)₃), and dimethylzinc (Zn(CH₃)₂) are used. Without limitation to the above combination, triethylgallium (Ga(C₂H₅)₃) can be used instead of trimethylgallium, and diethylzinc (Zn(C₂H₅)₂) can be used instead of dimethylzinc.

For example, in the case where an InGaZnO_{X} (X>0) film is deposited by an ALD method as the oxide 406, an In(CH₃)₃ gas and an O₃ gas are sequentially introduced plural times to form an InO₂ layer, a Ga(CH₃)₃ gas and an O₃ gas are sequentially introduced plural times to form a GaO layer, and then, a Zn(CH₃)₂ gas and an O₃ gas are sequentially introduced plural times to form a ZnO layer. Note that the order of these layers is not limited to this example. A mixed compound layer such as an InGaO₂ layer, an InZnO₂ layer, a GaInO layer, a ZnInO layer, or a GaZnO layer may be formed using these gases. Although an H₂O gas which is bubbled with an inert gas such as Ar may be used instead of an O₃ gas, it is preferable to use an O₃ gas, which does not contain H. Furthermore, instead of an In(CH₃)₃ gas, an In(C₂H₅)₃ gas or tris(acetylacetonato)indium may be used. Note that tris(acetylacetonato)indium is also referred to as In(acac)₃. In addition, instead of a Ga(CH₃)₃ gas, a Ga(C₂H₅)₃ gas or tris(acetylacetonato)gallium may be used. Note that tris(acetylacetonato)gallium is also referred to as Ga(acac)₃. A Zn(CH₃)₂ gas or zinc acetate may also be used. The deposition gas is not limited thereto.

In the case where the oxide semiconductor is deposited by a sputtering method, a target containing indium is preferably used in order to reduce the number of particles. In the case where an oxide target having a high proportion of atoms of the element M is used, the conductivity of the target may be decreased. In the case where a target containing indium is used, the conductivity of the target can be increased and DC discharge or AC discharge is facilitated; thus, deposition over a large substrate can be easily performed. Thus, semiconductor devices can be manufactured with improved productivity.

In the case where the oxide semiconductor is deposited by a sputtering method, the atomic ratio of In to M and Zn in the target may be 3:1:1, 3:1:2, 3:1:4, 1:1:0.5, 1:1:1, 1:1:2, 1:4:4, 4:2:4.1, or the like.

When an oxide semiconductor is deposited by a sputtering method, an oxide semiconductor having an atomic ratio different from that of a target used may be deposited. In particular, the proportion of zinc atoms in the deposited oxide semiconductor may be lower than that in the target. Specifically, the proportion of zinc is approximately 40 atomic % to 90 atomic % of that in the target in some cases.

The oxide 406a and the oxide 406c are preferably formed using a material containing one or more kinds of metal elements other than oxygen contained in the oxide 406b. By using such a material, interface states are less likely to be generated at the interface between the oxide 406a and the oxide 406b and the interface between the oxide 406c and the oxide 406b. Accordingly, carriers are not easily scattered or captured at the interfaces, which results in an improvement in field-effect mobility of the transistor. Furthermore, variation in threshold voltage of the transistor can be reduced. Thus, a semiconductor device having favorable electrical characteristics can be obtained.

The thickness of each of the oxides 406a and 406c is greater than or equal to 3 nm and less than or equal to 100 nm, preferably greater than or equal to 3 nm and less than or equal to 50 nm. The thickness of the oxide 406b is greater than or equal to 3 nm and less than or equal to 200 nm, preferably greater than or equal to 3 nm and less than or equal to 100 nm, further preferably greater than or equal to 3 nm and less than or equal to 50 nm.

As the oxide 406b, an oxide having a higher electron affinity than the oxide 406a and the oxide 406c is used. For example, as the oxide 406b, an oxide having a higher electron affinity than the oxide 406a and the oxide 406c by 0.07 eV or more and 1.3 eV or less, preferably 0.1 eV or more and 0.7 eV or less, further preferably 0.15 eV or more and 0.4 eV or less is used. Note that the electron affinity refers to an energy difference between the vacuum level and the bottom of the conduction band.

The oxide 406a and the oxide 406c, whose electron affinity is lower than the oxide 406b, have properties close to an insulator as compared with the oxide 406b, for example. Therefore, when gate voltage is applied, a channel is likely to be formed in the oxide 406b among the oxides 406a, 406b, and 406c.

To obtain stable electrical characteristics of a transistor including an oxide semiconductor in a semiconductor layer in which a channel is formed (also referred to as an OS transistor), the oxide 406b is preferably highly purified by reducing impurities and oxygen vacancies in the oxide semiconductor so as to be regarded as an intrinsic or substantially intrinsic oxide semiconductor. For example, oxygen vacancies can be reduced in some cases by supplying excess oxygen to the oxide 406b. Furthermore, it is preferable that at least the channel formation region in the oxide 406b be regarded as an intrinsic or substantially intrinsic oxide semiconductor.

At least as the oxide 406b in the oxide 406, a c-axis aligned crystalline oxide semiconductor (CAAC-OS) is preferably used.

### <Energy Band Structure of Oxide Semiconductor Film>

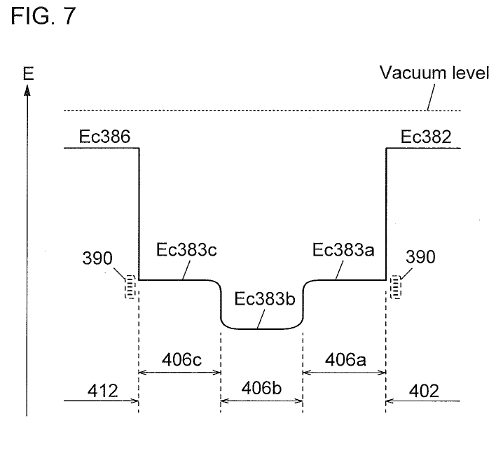

Functions and effects of the oxide 406 in which the oxide 406a, the oxide 406b, and the oxide 406c are stacked will be described using the energy band structure diagram in FIG. 7. FIG. 7 illustrates the energy band structure of the channel formation region of the transistor 490.

In FIG. 7, Ec382, Ec383a, Ec383b, Ec383c, and Ec386 denote the energy of the conduction band minimum of the insulator 402, the oxide 406a, the oxide 406b, the oxide 406c, and the insulator 412, respectively.

Here, an electron affinity corresponds to a value obtained by subtracting an energy gap from an energy difference between the vacuum level and the valence band maximum (the difference is also referred to as ionization potential). Note that the energy gap can be measured using a spectroscopic ellipsometer (UT-300 manufactured by HORIBA JOBIN YVON S.A.S.). The energy difference between the vacuum level and the valence band maximum can be measured using an ultraviolet photoelectron spectroscopy (UPS) device (VersaProbe manufactured by ULVAC-PHI, Inc.).

Note that an In—Ga—Zn oxide which is formed using a target having an atomic ratio of In:Ga:Zn=1:3:2 has an energy gap of approximately 3.5 eV and an electron affinity of approximately 4.5 eV. An In—Ga—Zn oxide which is formed using a target having an atomic ratio of In:Ga:Zn=1:3:4 has an energy gap of approximately 3.4 eV and an electron affinity of approximately 4.5 eV. An In—Ga—Zn oxide which is formed using a target having an atomic ratio of In:Ga:Zn=1:3:6 has an energy gap of approximately 3.3 eV and an electron affinity of approximately 4.5 eV. An In—Ga—Zn oxide which is formed using a target having an atomic ratio of In:Ga:Zn=1:6:2 has an energy gap of approximately 3.9 eV and an electron affinity of approximately 4.3 eV. An In—Ga—Zn oxide which is formed using a target having an atomic ratio of In:Ga:Zn=1:6:8 has an energy gap of approximately 3.5 eV and an electron affinity of approximately 4.4 eV. An In—Ga—Zn oxide which is formed using a target having an atomic ratio of In:Ga:Zn=1:6:10 has an energy gap of approximately 3.5 eV and an electron affinity of approximately 4.5 eV. An In—Ga—Zn oxide which is formed using a target having an atomic ratio of In:Ga:Zn=1:1:1 has an energy gap of approximately 3.2 eV and an electron affinity of approximately 4.7 eV. An In—Ga—Zn oxide which is formed using a target having an atomic ratio of In:Ga:Zn=3:1:2 has an energy gap of approximately 2.8 eV and an electron affinity of approximately 5.0 eV.

Since the insulator 402 and the insulator 412 are insulators, Ec382 and Ec386 are closer to the vacuum level (have a lower electron affinity) than Ec383a, Ec383b, and Ec383c.

Furthermore, Ec383a is closer to the vacuum level than Ec383b. Specifically, Ec383a is preferably closer to the vacuum level than Ec383b by 0.07 eV or more and 1.3 eV or less, further preferably 0.1 eV or more and 0.7 eV or less, still further preferably 0.15 eV or more and 0.4 eV or less.

Furthermore, Ec383c is closer to the vacuum level than Ec383b. Specifically, Ec383c is preferably closer to the vacuum level than Ec383b by 0.07 eV or more and 1.3 eV or less, further preferably 0.1 eV or more and 0.7 eV or less, still further preferably 0.15 eV or more and 0.4 eV or less.

In some cases, there is a mixed region of the oxide 406a and the oxide 406b between the oxide 406a and the oxide 406b. In some cases, there is a mixed region of the oxide 406b and the oxide 406c between the oxide 406b and the oxide 406c. The mixed region has a low interface state density. For that reason, the stack including the oxide 406a, the oxide 406b, and the oxide 406c has a band structure in which energy at each interface and in the vicinity of the interface is changed continuously (continuous junction).

In this case, electrons move mainly in the oxide 406b, not in the oxide 406a and the oxide 406c. Thus, when the interface state density at the interface between the oxide 406a and the oxide 406b and the interface state density at the interface between the oxide 406b and the oxide 406c are reduced, electron movement in the oxide 406b is less likely to be inhibited and the on-sate current of the transistor 490 can be increased.

Although trap states 390 due to impurities or defects might be formed in the vicinity of the interface between the oxide 406a and the insulator 402 and the interface between the oxide 406c and the insulator 412, the oxide 406b can be separated from the trap states owing to the existence of the oxide 406a and the oxide 406c.

In the transistor 490 in FIG. 6B and the like, the oxide 406b can be electrically surrounded by an electric field of the conductor 404. Therefore, a channel is formed in the entire oxide 406b (bulk) in some cases.

The oxide 406b is preferably an oxide semiconductor. A structure in which a semiconductor is electrically surrounded by an electric field of a conductor is referred to as a surrounded channel (s-channel) structure. In the s-channel structure, a large amount of current can flow between a source and a drain of a transistor, so that high on-state current can be obtained.

The s-channel structure is suitable for a miniaturized transistor because high on-state current can be obtained. A device including a miniaturized transistor can have a high integration degree and high density. For example, the channel length of the transistor is preferably less than or equal to 40 nm, further preferably less than or equal to 30 nm, still further preferably less than or equal to 20 nm, and the channel width of the transistor is preferably less than or equal to 40 nm, further preferably less than or equal to 30 nm, still further preferably less than or equal to 20 nm.

In the case where the transistor 490 has an s-channel structure, a channel is formed in the entire oxide 406b. Therefore, as the oxide 406b has a larger thickness, the channel region becomes larger. In other words, the thicker the oxide 406b is, the higher the on-state current of the transistor 490 is. For example, the oxide 406b may have a region with a thickness of 20 nm or more, preferably 40 nm or more, further preferably 60 nm or more, still further preferably 100 nm or more. To prevent a decrease in the productivity of the semiconductor device including the transistor 490, the oxide 406b may have a region with a thickness of 300 nm or less, preferably 200 nm or less, further preferably 150 nm or less, for example.

Moreover, the thickness of the oxide 406c is preferably as small as possible to increase the on-state current of the transistor 490. For example, the oxide 406c may have a region with a thickness less than 10 nm, preferably less than or equal to 5 nm, further preferably less than or equal to 3 nm. Meanwhile, the oxide 406c has a function of preventing elements other than oxygen (e.g., hydrogen and silicon) contained in the adjacent insulator from entering the oxide 406b in which a channel is formed. Therefore, the oxide 406c preferably has a certain thickness. For example, the oxide 406c may have a region with a thickness of 0.3 nm or more, preferably 1 nm or more, further preferably 2 nm or more.

To improve reliability, preferably, the thickness of the oxide 406a is large and the thickness of the oxide 406c is small. For example, the oxide 406a may have a region with a thickness of 10 nm or more, preferably 20 nm or more, further preferably 40 nm or more, still further preferably 60 nm or more. An increase in thickness of the oxide 406a can increase the distance from the oxide 406b in which a channel is formed to the interface between the adjacent insulator and the oxide 406a. To prevent a decrease in the productivity of the semiconductor device including the transistor 490, the oxide 406a may have a region with a thickness of 200 nm or less, preferably 120 nm or less, further preferably 80 nm or less, for example.

Note that silicon in the oxide semiconductor might serve as a carrier trap or a carrier generation source. Therefore, the silicon concentration in the oxide 406b is preferably as low as possible. For example, a region in which the silicon concentration measured by secondary ion mass spectrometry (SIMS) is lower than 1×10¹⁹ atoms/cm³, preferably lower than 5×10¹⁸ atoms/cm³, further preferably lower than 2×10¹⁸ atoms/cm³ is provided between the oxide 406b and the oxide 406a. A region in which the silicon concentration measured by SIMS is lower than 1×10¹⁹ atoms/cm³, preferably lower than 5×10¹⁸ atoms/cm³, further preferably lower than 2×10¹⁸ atoms/cm³ is provided between the oxide 406b and the oxide 406c.

The hydrogen concentration in the oxide 406a and that in the oxide 406c are preferably reduced in order to reduce the hydrogen concentration in the oxide 406b. The oxide 406a and the oxide 406c each have a region in which the hydrogen concentration measured by SIMS is lower than or equal to 2×10²⁰ atoms/cm³, preferably lower than or equal to 5×10¹⁹ atoms/cm³, further preferably lower than or equal to 1×10¹⁹ atoms/cm³, still further preferably lower than or equal to 5×10¹⁸ atoms/cm³. The nitrogen concentration in the oxide 406a and that in the oxide 406c are preferably reduced in order to reduce the nitrogen concentration in the oxide 406b. The oxide 406a and the oxide 406c each have a region in which the nitrogen concentration measured by SIMS is lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

When copper enters the oxide semiconductor, an electron trap might be generated. The electron trap might shift the threshold voltage of the transistor in the positive direction. Therefore, the copper concentration at the surface of or in the oxide 406b is preferably as low as possible. For example, the oxide 406b preferably has a region in which the copper concentration is lower than or equal to 1×10¹⁹ atoms/cm³, lower than or equal to 5×10¹⁸ atoms/cm³, or lower than or equal to 1×10¹⁸ atoms/cm³.

The above three-layer structure is just an example. For example, a two-layer structure without the oxide 406a or the oxide 406c may be employed. Alternatively, a four-layer structure in which any one of the semiconductors described as examples of the oxide 406a, the oxide 406b, and the oxide 406c is provided under or over the oxide 406a or the oxide 406c may be employed. Alternatively, an n-layer structure (n is an integer of 5 or more) may be employed in which any one of the semiconductors described as examples of the oxide 406a, the oxide 406b, and the oxide 406c is provided in two or more of the following positions: over the oxide 406a, under the oxide 406a, over the oxide 406c, and under the oxide 406c.

In particular, in the channel width direction of the transistor 490 described in this embodiment, the top surface and side surfaces of the oxide 406b are in contact with the oxide 406c, and the bottom surface of the oxide 406b is in contact with the oxide 406a (see FIG. 6B and the like). In this manner, the oxide 406b is surrounded by the oxide 406a and the oxide 406c, whereby the influence of the trap states can be further reduced.

According to one embodiment of the present invention, a transistor with small variation in electrical characteristics can be provided. Accordingly, a semiconductor device with small variation in electrical characteristics can be provided. According to one embodiment of the present invention, a transistor with high reliability can be provided. Accordingly, a semiconductor device with high reliability can be provided.

An oxide semiconductor has a band gap of 2 eV or more; therefore, a transistor including an oxide semiconductor in a channel formation region can have extremely low off-state current. Specifically, the off-state current per micrometer in channel width at room temperature (25° C.) and at a source-drain voltage of 3.5 V can be lower than 1×10⁻²⁰ A, lower than 1×10⁻²² A, or lower than 1×10⁻²⁴ A. That is, the on/off ratio of the transistor can be greater than or equal to 20 digits and less than or equal to 150 digits.

According to one embodiment of the present invention, a transistor with low power consumption can be provided. Accordingly, a semiconductor device with low power consumption can be provided. Since a transistor including an oxide semiconductor has a high on/off ratio, a semiconductor device with a high operation frequency and low power consumption can be provided in some cases. Moreover, a transistor whose channel region is formed in a CAAC-OS film can have improved frequency characteristics (f characteristics).

In a conventional transistor including silicon, germanium, or a compound thereof, particularly in an element having a short channel length, a gate electric field is preferably enhanced to suppress a short-channel effect. To enhance the gate electric field, the thickness of a gate insulating film is preferably reduced. In contrast, a transistor including an oxide semiconductor film is an accumulation-type transistor in which electrons are majority carriers. Therefore, drain-induced barrier lowering (DIBL) as a short-channel effect is less likely to occur than in an inversion-type transistor having a PN junction. In other words, the transistor including an oxide semiconductor film is resistant to a short-channel effect.

The transistor including an oxide semiconductor film can have a thicker gate insulating film than a conventional transistor including silicon or the like because of its high resistance to a short-channel effect. For example, a minute transistor having a channel length and a channel width of 50 nm or less may include a thick gate insulating film with a thickness of approximately 10 nm. When the thickness of the gate insulating film is increased, parasitic capacitance can be reduced. Thus, dynamic characteristics of a circuit can be improved in some cases. Furthermore, when the thickness of the gate insulating film is increased, leakage current and power consumption can be reduced in some cases.

Furthermore, a drain electric field is enhanced with a reduction in channel length; thus, a reduction in reliability due to hot-carrier degradation noticeably occurs in a conventional transistor including silicon or the like, particularly in a transistor having a short channel length. In contrast, in some cases, avalanche breakdown or the like is less likely to occur in the transistor including an oxide semiconductor than in a conventional transistor including silicon or the like for the following reasons: for example, in an oxide semiconductor, which has a wide energy gap (e.g., an oxide semiconductor containing indium, gallium, and zinc has an energy gap of 2.5 eV or more), electrons are not easily excited, and the effective mass of a hole is large. Therefore, for example, it may be possible to inhibit hot-carrier degradation or the like due to avalanche breakdown.

When thickness of the gate insulating film is increased, the withstand voltage of the gate insulating film can be increased, so that the transistor can be driven at higher gate voltage. In addition, when hot-carrier degradation is inhibited, the transistor can be driven at high drain voltage without an increase in channel length. Thus, the reliability of the transistor in a circuit supplied with high voltage can be increased: at the same time, since the channel length can be reduced, the integration degree of the circuit can be increased.

Moreover, the temperature dependence of a semiconductor element including an oxide semiconductor is smaller than that of a conventional semiconductor element including silicon, germanium, or a compound thereof. Therefore, for example, a temperature sensor in which the semiconductor element including an oxide semiconductor is used can have excellent characteristics.

A CAAC-OS has dielectric constant anisotropy. Specifically, the dielectric constant of a CAAC-OS is higher in the c-axis direction than in the a-axis direction and the b-axis direction. A transistor in which a channel is formed in a semiconductor film including a CAAC-OS and a gate electrode is located in the c-axis direction has a high dielectric constant in the c-axis direction; accordingly, an electric field generated by the gate electrode easily reaches the entire CAAC-OS. Thus, the subthreshold swing (S value) can be reduced. In the transistor including a CAAC-OS in the semiconductor film, the S value is not easily increased by miniaturization.

Moreover, since the dielectric constant in the a-axis direction and the b-axis direction of an CAAC-OS is small, an influence of the electric field generated between a source and a drain is reduced. Thus, a channel length modulation effect, a short-channel effect, or the like is less likely to occur, whereby the reliability of the transistor can be increased.

Here, the channel length modulation effect is a phenomenon in which, when the drain voltage is higher than the threshold voltage, a depletion layer expands from the drain side, so that the effective channel length is decreased. The short-channel effect is a phenomenon in which a channel length is reduced, so that a deterioration in electrical characteristics, such as a decrease in threshold voltage, is caused. The more a transistor is miniaturized, the more likely deterioration in electrical characteristics caused by these phenomena is to occur.

### <Atomic Ratio>

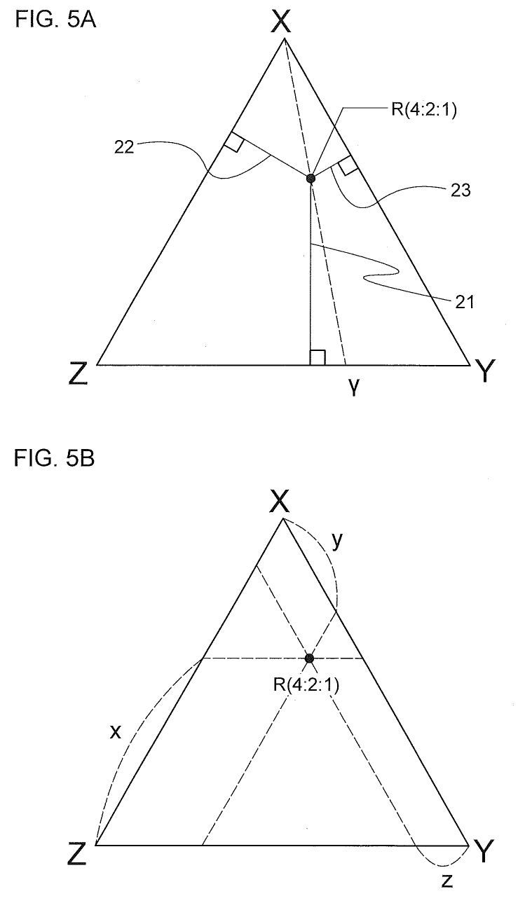

FIGS. 5A and 5B can be used to show the atomic ratio of an element X to an element Y and an element Z in a substance. The atomic ratio of the element X to the element Y and the element Z is denoted by x:y:z. This atomic ratio can be shown as coordinates (x:y:z) in FIGS. 5A and 5B.

FIGS. 5A and 5B each illustrate a regular triangle with vertices X, Y, and Z, and a coordinate point R (4:2:1) as an example. As the distance to the vertex decreases, the proportion of atoms of a corresponding element increases, whereas as the distance increases, the proportion of atoms decreases. As illustrated in FIG. 5A, the atomic ratio of the elements is represented by the ratio of the lengths of perpendicular lines from the coordinate point to the opposite sides of the respective vertexes of the triangle. For example, the proportion of atoms of the element X is represented by the length of a perpendicular line 21 from the coordinate point to the opposite side of the vertex X, that is, to a side YZ. Therefore, at the coordinate point R in FIGS. 5A and 5B, the atomic ratio of the element X to the element Y and the element Z is the ratio of the length of the perpendicular line 21 to the length of a perpendicular line 22 and the length of a perpendicular line 23, that is, x:y:z=4:2:1. The intersection of the side YZ with a line passing through the vertex X and the coordinate point R is denoted by γ. Assuming that the ratio of the length of a line Yγ to the length of a line γZ is Yγ:γZ, Yγ:γZ corresponds to (the number of atoms of the element Z):(the number of atoms of the element Y). That is, when x:y:z is 4:2:1, for example, Yγ:γZ=1:2 is satisfied.

As illustrated in FIG. 5B, three straight lines which pass through the coordinate point R and are parallel to the respective three sides of the triangle are drawn. The intersections of the three lines with the three sides can be used to determine x, y, and z in FIG. 5B.

The oxide 406b preferably contains indium, the element M, and zinc.

Here, the element M is preferably gallium, aluminum, yttrium, tin, or the like. Other elements which can be used as the element M are boron, silicon, titanium, iron, nickel, germanium, zirconium, molybdenum, lanthanum, cerium, neodymium, hafnium, tantalum, tungsten, and the like. Note that two or more of the above elements may be used in combination as the element M in some cases. The element M is an element having a high bonding energy with oxygen, for example. The element M is an element whose bonding energy with oxygen is higher than that of indium, for example. The element M is an element having a function of increasing the energy gap of the oxide, for example.

Here, the atomic ratio of indium to the element M and zinc in the oxide 406b is denoted by x_{b}:y_{b}:z_{b}.

The oxide 406b included in the transistor of one embodiment of the present invention is preferably a CAAC-OS film.

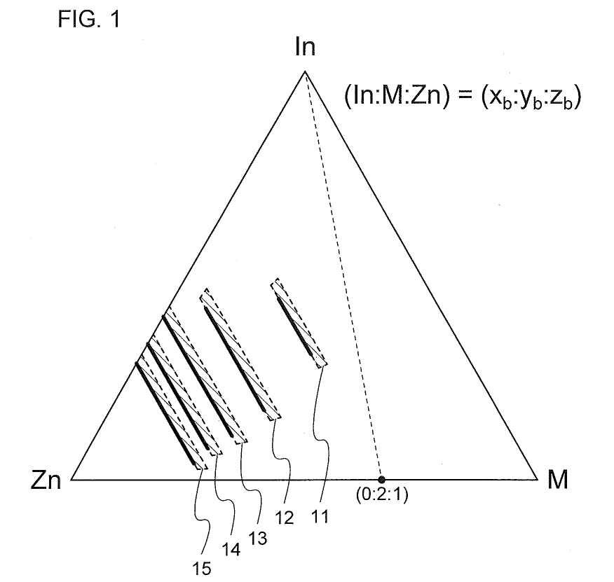

As disclosed in Non-Patent Document 1, it is known that there is a homologous series represented by InMO₃(ZnO)ₘ (m is a natural number) as one of oxides containing indium, the element M, and zinc. Here, for example, the case where the element M is Ga will be described. It is known that a single-phase solid solution can be obtained within the ranges indicated by thick lines in FIG. 1 when powders of In₂O₃, Ga₂O₃, and ZnO are mixed in a ratio within the ranges in FIG. 1 and sintered at 1350° C. (in the example in FIG. 1, m is 1 to 5). In this specification, the range is referred to as a solid solution range.

The oxide film of one embodiment of the present invention contains indium, the element M, and zinc. A CAAC-OS film can be easily obtained in the case where the composition ratio of indium to the element M and zinc is within or in the vicinity of the solid solution range, for example, within or in the vicinity of the ranges shown by equations (1) to (5). Note that the element M is preferably gallium.

Solid solution ranges in the case where in is 1, 2, 3, 4, and 5 indicated by the thick lines in FIG. 1 correspond to the following equations (1), (2), (3), (4), and (5), respectively. In the equations, x_{b}:y_{b}:z_{b} denotes the atomic ratio of indium to the element M and zinc.

[Formula 1]

x_{b}:y_{b}:z_{b}=(1−α₁):(1+α₁):1 (1)

In the equation (1), α₁ is greater than or equal to −0.33 and less than or equal to 0.88.

[Formula 2]

x_{b}:y_{b}:z_{b}=(1−α₂):(1+α₂):2 (2)

In the equation (2), α₂ is greater than or equal to −0.68 and less than or equal to 0.32.

[Formula 3]

x_{b}:y_{b}:z_{b}=(1−α₃):(1+α₃):3 (3)

In the equation (3), α₃ is greater than or equal to −1 and less than or equal to 0.46.

[Formula 4]

x_{b}:y_{b}:z_{b}=(1−α₄):(1+α₄):4 (4)

In the equation (4), α₄ is greater than or equal to −1 and less than or equal to 0.54.

[Formula 5]

x_{b}:y_{b}:z_{b}=(1−α₅):(1+α₅):5 (5)

In the equation (5), α₅ is greater than or equal to −1 and less than or equal to 0.72.

Here, the following case will be described: in an oxide film containing indium, the element M, and zinc in an atomic ratio in the vicinity of the solid solution range, the proportion of zinc atoms is higher than that within the solid solution range. Such an excessive proportion of zinc atoms might increase sDOS, for example.

As another possibility, for example, an excessive proportion of zinc atoms may cause segregation of zinc oxide. The segregation of zinc oxide might lead to formation of a clear grain boundary in the oxide film.

Accordingly, excessive zinc is unfavorable to the oxide film containing indium, the element M, and zinc.

In the case where the proportion of zinc atoms is low, characteristics (e.g., reliability) of a transistor including the oxide are probably improved as compared with the case where the composition of the oxide film is within the solid solution range. Described now will be compositions which are within the solid solution ranges in the case where m is 1, 2, 3, 4, and 5 and have low proportions of zinc atoms. In these cases, the oxide film of one embodiment of the present invention preferably satisfies the following equations (6) to (10). The element M is preferably gallium. Note that the equations (6) to (10) each include the solid solution range and a neighborhood range in which the proportion of zinc atoms is lower than that within the solid solution range.

Non-Patent Document 2 reports that InGaO₃(ZnO) can have a layered structure of YbFe₂O₄ type in which InO₂ layers with six-coordinated cation sites and GaZnO₂ layers with five-coordinated cation sites are periodically stacked. In addition, the existence of the solid solution range reported in Non-Patent Document 1 indicates possibilities that an In ion occupies not only the six-coordinated site in the InO₂ layer but also the five-coordinated site in the GaZnO₂ layer and that a Ga ion occupies not only the five-coordinated site in the GaZnO₂ layer but also the six-coordinated site in the InO₂ layer. In contrast, a Zn ion can exist more stably in the five-coordinated site in the GaZnO₂ layer than in the six-coordinated site in the InO₂ layer, which infers that a Zn ion hardly occupies the six-coordinated site in the InO₂ layer.

Accordingly, in a composition which is in the vicinity of the solid solution range and in which the proportion of zinc atoms is lower than that of indium atoms and that of gallium atoms, an In ion or a Ga ion easily substitutes for a Zn ion in the five-coordinated site; thus, a cation vacancy is less likely to be generated in principle, and defect states such as sDOS are also less likely to be formed. On the other hand, in the case where the proportion of zinc atoms is higher than that of indium atoms and that of gallium atoms, a Zn ion hardly substitutes for an ion in the six-coordinated site in the InO₂ layer; consequently, excessive Zn possibly causes a segregation of ZnO or the like and results in an increase in sDOS.

[Formula 6]

x_{b}:y_{b}:z_{b}=(1−α₁):(1+α₁):m₁ (6)

In the equation (6), α₁ is preferably greater than or equal to −0.43 and less than or equal to 0.18. The allowable range of m₁ is, for example, greater than 0.7 and less than or equal to 1.1, or greater than or equal to 0.9 and less than or equal to 1.1. Since excessive zinc is sometimes unfavorable as described above, m₁ is preferably greater than 0.7 and less than or equal to 1, further preferably greater than or equal to 0.9 and less than or equal to 1.

[Formula 7]

x_{b}:y_{b}:z_{b}=(1−α₂):(1+α₂):2m₂ (7)

In the equation (7), α₂ is preferably greater than or equal to −0.78 and less than or equal to 0.42. The allowable range of m₂ is, for example, greater than 0.7 and less than or equal to 1.1, or greater than or equal to 0.9 and less than or equal to 1.1. Since excessive zinc is sometimes unfavorable as described above, m₂ is preferably greater than 0.7 and less than or equal to 1, further preferably greater than or equal to 0.9 and less than or equal to 1.

[Formula 8]

x_{b}:y_{b}:z_{b}=(1−α₃)(1+α₃): 3m₃ (8)

In the equation (8), α₃ is preferably greater than or equal to −1 and less than or equal to 0.56. The allowable range of m₃ is, for example, greater than 0.7 and less than or equal to 1.1, or greater than or equal to 0.9 and less than or equal to 1.1. Since excessive zinc is sometimes unfavorable as described above, In₃ is preferably greater than 0.7 and less than or equal to 1, further preferably greater than or equal to 0.9 and less than or equal to 1.

[Formula 9]

x_{b}:y_{b}:z_{b}=(1−α₄):(1+α₄):4m₄ (9)

In the equation (9), α₄ is preferably greater than or equal to −1 and less than or equal to 0.64. The allowable range of m₄ is, for example, greater than 0.7 and less than or equal to 1.1, or greater than or equal to 0.9 and less than or equal to 1.1. Since excessive zinc is sometimes unfavorable as described above, m₄ is preferably greater than 0.7 and less than or equal to 1, further preferably greater than or equal to 0.9 and less than or equal to 1.

[Formula 10]

x_{b}:y_{b}:z_{b}=(1−α₅):(1+α₅):5m₅ (10)

In the equation (10), α₅ is preferably greater than or equal to −1 and less than or equal to 0.82. The allowable range of m₅ is, for example, greater than 0.7 and less than or equal to 1.1, or greater than or equal to 0.9 and less than or equal to 1.1. Since excessive zinc is sometimes unfavorable as described above, m₅ is preferably greater than 0.7 and less than or equal to 1, further preferably greater than or equal to 0.9 and less than or equal to 1.

Next, a favorable range of the atomic ratio of indium to the element M and zinc in the oxide 406b will described with reference to FIG. 1. Note that the proportion of oxygen atoms is not shown in FIG. 1. For example, the ranges represented by the equations (6) to (10) correspond to regions 11 to 15 in FIG. 1, respectively. In the example shown here, m₁ to m₅ are each greater than or equal to 0.9 and less than or equal to 1. In FIG. 1, the regions also include line segments surrounding the regions and vertexes of the regions. Here, the element M is preferably gallium.

Here, to increase carrier mobility, the indium content is preferably increased. In an oxide semiconductor containing indium, the element M, and zinc, the s orbital of heavy metal mainly contributes to carrier conduction, and when the indium content is increased, overlaps of the s orbitals are increased; therefore, an oxide with a high indium content has higher mobility than an oxide with a low indium content. Thus, with the use of an oxide with a high indium content for an oxide semiconductor film, carrier mobility can be increased.

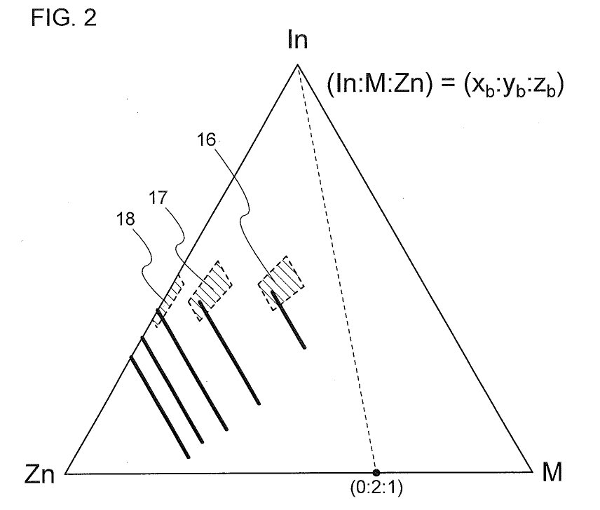

Accordingly, as long as x_{b}:y_{b}:z_{b} is within the solid solution range, a higher proportion of indium can lead to a higher carrier mobility in some cases. A favorable range of x_{b}:y_{b}:z_{b} will be described below with reference to FIG. 2.

Preferred values of x_{b}, y_{b}, and z_{b} are as follows: x_{b} is 4−β₁, y_{b} is 2+β₁, and z_{b} is greater than or equal to 2.1 and less than or equal to 3.3, where β₁ is preferably greater than or equal to −0.3 and less than or equal to 0.3. For example, the range of a region 16 in FIG. 2 is preferable.

Alternatively, preferred values of x_{b}, y_{b}, and z_{b} are as follows: x_{b} is 5−β₂, y_{b} is 1+β₂, and z_{b} is greater than or equal to 4.2 and less than or equal to 6.6, where β₂ is preferably greater than or equal to −0.3 and less than or equal to 0.3. For example, the range of a region 17 in FIG. 2 is preferable.

Alternatively, preferred values of x_{b}, y_{b}, and z_{b} are as follows: x_{b} is 2−β₃, y_{b} is 0, and z_{b} is greater than or equal to 2.1 and less than or equal to 3.3, where β₃ is preferably greater than or equal to 0 and less than or equal to 0.1. For example, the range of a region 18 in FIG. 2 is preferable.

The oxide film of one embodiment of the present invention includes a first region and a second region. The first region is a region which has c-axis alignment and in which the direction of the c-axis is parallel to a surface of the oxide film or a normal vector of the formation surface of the oxide film. The second region is a region without the c-axis alignment. In other words, the second region is a region in which the c-axis alignment is difficult to observe. The second region can also be referred to as a region which is not a CAAC. Note that there is a possibility that an oxide film including the second region has a higher density of shallow-level defect states (sDOS) than an oxide film without the second region.

In an oxide semiconductor film, specifically, at least in an oxide semiconductor film used as the oxide 406b, atomic voids preferably account for less than 20% of the entire oxide semiconductor film.

It is preferable that the atomic ratio(s) in the first region and/or the second region satisfy any of the equations (6) to (10). It is particularly preferable that the atomic ratio in the second region satisfy any of the equations (6) to (10).

Alternatively, it is preferable that the atomic ratio(s) in the first region and/or the second region satisfy any of the atomic ratios in the regions 11 to 18. It is particularly preferable that the atomic ratio in the second region lie in any of the regions 11 to 18.

The transistor of one embodiment of the present invention may include an oxide in which a plurality of films is stacked. For example, a three-layer structure which includes the oxide 406c over the oxide 406b and the oxide 406a under the oxide 406b may be employed. As an alternative, a structure without the oxide 406a or the oxide 406c is also possible.

The atomic ratio of indium to the element M and zinc in the oxide 406a and that in the oxide 406c are denoted by xₐ:yₐ:zₐ and x_{c}:y_{c}:z_{c}, respectively. Here, the element M is preferably gallium.

In order that the oxide 406a and the oxide 406c can each have a lower electron affinity than the oxide 406b, for example, the indium content in the oxide 406a and that in the oxide 406c are preferably lower than that in the oxide 406b. In the case where the element M is gallium, for example, the gallium content may be increased. Further preferably, the zinc content is lower than the gallium content, for example. Note that a too low indium content is sometimes unfavorable. If the indium content is too low, for example, the electrical conductivity of a sputtering target decreases, which may make DC sputtering deposition difficult.

Thus, xₐ and yₐ preferably satisfy xₐ≦yₐ, further preferably 2xₐ≦yₐ, still further preferably 2.7xₐ≦yₐ≦3.3xₐ. In addition, x_{c} and y_{c} preferably satisfy x_{c}≦y_{c}, further preferably 2x_{c}≦y_{c}, still further preferably 2.7x_{c}≦y_{c}≦3.3x_{c}.

In other words, preferred values of xₐ, yₐ, and zₐ are as follows: xₐ is 1, yₐ is greater than 2.7 and less than or equal to 3.3, and zₐ is greater than 1 and less than or equal to 2.

Preferred values of x_{c}, y_{c}, and z_{c} are as follows: x_{c} is 1, y_{c} is greater than 2.7 and less than or equal to 3.3, and z_{c} is greater than 1 and less than or equal to 2.

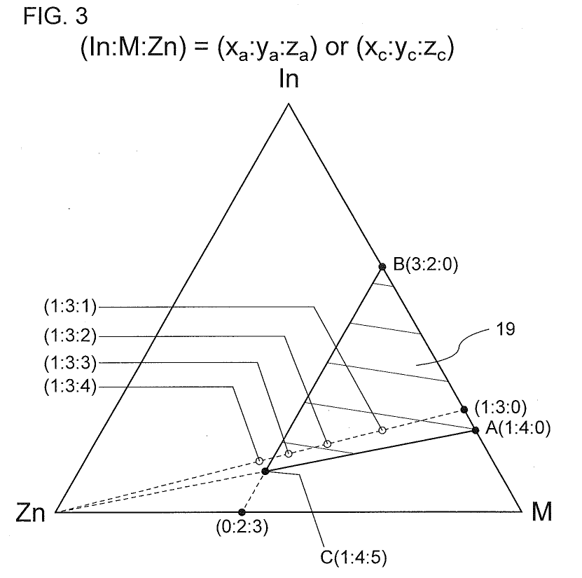

In other words, the proportion of atoms of the element M is preferably 40% or more, further preferably 50% or more of the sum of the proportions of atoms of indium, the element M, and zinc. FIG. 3 shows a preferred range of the atomic ratio of indium to the element M and zinc in each of the oxides 406a and 406c. Note that the proportion of oxygen atoms is not shown in FIG. 3. In FIG. 3, the element M is preferably gallium.

The atomic ratio of indium to the element M and zinc in the oxide 406b is preferably within the range of a region 19 in FIG. 3. The region 19 is defined by line segments between a coordinate point A (x:y:z=1:4:0), a coordinate point B (x:y:z=3:2:0), and a coordinate point C (x:y:z=1:4:5). Note that the region 19 includes coordinate points on the line segments and the coordinate points A to C.

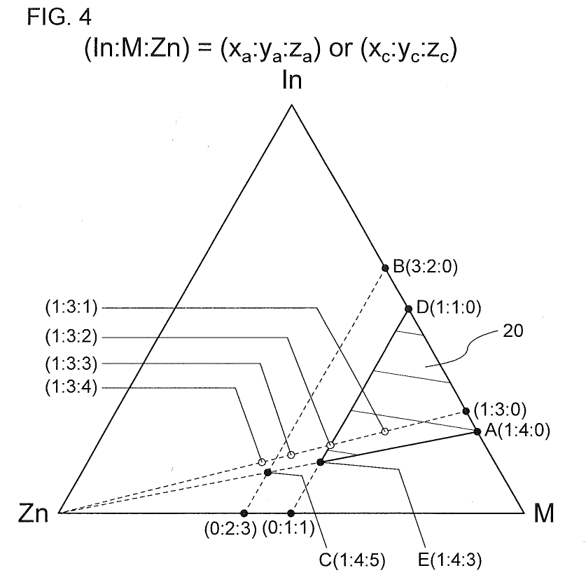

Further preferably, the atomic ratio of indium to the element M and zinc in the oxide 406b is preferably within the range of a region 20 in FIG. 4. The region 20 is defined by line segments between the coordinate point A (x:y:z=1:4:0), a coordinate point D (x:y:z=1:1:0), and a coordinate point E (x:y:z=1:4:3). Note that the region includes coordinate points on the line segments and the coordinate points A, D, and E.

The proportions of atoms of indium, the element M, zinc, and the like in each of the oxides 406a to 406c can be measured, for example, by ICP-MS (Inductively Coupled Plasma-Mass Spectrometry), scanning electron microscope-energy dispersive X-ray spectroscopy (SEM-EDX), transmission electron microscope-energy dispersive X-ray spectroscopy (TEM-EDX), transmission electron microscope-electron energy loss spectroscopy (TEM-EELS), X-ray photoelectron spectroscopy (XPS), secondary ion mass spectrometry (SIMS), or Rutherford backscattering spectrometry (RBS).

### <Modification Example of Transistor>

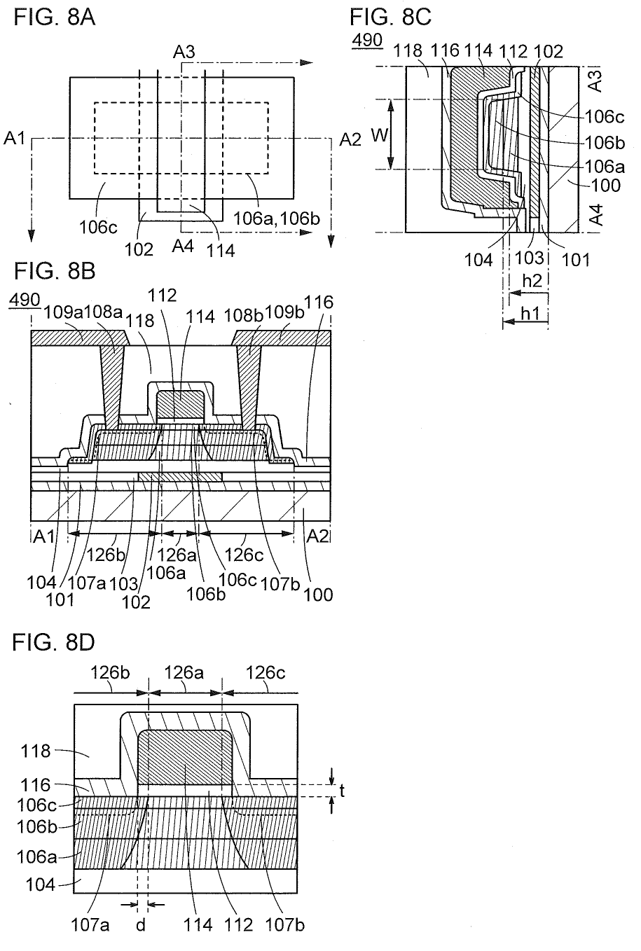

Instead of the structure illustrated in FIGS. 6A to 6C, the transistor 490 may have any of structures illustrated in FIGS. 8A to 8D, FIGS. 9A to 9F, FIGS. 10A and 10B, FIGS. 11A and 11B, FIGS. 12A and 12B, FIGS. 13A and 13B, FIGS. 14A and 14B, FIGS. 15A and 15B, FIGS. 16A and 16B, and FIGS. 17A and 17B.

FIG. 8A is a top view of the transistor 490. FIG. 8B is a cross-sectional view taken along dashed-dotted line A1-A2 in FIG. 8A. FIG. 8C is a cross-sectional view taken along dashed-dotted line A3-A4 in FIG. 8A. A region along dashed-dotted line A1-A2 shows a structure in the channel length direction of the transistor 490, and a region along dashed-dotted line A3-A4 shows a structure in the channel width direction of the transistor 490. The channel length direction of a transistor refers to a direction in which a carrier moves between a source (a source region or a source electrode) and a drain (a drain region or a drain electrode), and the channel width direction refers to a direction perpendicular to the channel length direction in a plane parallel to a substrate. In FIG. 8A, some components of the transistor 490 (e.g., an insulating film functioning as a protective insulating film) are not illustrated to avoid complexity. As in FIG. 8A, some components are not illustrated in some cases in top views of transistors described below.

The transistor 490 includes an oxide 106b, a conductor 114, an oxide 106a, an oxide 106c, an insulator 112, and an insulator 116. The oxide 106b is provided over the oxide 106a, the oxide 106c is provided over the oxide 106b, the insulator 112 is provided over the oxide 106c, and the conductor 114 is provided over the insulator 112. The oxide 116 is provided over the conductor 114 and includes a region in contact with a top surface of the oxide 106c. The oxide 106b includes a region that overlaps with the conductor 114 with the oxide 106c and the insulator 112 positioned therebetween. As illustrated in the top view in FIG. 8A, it is preferable that the periphery of the oxide 106a be substantially aligned with the periphery of the oxide 106b and that the periphery of the insulator 106c be positioned outward from the peripheries of the oxide 106a and the oxide 106b.

For the oxide 106a, refer to the oxide 406a; for the oxide 106b, the oxide 406b; for the oxide 106c, the oxide 406c; for the insulator 112, the insulator 412; for the conductor 114, the conductor 404; and for the insulator 116, the insulator 408.

For example, as illustrated in FIGS. 8A to 8C, the transistor 490 includes an insulator 101, a conductor 102, an insulator 103, and an insulator 104 which are formed over a layer 100; the oxide 106a, the oxide 106b, and the oxide 106c which are formed over the insulator 104; the insulator 112 and the conductor 114 which are formed over the oxide 106c; and the insulator 116, an insulator 118, a conductor 108a, a conductor 108b, a conductor 109a, and a conductor 109b which are formed over the conductor 114.

For the layer 100, refer to the layer 625; for the insulator 101, an insulator 571 described later; for the conductor 102, the conductor 413; for the insulator 103, an insulator 585 described later; for the insulator 104, the insulator 402; for the insulator 118, an insulator 591 described later; for the conductor 108a and the conductor 108b, a plug 544b described later and the like; and for the conductor 109a and the conductor 109b, a conductor 514 described later and the like.

Although the periphery of the oxide 106c is positioned outward from the periphery of the oxide 106a in FIGS. 8B and 8C, the structure of the transistor described in this embodiment is not limited thereto. For example, the periphery of the oxide 106a may be positioned outward from the periphery of the oxide 106c, or the side end portion of the oxide 106a may be substantially aligned with a side end portion of the oxide 106c.

In the oxide 106a, the oxide 106b, and the oxide 106c of the transistor 490 described in this embodiment, a region 126a, a region 126b, and a region 126c are formed, and the region 126b and the region 126c have a higher concentration of a dopant and lower resistance than the region 126a. The dopant concentration in the region 126a is, for example, less than or equal to 5%, less than or equal to 2%, or less than or equal to 1%, of the maximum dopant concentration in the region 126b or the region 126c. Instead of the term “dopant,” the term “donor,” “acceptor,” “impurity,” or “element” may be used.

FIG. 8D shows an enlarged view of the conductor 114 and the vicinity thereof in the transistor 490 in FIG. 8B. As illustrated in FIG. 8D, the region 126a is a region substantially overlapping with the conductor 114, and the region 126b and the region 126c are regions except the region 126a in the oxide 106a, the oxide 106b, and the oxide 106c. It is preferable that the region 126b and the region 126c partly overlap with a region (channel formation region) in which the oxide 106b overlaps with the conductor 114. For example, side end portions of the region 126b and the region 126c in the channel length direction are preferably positioned inward from a side end portion of the conductor 114 by a distance d. In this case, the distance d preferably satisfies 0.25t<d<t, where t represents the thickness of the insulator 112.

As described above, the region 126b and the region 126c are partly formed in a region in which the oxide 106a, the oxide 106b, and the oxide 106c overlap with the conductor 114. Accordingly, the channel formation region of the transistor 490 is in contact with the regions 126b and 126c having low resistance, and thus, high-resistance offset regions are not formed between the region 126a and the regions 126b and 126c. As a result, the on-state current of the transistor 490 can be increased. Furthermore, when the side end portions of the regions 126b and 126c in the channel length direction are positioned such that 0.25t<d<t is satisfied, the regions 126b and 126c can be prevented from extending inward too much in the channel length direction, and thus, the transistor 490 can be prevented from being constantly in an on state.

As described in detail later, the region 126b and the region 126c are formed by ion doping treatment such as an ion implantation method. For this reason, as the depth from the top surface of the oxide 106c increases, the side end portions of the regions 126b and 126c in the channel length direction might shift toward the side end portions of the oxide 106a, the oxide 106b, and the oxide 106c in the channel length direction as illustrated in FIG. 8D. In this case, the distance d is the distance between the side end portion of the conductor 114 in the channel length direction and each of the side end portions of the regions 126b and 126c in the channel length direction, which are the closest to the conductor 114 and are positioned inward from the side end portion of the conductor 114.

In some cases, the regions 126b and 126c in the oxide 106a do not overlap with the conductor 114, for example. In this case, at least part of the regions 126b and 126c in the oxide 106a or the oxide 106b preferably overlaps with the conductor 114.

A low-resistance region 107a and a low-resistance region 107b are preferably formed in the oxide 106a, the oxide 106b, and the oxide 106c in the vicinity of the interface with the insulator 116 (indicated by dotted lines in FIG. 8B). The low-resistance region 107a and the low-resistance region 107b contain at least one of the elements contained in the insulator 116. It is preferable that the low-resistance region 107a and the low-resistance region 107b be partly and substantially in contact with a region (channel formation region) of the oxide 106b overlapping with the conductor 114 or partly overlap with the region.

Since a large region of the oxide 106c is in contact with the insulator 116, the low-resistance region 107a and the low-resistance region 107b are easily formed in the oxide 106c. The concentration of the element contained in the insulator 116 is higher in the low-resistance region 107a and the low-resistance region 107b included in the oxide 106c than in a region of the oxide 106c other than the low-resistance region 107a and the low-resistance region 107b (e.g., a region of the oxide 106c overlapping with the conductor 114).

The low-resistance region 107a is formed in the region 126b and the low-resistance region 107b is formed in the region 126c. In an ideal structure, the concentration of an added element is the highest in the low-resistance regions 107a and 107b, the second highest in regions in the regions 126b and 126c except the low-resistance regions 107a and 107b, and the lowest in the region 126a. Here, the added elements include the dopant for forming the region 126b and the region 126c and the element added from the insulator 116 to the low-resistance region 107a and the low-resistance region 107b.

The formation of the region 126b, the region 126c, the low-resistance region 107a, and the low-resistance region 107b leads to a reduction in contact resistance between the conductor 108a or the conductor 108b and the oxide 106a, the oxide 106b, or the oxide 106c, whereby the transistor 490 can have higher on-state current.

Although the low-resistance regions 107a and 107b are formed in the transistor 490 in FIGS. 8A to 8D, the structure of the semiconductor device described in this embodiment is not necessarily limited thereto. For example, in the case where the regions 126b and 126c have sufficiently low resistance, the low-resistance regions 107a and 107b need not be formed.

The insulator 112 is formed over the oxide 106c, and the conductor 114 is formed over the insulator 112. At least part of the insulator 112 and part of the conductor 114 overlap with the conductor 102 and the oxide 106b. It is preferable that a side end portion of the conductor 114 in the channel length direction be substantially aligned with a side end portion of the insulator 112 in the channel length direction. Here, the insulator 112 functions as a gate insulating film of the transistor 490, and the conductor 114 functions as a gate electrode of the transistor 490.

The insulator 116 is formed over the conductor 114, the oxide 106c, and the insulator 104. The insulator 116 is preferably in contact with a region of the oxide 106c which does not overlap with the insulator 112. The insulator 116 may be in contact with at least part of the insulator 104. The insulator 118 is formed over the insulator 116. Here, the insulator 116 functions as a protective insulating film of the transistor 490, and the insulator 118 functions as an interlayer insulating film of the transistor 490. The insulator 116 is preferably formed using an insulator that has an effect of blocking oxygen.

The conductor 108a and the conductor 108b are formed in openings provided in the insulator 118, the insulator 116, and the oxide 106c so as to be in contact with the low-resistance region 107a and the low-resistance region 107b. Over the insulator 118, the conductor 109a is formed in contact with the top surface of the conductor 108a and the conductor 109b is formed in contact with the top surface of the conductor 108b. The conductor 108a and the conductor 108b are spaced apart and are preferably formed to face each other with the conductor 114 positioned therebetween as illustrated in FIG. 8B. Here, the conductor 108a functions as one of a source electrode and a drain electrode of the transistor 490, and the conductor 108b functions as the other of the source electrode and the drain electrode of the transistor 490. The conductor 109a functions as a wiring connected to the one of the source electrode and the drain electrode of the transistor 490, and the conductor 109b functions as a wiring connected to the other of the source electrode and the drain electrode of the transistor 490. Although the conductor 108a and the conductor 108b are in contact with the oxide 106b in FIG. 8B, this embodiment is not limited to this structure. As long as the contact resistance with the low-resistance region 107a and the low-resistance region 107b is sufficiently low, the conductor 108a and the conductor 108b may be in contact with the oxide 106c.

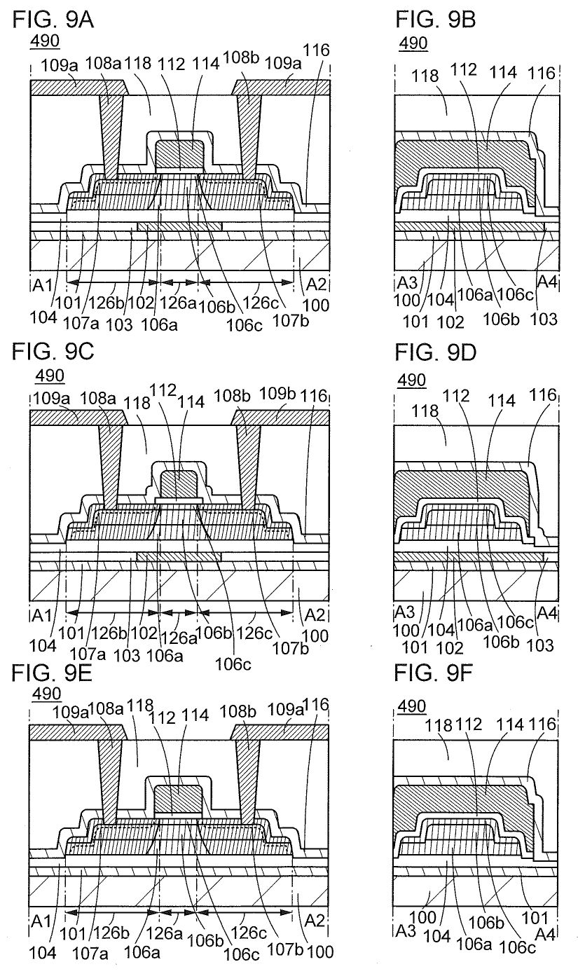

FIGS. 9A to 9F illustrate modification examples of the transistor 490 in FIGS. 8A to 8D. The transistor 490 in FIGS. 9A and 9B is different from that in FIGS. 8A to 8D in that the side end portion of the oxide 106b is positioned inward from the side end portion of the oxide 106a. In other words, in FIGS. 9A and 9B, the peripheries of the oxides 106a and 106c are positioned outward from the periphery of the oxide 106b, and the oxide 106b is surrounded by the oxides 106a and 106c. It is preferable that the side end portion of the oxide 106a, especially, that in the channel width direction be substantially aligned with the side end portion of the oxide 106c, especially, that in the channel width direction.

Patterning is performed such that the side end portion of the oxide 106b is positioned inward from the side end portion of the oxide 106a as in the transistor 490 in FIGS. 9A and 9B, whereby the number of times the insulator 104 is etched together with the oxide 106a or the oxide 106b can be reduced. A portion of a surface of the insulator 104 to be etched can be away from the conductor 102, leading to an increase in withstand voltage of the transistor 490.

In the transistor 490 in FIGS. 9A and 9B and the like, the side end portion of the conductor 114 in the channel length direction is substantially aligned with the side end portion of the insulator 112 in the channel length direction; however, the structure of the semiconductor device described in this embodiment is not limited thereto. For example, as in the transistor 490 in FIGS. 9C and 9D, the width of the conductor 114 in the channel length direction may be smaller than the width of the insulator 112 in the channel length direction.

Although the conductor 102 and the insulator 103 are formed in the transistor 490 in FIGS. 9A and 9B or the like, the structure of the semiconductor device described in this embodiment is not limited thereto. For example, as in the transistor 490 in FIGS. 9E and 9F, a structure without the conductor 102 and the insulator 103 may also be employed.

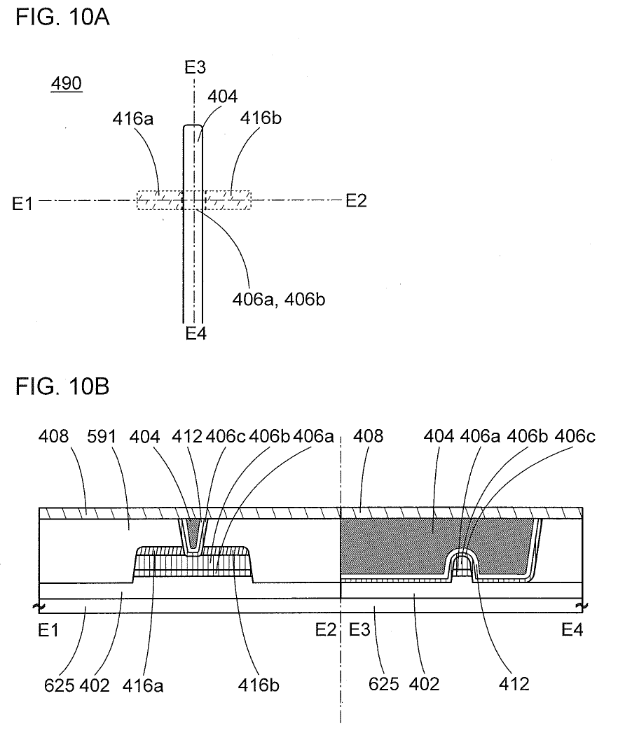

The transistor 490 in FIGS. 10A and 10B is different from that in FIGS. 6A to 6C in the structures of the oxide 406c, the insulator 412, the conductor 404, and the insulator 408. FIG. 10A shows a top view of the transistor 490. FIG. 10B shows cross-sectional views taken along dashed-dotted line E1-E2 and dashed-dotted line E3-E4 in FIG. 10A. The transistor 490 in FIG. 10B includes the following components: the layer 625, the insulator 402 over the layer 625, the oxide 406a over the insulator 402, the oxide 406b over the oxide 406a, the conductor 416a and the conductor 416b over the oxide 406b, the oxide 406c in contact with a top surface of the oxide 406b, the insulator 412 over the oxide 406c, the conductor 404 over the insulator 412, the insulator 591 over the conductor 416a and the conductor 416b, and the insulator 408 over the insulator 591 and the conductor 404.

As illustrated in FIG. 10B, it is preferable that the insulator 412 be stacked over the oxide 406c and that the oxide 406c and the insulator 412 be formed along a side surface of an opening in the insulator 591. The conductor 404 is preferably formed such that the opening covered with the oxide 406c and the insulator 412 is filled. In addition, the conductor 404 is preferably formed over a region between the conductor 416a and the conductor 416b (a region in which the conductor 416a and the conductor 416b are spaced apart from each other) with the insulator 412 positioned between the conductor 404 and the region.

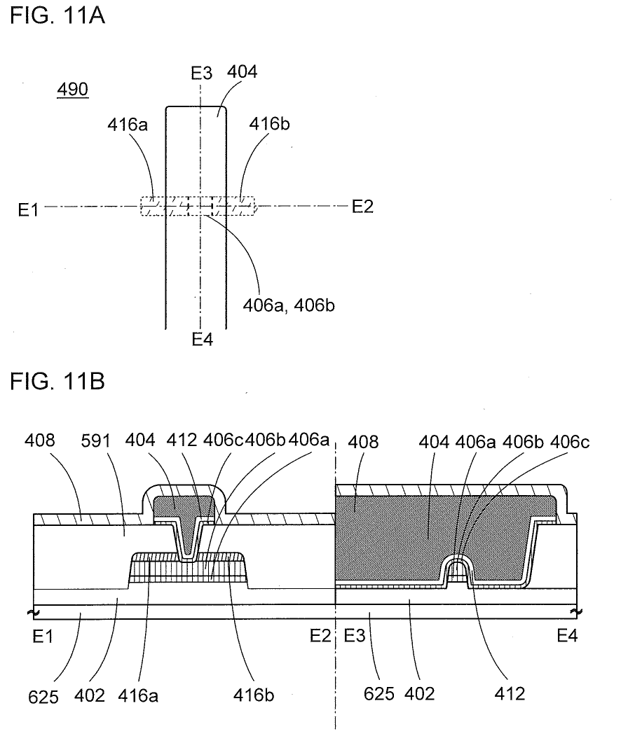

The transistor 490 in FIGS. 11A and 11B is different from that in FIGS. 10A and 10B in the structures of the oxide 406c, the insulator 412, and the conductor 404. FIG. 11A shows a top view of the transistor 490. FIG. 11B shows cross-sectional views taken along dashed-dotted line E1-E2 and dashed-dotted line E3-E4 in FIG. 11A. In the transistor 490 in FIG. 11B, the insulator 412 is stacked over the oxide 406c. The oxide 406c is formed in contact with the side surface of the opening in the insulator 591 and a top surface of the insulator 591. The conductor 404 is formed such that the opening covered with the oxide 406c and the insulator 412 is filled. The conductor 404 is also formed over the top surface of the insulator 591 with the oxide 406c and the insulator 412 positioned therebetween. The insulator 408 is formed in contact with a top surface of the conductor 404. The insulator 408 is preferably formed in contact with at least part of a side surface of the conductor 404.

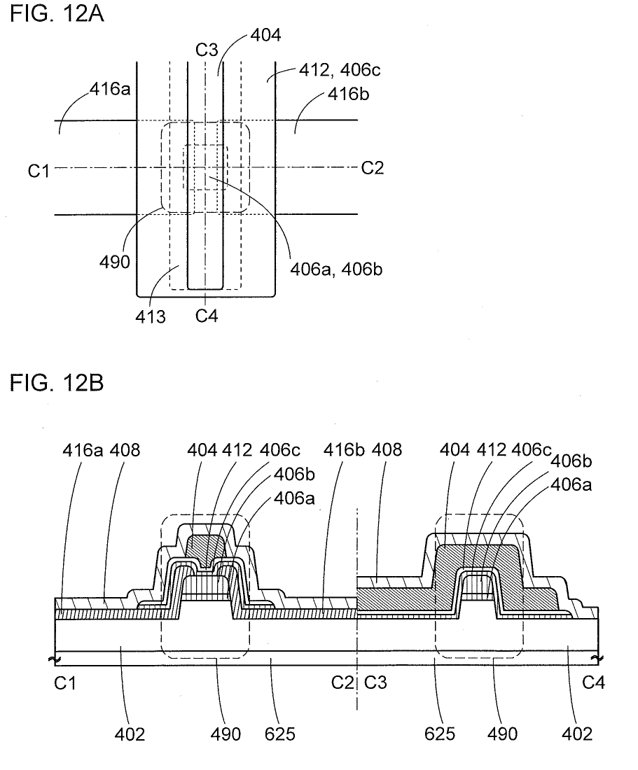

FIG. 12A is a top view of the transistor 490. FIG. 12B shows cross-sections taken along dashed-dotted line C1-C2 and dashed-dotted line C3-C4 in FIG. 12A.

The transistor 490 in FIG. 12B includes the insulator 402, the oxide 406a over the insulator 402, the oxide 406b over the oxide 406a, the conductor 416a and the conductor 416b which are in contact with side surfaces of the oxide 406a and a top surface and side surfaces of the oxide 406b, the oxide 406c in contact with side surfaces of the oxide 406a, the top surface and side surfaces of the oxide 406b, a top surface and side surfaces of the conductor 416a, and a top surface and side surfaces of the conductor 416b, the insulator 412 over the oxide 406c, and the conductor 404 over the insulator 412.

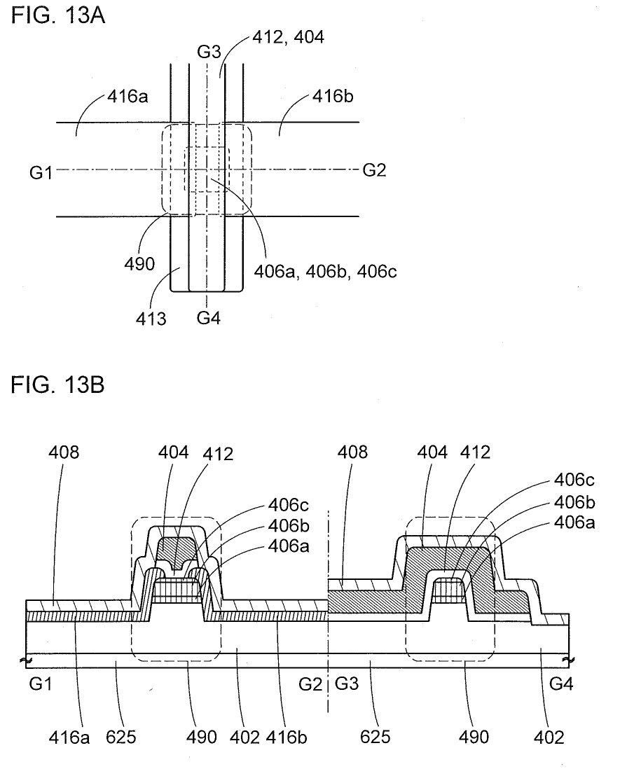

FIG. 13A is a top view of the transistor 490. FIG. 13B shows cross-sectional views taken along dashed-dotted line G1-G2 and dashed-dotted line G3-G4 in FIG. 13A.

The transistor 490 in FIGS. 13A and 13B includes the following components: the insulator 402, the oxide 406a over a projection of the insulator 402, the oxide 406b over the oxide 406a, the oxide 406c over the oxide 406b, the conductor 416a and the conductor 416b which are in contact with the oxides 406a, 406b, and 406c and are spaced apart from each other, the insulator 412 over the oxide 406c and the conductors 416a and 416b, the conductor 404 over the insulator 412, and the insulator 408 over the conductors 416a and 416b, the insulator 412, and the conductor 404.

The insulator 412 is in contact with at least side surfaces of the oxide 406b in the cross section G3-G4. In the cross section G3-G4, the conductor 404 faces the top surface and the side surfaces of the oxide 406b with at least the insulator 412 positioned therebetween.

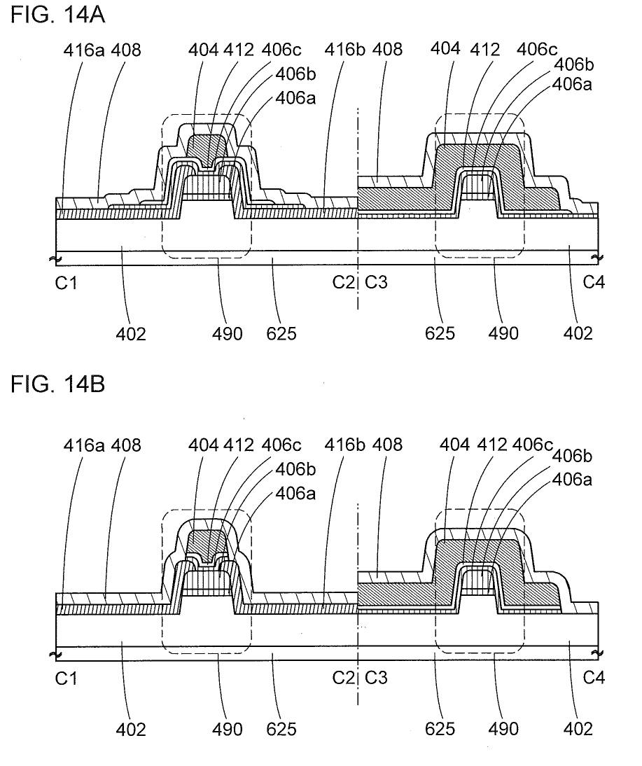

In the structures in FIGS. 6A to 6C and FIGS. 12A and 12B, an end portion of the oxide 406c and an end portion of the insulator 412 are substantially aligned with each other; as in the transistor 490 in FIG. 14A, however, the end portion of the oxide 406c and the end portion of the insulator 412 are not necessarily aligned with each other. As illustrated in FIG. 14B, the end portions of the oxide 406c and the insulator 412 may be substantially aligned with an end portion of the conductor 404.

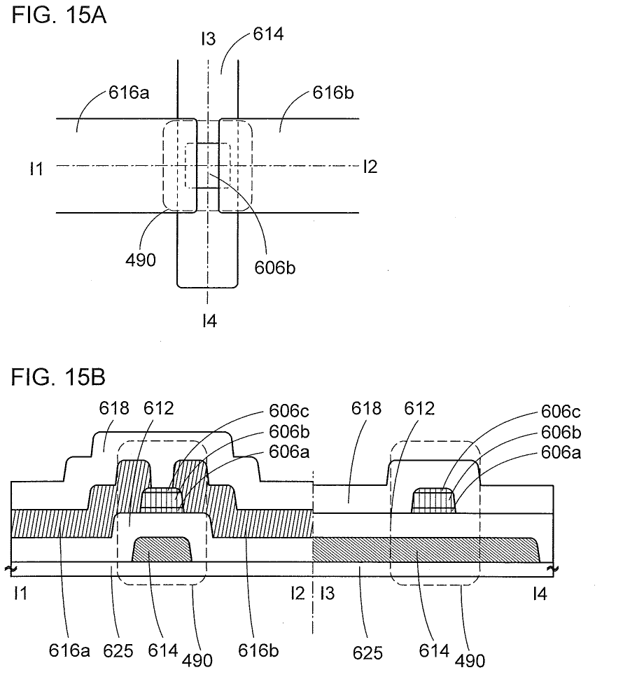

FIGS. 15A and 15B are a top view and a cross-sectional view, respectively, which illustrate the transistor 490 of one embodiment of the present invention. FIG. 15A is a top view, and FIG. 15B shows cross-sectional views taken along dashed-dotted line 11-12 and dashed-dotted line 13-14 in FIG. 15A. For simplification of the drawing, some components are not illustrated in the top view in FIG. 15A.

The transistor 490 in FIGS. 15A and 15B includes a conductive layer 614 over the layer 625, an insulator 612 over the conductive layer 614, a semiconductor 606a over the insulator 612, a semiconductor 606b over the semiconductor 606a, a semiconductor 606c over the semiconductor 606b, a conductive layer 616a and a conductive layer 616b which are in contact with the semiconductors 606a, 606b, and 606c and are spaced apart from each other, and an insulating film 618 over the semiconductor 606c and the conductive layers 616a and 616b. The conductive layer 614 faces a bottom surface of the semiconductor 606b with the insulator 612 positioned therebetween. The insulator 612 may have a projection. The semiconductor 606a is not necessarily provided. The insulating film 618 is not necessarily provided.

The semiconductor 606b functions as a channel formation region of the transistor 490. The conductive layer 614 functions as a first gate electrode (also referred to as a front gate electrode) of the transistor 490. The conductive layer 616a and the conductive layer 616b function as a source electrode and a drain electrode of the transistor 490.

The insulating film 618 is preferably an insulator containing excess oxygen.

For the conductive layer 614, refer to the description of the conductor 404. For the insulator 612, refer to the description of the insulator 412. For the semiconductor 606a, refer to the description of the oxide 406a. For the semiconductor 606b, refer to the description of the oxide 406b. For the semiconductor 606c, refer to the description of the oxide 406c. For the conductive layer 616a and the conductive layer 616b, refer to the description of the conductor 416a and the conductor 416b. For the insulating film 618, refer to the description of the insulator 402.

Thus, the transistor 490 in FIGS. 15A and 15B can be regarded as different from the transistor 490 in FIGS. 6A to 6C only in part of the structure. Specifically, the structure of the transistor 490 in FIGS. 15A and 15B is similar to the structure in FIGS. 6A to 6C except that the conductor 404 is not provided. Therefore, for the transistor 490 in FIGS. 15A and 15B, the description of the transistor 490 in FIGS. 6A to 6C can be referred to as appropriate.

The transistor 490 may include a conductor which overlaps with the semiconductor 606b with the insulating film 618 positioned therebetween. The conductor functions as a second gate electrode of the transistor 490. For the conductor, refer to the description of the conductor 413. Furthermore, an s-channel structure may be formed using the second gate electrode.

Over the insulating film 618, a display element may be provided. For example, a pixel electrode, a liquid crystal layer, a common electrode, a light-emitting layer, an organic EL layer, an anode, a cathode, or the like may be provided. The display element is connected to the conductive layer 616a, for example.

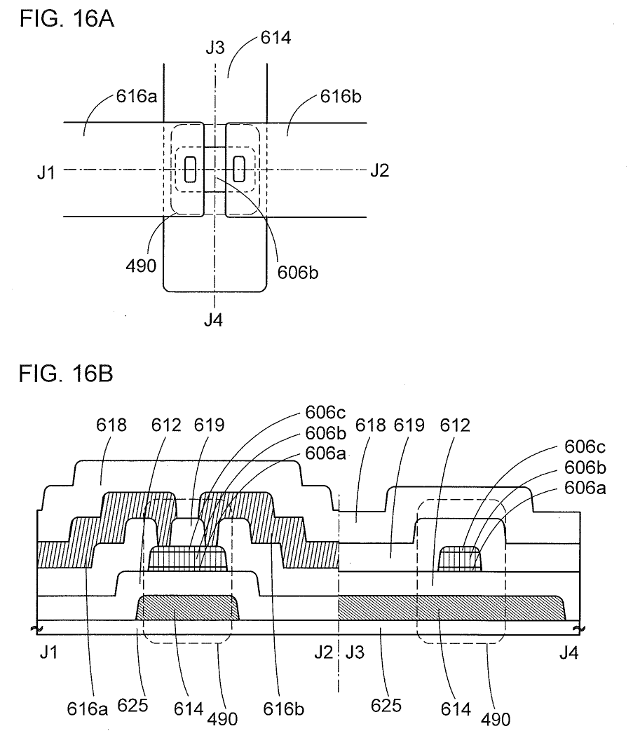

Over the semiconductor, an insulator that can function as a channel protective film may be provided. Alternatively, as illustrated in FIGS. 16A and 16B, an insulating film 619 may be provided between the semiconductor 606c and the conductive layers 616a and 616b. In this case, the conductive layer 616a (the conductive layer 616b) and the semiconductor 606c are connected to each other through an opening in the insulating film 619. For the insulating film 619, the description of the insulating film 618 may be referred to.

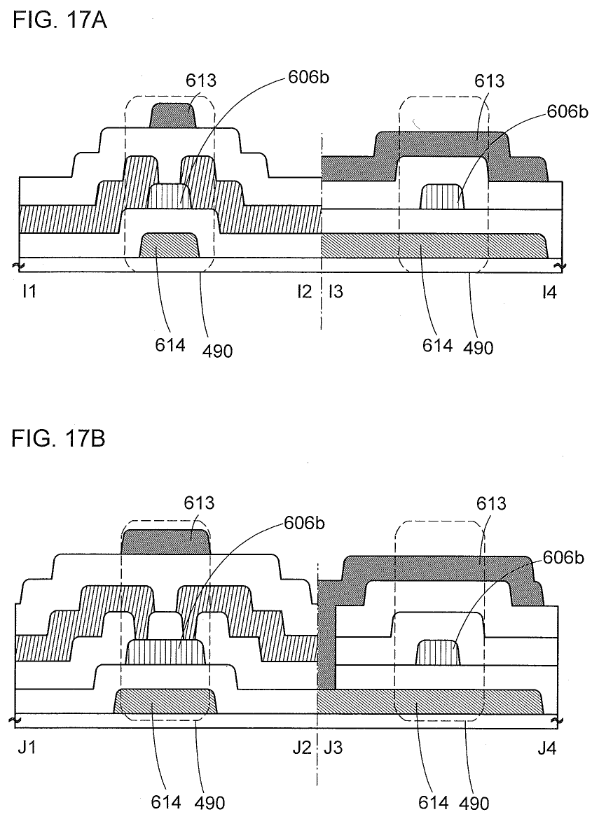

In FIG. 15B and FIG. 16B, a conductor 613 may be provided over the insulating film 618. FIGS. 17A and 17B illustrate examples of such a case. For the conductor 613, refer to the description of the conductor 413. A potential or signal supplied to the conductor 613 may be the same as or different from that supplied to the conductive layer 614. For example, the threshold voltage of the transistor 490 may be controlled by a constant potential supplied to the conductor 613. In other words, the conductor 613 can function as a second gate electrode.

In some cases, a bottom-gate transistor like the transistors in FIGS. 15A and 15B, FIGS. 16A and 16B, FIGS. 17A and 17B, and the like can be easily manufactured on a conventional manufacturing line for amorphous silicon, for example. In some cases, a top-gate transistor like the transistors in FIGS. 6A to 6C and the like can be easily manufactured on a conventional manufacturing line for low-temperature polysilicon or a conventional LSI manufacturing line, for example.

### <Method for Manufacturing Transistor 490>

A method for manufacturing the transistor 490 in FIGS. 8A to 8D will be described below.

First, the layer 100 is prepared. Next, the insulator 101 is deposited.

The insulator 101 can be deposited by a sputtering method, a chemical vapor deposition (CVD) method, a molecular beam epitaxy (MBE) method, a pulsed laser deposition (PLD) method, an atomic layer deposition (ALD) method, or the like.

Then, the insulator 103 is deposited. Any of the above-described insulators may be used as the insulator 103. The insulator 103 can be deposited by a sputtering method, a CVD method, an MBE method, a PLD method, an ALD method, or the like.

Next, a resist or the like is formed over the insulator 103, and an opening is formed in the insulator 103.

Next, a conductor to be the conductor 102 is deposited. Any of the above-described conductors can be used as the conductor to be the conductor 102. The conductor to be the conductor 102 can be deposited by a sputtering method, a CVD method, an MBE method, a PLD method, an ALD method, or the like.

Next, the conductor to be the conductor 102 over the insulator 103 is removed by CMP treatment. As a result, the conductor 102 remains only in the opening formed in the insulator 103.

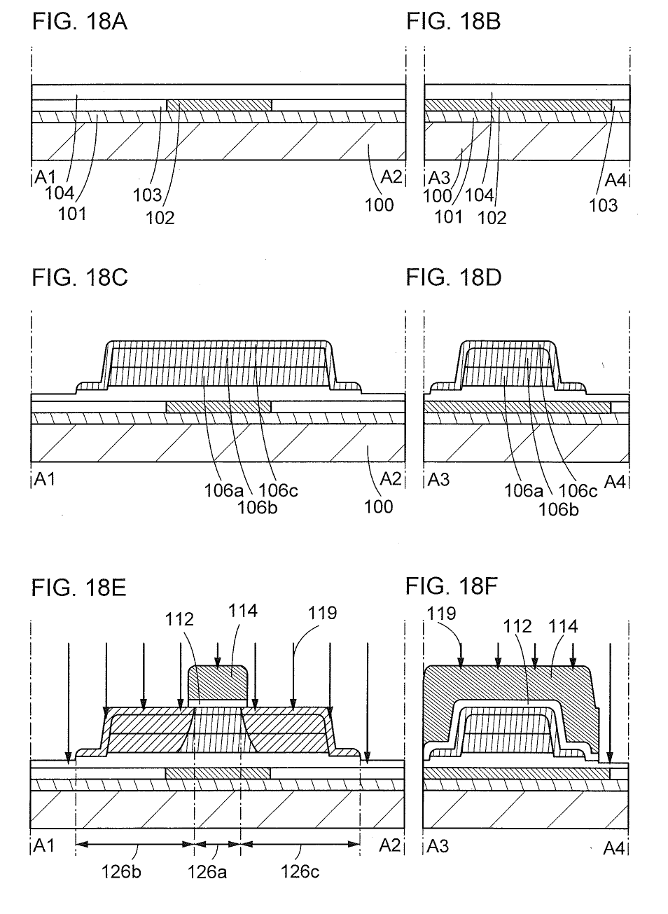

Then, the insulator 104 is deposited (see FIGS. 18A and 18B). Any of the above-described insulators may be used as the insulator 104. The insulator 104 can be deposited by a sputtering method, a CVD method, an MBE method, a PLD method, an ALD method, or the like.

Then, an insulator to be the oxide 106a in a later step is formed. As the insulator, any of insulators, semiconductors, and conductors which can be used as the oxide 406a may be used. The insulator can be deposited by a sputtering method, a CVD method, an MBE method, a PLD method, an ALD method, or the like.

The insulator to be the oxide 106a is deposited preferably by a sputtering method, further preferably by a sputtering method in an atmosphere containing oxygen. In the sputtering method, either a parallel-plate-type sputtering apparatus or a facing-target sputtering apparatus may be used. Deposition using a facing-target sputtering apparatus causes less damage to a formation surface and thus facilitates the formation of a film with high crystallinity in some cases. For this reason, a facing-target sputtering apparatus is preferably used for the deposition of a CAAC-OS described later in some cases.

Deposition using a parallel-plate-type sputtering apparatus can also be referred to as parallel electrode sputtering (PESP). Deposition using a facing-target sputtering apparatus can also be referred to as vapor deposition sputtering (VDSP).

During the deposition of the insulator to be the oxide 106a by a sputtering method, oxygen may be added to a surface of the insulator 104 (interface between the oxide 106a and the insulator 104 after the formation of the oxide 106a) and the vicinity thereof. Oxygen is added to the insulator 104 as an oxygen radical, for example; however, the state of oxygen at the time of being added is not limited thereto. Oxygen may be added to the insulator 104 as an oxygen atom, an oxygen ion, or the like. By adding oxygen to the insulator 104 in this manner, the insulator 104 can contain excess oxygen.

In a region in the vicinity of the interface between the insulator 104 and the insulator to be the oxide 106a, a mixed region is formed in some cases. The mixed region contains components of the insulator 104 and components of the insulator to be the oxide 106a.

Next, a semiconductor to be the oxide 106b in a later step is deposited. As the semiconductor, any of semiconductors which can be used as the oxide 406b may be used. The semiconductor can be deposited by a sputtering method, a CVD method, an MBE method, a PLD method, an ALD method, or the like. A PESP method or a VDSP method can also be employed. Note that successive deposition of the insulator to be the oxide 106a and the semiconductor to be the oxide 106b without exposure to the air can reduce entry of impurities into the films and their interface.

A mixed gas of oxygen and a rare gas such as argon (or helium, neon, krypton, xenon, or the like) is preferably used as the deposition gas. For example, the proportion of oxygen in the whole deposition gas may be less than 50 vol %, preferably less than or equal to 33 vol %, further preferably less than or equal to 20 vol %, still further preferably less than or equal to 15 vol %.

When deposition is performed by a sputtering method, the substrate temperature may be set high. A high substrate temperature can promote migration of sputtered particles over the top surface of the substrate. Thus, an oxide with higher density and higher crystallinity can be deposited. Note that the substrate temperature may be, for example, higher than or equal to 100° C. and lower than or equal to 450° C., preferably higher than or equal to 150° C. and lower than or equal to 400° C., further preferably higher than or equal to 170° C. and lower than or equal to 350° C.

Next, heat treatment is preferably performed. The heat treatment can reduce the hydrogen concentration in the oxide 106a and the oxide 106b formed in later steps in some cases. The heat treatment can also reduce oxygen vacancies in the oxide 106a and the oxide 106b formed in later steps in some cases. The heat treatment may be performed at a temperature higher than or equal to 250° C. and lower than or equal to 650° C., preferably higher than or equal to 450° C. and lower than or equal to 600° C., further preferably higher than or equal to 520° C. and lower than or equal to 570° C. The heat treatment is performed in an inert gas atmosphere or an atmosphere containing an oxidation gas at 10 ppm or more, 1% or more, or 10% or more. The heat treatment may be performed under a reduced pressure. Alternatively, the heat treatment may be performed in the following manner: heat treatment is performed in an inert gas atmosphere, and then, another heat treatment is performed in an atmosphere containing an oxidation gas at 10 ppm or more, 1% or more, or 10% or more in order to compensate desorbed oxygen. The heat treatment can increase the crystallinity of the oxide 106a and the oxide 106b formed in later steps and remove impurities such as hydrogen and water, for example. As the heat treatment, lamp heating can be performed with an RTA apparatus.

By the heat treatment, oxygen can be supplied from the insulator 104 to the insulator to be the oxide 106a and the semiconductor to be the oxide 106b. By the heat treatment performed on the insulator 104, oxygen can be supplied to the insulator to be the oxide 106a and the semiconductor to be the oxide 106b very easily.

Here, the insulator 101 functions as a barrier film that blocks oxygen. The insulator 101 provided under the insulator 104 can prevent oxygen diffused into the insulator 104 from being diffused into a layer below the insulator 104.

Oxygen is supplied to the insulator to be the oxide 106a and the semiconductor to be the oxide 106b in this manner to reduce oxygen vacancies, whereby a highly purified intrinsic or substantially highly purified intrinsic oxide semiconductor with a low density of defect states can be obtained.

Furthermore, high-density plasma treatment or the like may be performed. High-density plasma may be generated using microwaves. For the high-density plasma treatment, an oxidation gas such as oxygen or nitrous oxide may be used, for example. Alternatively, a mixed gas of an oxidation gas and a rare gas such as He, Ar, Kr, or Xe may be used. In the high-density plasma treatment, a bias may be applied to the substrate, in which case oxygen ions or the like in the plasma can be attracted to the substrate side. The high-density plasma treatment may be performed while the substrate is heated. In the case where the high-density plasma treatment is performed instead of the heat treatment, for example, an effect similar to that of the heat treatment can be obtained at lower temperatures. The high-density plasma treatment may be performed before the deposition of the insulator to be the oxide 106a, after the deposition of the insulator 112, or after the deposition of the insulator 116, for example.

Then, a resist or the like is formed over the semiconductor to be the oxide 106b and processing is performed using the resist or the like, whereby the oxide 106a and the oxide 106b are formed. As illustrated in FIGS. 18C and 18D, an exposed surface of the insulator 104 is removed at the time of the formation of the oxide 106b in some cases.

Then, an insulator to be the oxide 106c in a later step is deposited. As the insulator, any of the above-described insulators, semiconductors, and conductors may be used. The insulator can be deposited by a sputtering method, a CVD method, an MBE method, a PLD method, an ALD method, or the like. A PESP method or a VDSP method can also be employed.

Then, a resist or the like is formed over the insulator to be the oxide 106c and processing is performed using the resist or the like, whereby the oxide 106c is formed (see FIGS. 18C and 18D). As illustrated in FIGS. 18C and 18D, an exposed surface of the insulator 104 is removed at the time of the formation of the oxide 106c in some cases.

Next, an insulator to be the insulator 112 in a later step is deposited. As the insulator, any of insulators which can be used as the insulator 412 may be used. The insulator can be deposited by a sputtering method, a CVD method, an MBE method, a PLD method, an ALD method, or the like. For example, the insulator 112 may be deposited by an ALD method at a deposition substrate temperature higher than or equal to 400° C. and lower than or equal to 520° C., preferably higher than or equal to 450° C. and lower than or equal to 500° C. Deposition at high substrate temperatures allows a reduction in the concentration of impurities contained in the insulator 112. For example, since a carbon compound, water, or the like contained in a deposition gas or a deposition chamber can be reduced, the concentration of carbon and/or hydrogen can be reduced. Deposition at high substrate temperatures also allows an increase in the density (or film density) of the insulator 112. An increase in the density of the insulator 112 can reduce the density of defect states in the insulator 112; thus, a manufactured transistor can have stable electrical characteristics.

Next, a conductor to be the conductor 114 in a later step is deposited. As the conductor, any of conductors that can be used as the conductor 404 may be used. The conductor can be deposited by a sputtering method, a CVD method, an MBE method, a PLD method, an ALD method, or the like.

Then, a resist or the like is formed over the conductor that can be used as the conductor 114 and processing is performed using the resist or the like, whereby the insulator 112 and the conductor 114 are formed (see FIGS. 18E and 18F). Here, after the insulator 112 and the conductor 114 are formed such that the side end portion of the conductor 114 in the channel length direction is substantially aligned with the side end portion of the insulator 112 in the channel length direction, only the conductor 114 may be selectively etched by wet etching or the like using the same mask. When such etching is performed, as in the transistor 490 in FIGS. 9C and 9D, the width of the conductor 114 in the channel length direction can be smaller than the width of the insulator 112 in the channel length direction.

Next, a dopant 119 is added to the oxide 106a, the oxide 106b, and the oxide 106c with the use of the conductor 114 and the insulator 112 as masks (see FIGS. 18E and 18F). As a result, the region 126a, the region 126b, and the region 126c are formed in the oxide 106a, the oxide 106b, and oxide 106c. Thus, the concentration of the dopant 119 measured in SIMS analysis is higher in the region 126b and the region 126c than in the region 126a. For the addition of the dopant 119, an ion implantation method by which an ionized source gas is subjected to mass separation and then added, an ion doping method by which an ionized source gas is added without mass separation, a plasma immersion ion implantation method, or the like can be used. In the case where mass separation is performed, ion species to be added and its concentration can be strictly controlled. In contrast, in the case where mass separation is not performed, ions can be added at a high concentration in a short time. Alternatively, an ion doping method in which atomic or molecular clusters are generated and ionized may be employed. Instead of the term “dopant,” the term “ion,” “donor,” “acceptor,” “impurity,” or “element” may be used.

The addition step of the dopant 119 may be controlled by appropriately setting the implantation conditions such as the acceleration voltage and the dose. The dose of the dopant 119 may be greater than or equal to 1×10¹² ions/cm² and less than or equal to 1×10¹⁶ ions/cm², preferably greater than or equal to 1×10¹³ ions/cm² and less than or equal to 1×10¹⁵ ions/cm². The acceleration voltage at which the dopant 119 is introduced may be higher than or equal to 2 kV and lower than or equal to 50 kV, preferably higher than or equal to 5 kV and lower than or equal to 30 kV.

Examples of the dopant 119 include hydrogen, helium, neon, argon, krypton, xenon, nitrogen, fluorine, phosphorus, chlorine, arsenic, boron, magnesium, aluminum, silicon, titanium, vanadium, chromium, nickel, zinc, gallium, germanium, yttrium, zirconium, niobium, molybdenum, indium, tin, lanthanum, cerium, neodymium, hafnium, tantalum, and tungsten. Among these elements, helium, neon, argon, krypton, xenon, nitrogen, fluorine, phosphorus, chlorine, arsenic, and boron are preferable because these elements can be added relatively easily by an ion implantation method, an ion doping method, a plasma immersion ion implantation method, or the like.

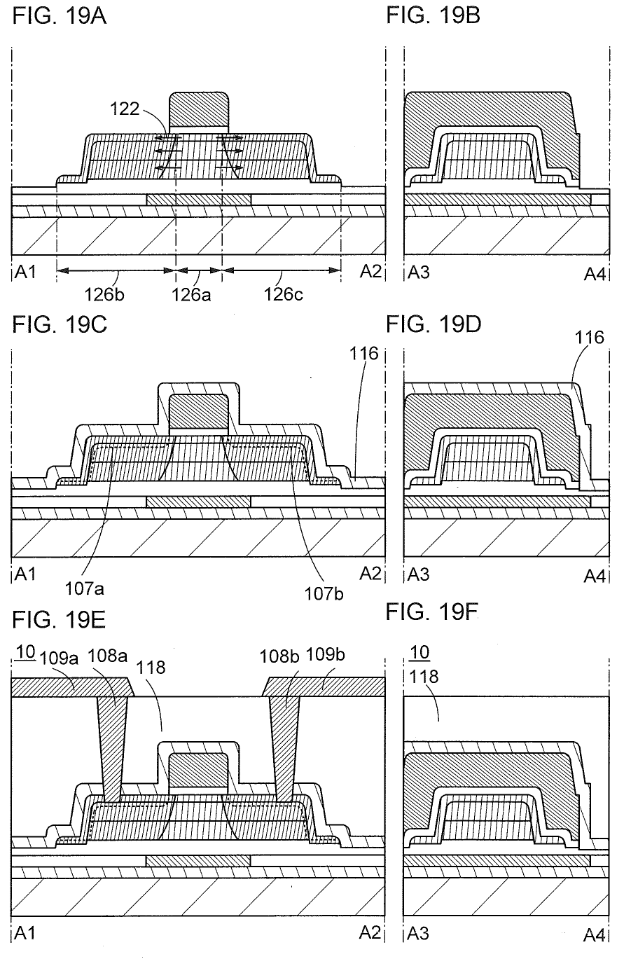

After the addition treatment of the dopant 119, heat treatment may be performed. The heat treatment may be performed, for example, at a temperature higher than or equal to 250° C. and lower than or equal to 650° C., preferably higher than or equal to 350° C. and lower than or equal to 450° C., in a nitrogen atmosphere or the air (ultra dry air) or under reduced pressure. In the case where oxygen vacancies are formed in the regions 126b and 126c by the addition of the dopant 119, for example, subsequent heat treatment can cause gettering of hydrogen 122 around the regions 126b and 126c at the sites of the oxygen vacancies (see FIGS. 19A and 19B). The donor level formed in this manner is stable, and thus, the resistance is hardly increased later.

Then, the insulator 116 is formed (see FIGS. 19C and 19D).

Next, heat treatment is preferably performed. By the heat treatment, oxygen can be supplied from the insulator 104 or the like to the oxide 106a, the oxide 106b, and the oxide 106c. Since the oxide 106a, the oxide 106b, and the oxide 106c are surrounded by the insulator 101 and the insulator 116 each having a function of blocking oxygen, outward diffusion of oxygen can be prevented. Accordingly, oxygen can be effectively supplied to the oxide 106a, the oxide 106b, and the oxide 106c, especially to a channel formation region in the oxide 106b. In this manner, oxygen is supplied to the oxide 106a, the oxide 106b, and the oxide 106c to reduce oxygen vacancies, whereby a highly purified intrinsic or substantially highly purified intrinsic oxide semiconductor with a low density of defect states can be obtained.

Subsequently, the insulator 118 is deposited. Then, a resist or the like is formed over the insulator 118, and openings are formed in the insulator 118, the insulator 116, and the oxide 106c. After that, a conductor to be the conductor 108a and the conductor 108b is deposited. As the conductor to be the conductor 108a and the conductor 108b, any of the above-described conductors can be used. The conductor can be deposited by a sputtering method, a CVD method, an MBE method, a PLD method, an ALD method, or the like.

Next, the conductor to be the conductor 108a and the conductor 108b over the insulator 118 is removed by CMP treatment. As a result, the conductor 108a and the conductor 108b are formed only in the openings formed in the insulator 118, the insulator 116, and the oxide 106c.

Subsequently, a conductor to be the conductor 109a and the conductor 109b is deposited over the insulator 118, the conductor 108a, and the conductor 108b. As the conductor to be the conductor 109a and the conductor 109b, any of the above-described conductors can be used. The conductor can be deposited by a sputtering method, a CVD method, an MBE method, a PLD method, an ALD method, or the like.

Next, a resist or the like is formed over the conductor to be the conductor 109a and the conductor 109b, and the conductor is processed using the resist or the like; thus, the conductor 109a and the conductor 109b are formed (see FIGS. 19E and 19F).

### [Semiconductor Device]

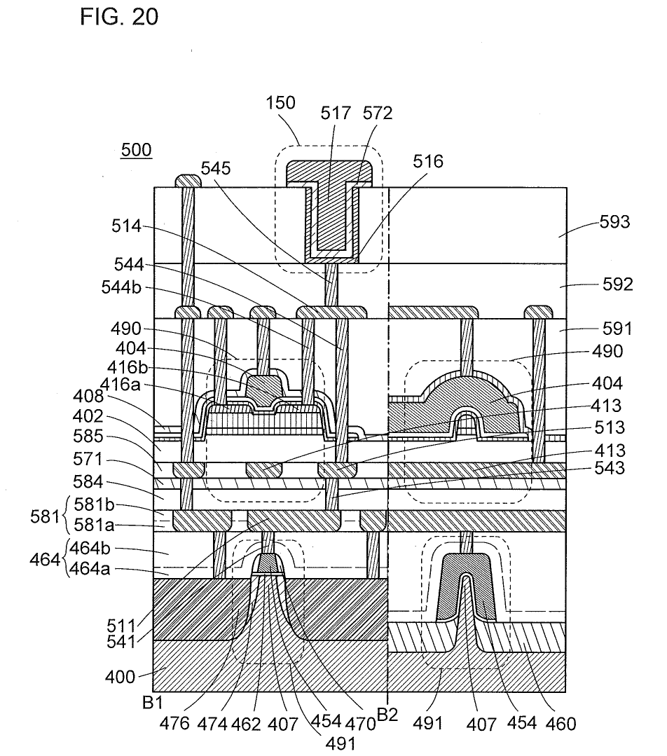

FIG. 20 shows an example of a cross-sectional view of a semiconductor device 500. The semiconductor device 500 in FIG. 20 includes the transistor 490 and a transistor 491.

The semiconductor device 500 includes a substrate 400, the transistor 491 over the substrate 400, an insulator 464 over the transistor 491, and plugs such as a plug 541. The plug 541 or the like is connected to, for example, a gate electrode, a source electrode, or a drain electrode of the transistor 491.

The details of the transistor 491 will be described later.

The semiconductor device 500 includes an insulator 581 over the insulator 464, an insulator 584 over the insulator 581, the insulator 571 over the insulator 584, the insulator 585 over the insulator 571, a conductor 511 and the like over the insulator 464, a plug 543 and the like connected to the conductor 511 and the like, and a conductor 513 over the insulator 571. As illustrated in FIG. 20, the insulator 464 may have a two-layer structure of an insulator 464a and an insulator 464b over the insulator 464a. As illustrated in FIG. 20, the insulator 581 may have a two-layer structure of an insulator 581a and an insulator 581b over the insulator 581a.

The semiconductor device 500 may include the conductor 413.

The semiconductor device 500 includes the transistor 490 and plugs such as a plug 544 and the plug 544b over the insulator 571. The plugs such as the plug 544 and the plug 544b are connected to the conductor 513 and a gate electrode, a source electrode, and a drain electrode of the transistor 490.

The semiconductor device 500 includes an insulator 592, conductors such as the conductor 514, and plugs such as a plug 545 over the insulator 591. The plug 545 and the like are connected to the conductors such as the conductor 514.

The semiconductor device 500 includes a capacitor 150 and an insulator 593 over the insulator 592. The capacitor 150 includes a conductor 516, a conductor 517, and an insulator 572. The insulator 572 includes a region positioned between the conductor 516 and the conductor 517. The conductor 516 is formed in an opening provided in the insulator 593, the insulator 572 is formed over the conductor 516 and the insulator 593, and the conductor 517 is formed over the insulator 572 such that the opening is filled.

As the insulator 464, for example, silicon oxide, silicon oxynitride, silicon nitride oxide, silicon nitride, aluminum oxide, aluminum oxynitride, aluminum nitride oxide, or aluminum nitride may be used.

The insulator 464 can be formed by a sputtering method, a CVD method (including a thermal CVD method, an MOCVD method, a PECVD method, and the like), an MBE method, an ALD method, a PLD method, or the like. In particular, the insulator is deposited preferably by a CVD method, further preferably by a plasma CVD method, because coverage can be improved. To reduce plasma damage, a thermal CVD method, an MOCVD method, or an ALD method is preferably used.

Alternatively, the insulator 464 can be formed using silicon carbonitride, silicon oxycarbide, or the like. Alternatively, undoped silicate glass (USG), boron phosphorus silicate glass (BPSG), borosilicate glass (BSG), or the like can be used. USG, BPSG, and the like may be formed by an atmospheric pressure CVD method. Alternatively, for example, hydrogen silsesquioxane (HSQ) may be applied by a coating method.

The insulator 464 may have a single-layer structure or a stacked-layer structure of a plurality of materials.

In FIG. 20, the insulator 464 includes two layers, i.e., the insulator 464a and the insulator 464b over the insulator 464a.

It is preferable that the insulator 464a strongly adhere to or well cover a region 476, a conductor 454, and the like of the transistor 491.

As an example of the insulator 464a, silicon nitride formed by a CVD method can be used. Here, the insulator 464a preferably contains hydrogen in some cases. When the insulator 464a contains hydrogen, defects or the like in the substrate 400 are reduced and characteristics of the transistor 491 and the like are improved in some cases. For example, in the case where the substrate 400 is formed using a material containing silicon, a defect such as a dangling bond of silicon can be terminated with hydrogen.

The parasitic capacitance formed between a conductor under the insulator 464a and a conductor over the insulator 464b, for example, between the conductor 454 and the conductor 511, is preferably small. Thus, the insulator 464b preferably has a low dielectric constant. The dielectric constant of the insulator 464b is preferably lower than that of an insulator 462. The dielectric constant of the insulator 464b is preferably lower than that of the insulator 464a. As an example, the insulator 464b can be formed using USG.

As the insulator 584 and the insulator 585, for example, silicon oxide, silicon oxynitride, silicon nitride oxide, silicon nitride, aluminum oxide, aluminum oxynitride, aluminum nitride oxide, or aluminum nitride may be used.

The insulator 584 and the insulator 585 can be formed by a sputtering method, a CVD method (including a thermal CVD method, an MOCVD method, a PECVD method, and the like), an MBE method, an ALD method, a PLD method, or the like. In particular, the insulators are deposited preferably by a CVD method, further preferably by a plasma CVD method, because coverage can be improved. To reduce plasma damage, a thermal CVD method, an MOCVD method, or an ALD method is preferably used.

Alternatively, the insulator 584 and the insulator 585 can be formed using silicon carbide, silicon carbonitride, silicon oxycarbide, or the like. Alternatively, undoped silicate glass (USG), boron phosphorus silicate glass (BPSG), borosilicate glass (BSG), or the like can be used. USG, BPSG, and the like may be formed by an atmospheric pressure CVD method. Alternatively, for example, hydrogen silsesquioxane (HSQ) may be applied by a coating method.

Each of the insulators 584 and 585 may have a single-layer structure or a stacked-layer structure of a plurality of materials.

For the insulator 581, the description of the insulator 464 may be referred to. The insulator 581 may have a stacked-layer structure of a plurality of layers. For example, the insulator 581 may have a two-layer structure of the insulator 581a and the insulator 581b over the insulator 581a as illustrated in FIG. 20. For the insulator 581a and the insulator 581b, for example, the description of the insulator 464a and the insulator 464b may be referred to.

A conductive material such as a metal material, an alloy material, or a metal oxide material can be used as a material of the conductor 511, the conductor 513, the conductor 413, the plug 543, and the like. For example, a single-layer structure or a stacked-layer structure of a metal such as aluminum, titanium, chromium, nickel, copper, yttrium, zirconium, niobium, molybdenum, silver, tantalum, or tungsten, or an alloy containing the metal as a main component can be used. Alternatively, a metal nitride such as tungsten nitride, molybdenum nitride, titanium nitride, or tantalum nitride can be used.

The conductors such as the conductor 511 and the conductor 513 preferably function as wirings of the semiconductor device 500. Therefore, these conductors are also referred to as wirings or wiring layers in some cases. These conductors are preferably connected to each other through a plug such as the plug 543.

The insulator 571 is preferably formed using an insulating material with low permeability to an impurity. The insulator 571 preferably has low oxygen permeability, for example. The insulator 571 preferably has low hydrogen permeability, for example. The insulator 571 preferably has low water permeability, for example.

As the insulator 571, for example, a single-layer structure or a stacked-layer structure including aluminum oxide, hafnium oxide, tantalum oxide, zirconium oxide, lead zirconate titanate (PZT), strontium titanate (SrTiO₃), (Ba,Sr)TiO₃ (BST), silicon nitride, or the like can be used. Alternatively, for example, aluminum oxide, bismuth oxide, germanium oxide, niobium oxide, silicon oxide, titanium oxide, tungsten oxide, yttrium oxide, zirconium oxide, or gallium oxide may be added to the insulator. Alternatively, the insulator may be subjected to nitriding treatment to be an oxynitride film. Silicon oxide, silicon oxynitride, or silicon nitride may be stacked over the above insulator. Aluminum oxide is particularly preferable because of its excellent barrier property against water or hydrogen.

The insulator 571 may be a stack of a layer containing a material with low permeability to water or hydrogen and a layer containing another insulating material. The insulator 571 may be, for example, a stack of a layer containing silicon oxide or silicon oxynitride and a layer containing a metal oxide.

The insulator 571 in the semiconductor device 500 can prevent an element contained in a material of a layer under the insulator 571 from being diffused into a layer over the insulator 571, for example. Specifically, the insulator 571 can prevent hydrogen, water, or the like contained in a material of a layer under the insulator 571 from being diffused into the transistor 490. In the case where the transistor 490 includes an oxide semiconductor, for example, the deterioration in characteristics of the transistor can be suppressed in some cases by suppressing the diffusion of hydrogen into the oxide semiconductor.

The transistor 490 includes the oxide 406. The oxide 406 includes a semiconductor material. Examples of the semiconductor material are oxide semiconductor materials, semiconductor materials such as silicon, germanium, gallium, and arsenic, compound semiconductor materials containing silicon, germanium, gallium, arsenic, aluminum, or the like, and organic semiconductor materials. In particular, the oxide 406 preferably includes an oxide semiconductor.

The insulator 402 may be formed to have a single-layer structure or a stacked-layer structure including, for example, silicon oxide, silicon oxynitride, silicon nitride oxide, silicon nitride, aluminum oxide, aluminum oxynitride, aluminum nitride oxide, aluminum nitride, or the like. The insulator 402 can be formed by a sputtering method, a CVD method (including a thermal CVD method, an MOCVD method, a PECVD method, and the like), an MBE method, an ALD method, a PLD method, or the like. In particular, the insulator is deposited preferably by a CVD method, further preferably by a plasma CVD method, because coverage can be improved. To reduce plasma damage, a thermal CVD method, an MOCVD method, or an ALD method is preferably used.

The insulator 402 may include a charge trapping layer. For example, the insulator 402 may have a structure in which a first insulator, a second insulator, and a third insulator are stacked in this order, and the second insulator may be formed using hafnium oxide, aluminum oxide, tantalum oxide, aluminum silicate, or the like to serve as a charge trapping layer. As the first insulator and the third insulator, for example, silicon oxide, silicon oxynitride, silicon nitride oxide, silicon nitride, aluminum oxide, aluminum oxynitride, aluminum nitride oxide, or aluminum nitride can be used. The threshold voltage of the transistor can be changed by injecting electrons into the second insulator. For example, the tunnel effect may be utilized to inject electrons into the second insulator. By applying positive voltage to the conductor 413, tunnel electrons can be injected into the second insulator.

The insulator 402 can be formed using a material and a method similar to those of the insulator 464 or the like. Furthermore, the hydrogen concentration in the insulator 402 is preferably reduced in order to prevent an increase of the hydrogen concentration in the oxide 406. Specifically, the hydrogen concentration in the insulator 402, which is measured by SIMS, is lower than or equal to 2×10²⁰ atoms/cm³, preferably lower than or equal to 5×10¹⁹ atoms/cm³, further preferably lower than or equal to 1×10¹⁹ atoms/cm³, still further preferably lower than or equal to 5×10¹⁸ atoms/cm³. Furthermore, the nitrogen concentration in the insulator 402 is preferably reduced in order to prevent an increase in the nitrogen concentration in the oxide 406. Specifically, the nitrogen concentration in the insulator 402, which is measured by SIMS, is lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×1017 atoms/cm³.

The insulator 402 is preferably formed using an insulator from which oxygen is released by heating (also referred to as “insulator containing excess oxygen”). Specifically, it is preferable to use an insulator with the following characteristics: the amount of oxygen that is released from the insulator in TDS analysis and converted into oxygen atoms is 1.0×10¹⁸ atoms/cm³ or more, preferably 3.0×1020 atoms/cm³ or more.

The insulator containing excess oxygen can be formed by treatment for adding oxygen to an insulator. Oxygen can be added by heat treatment in an oxygen atmosphere or with an ion implantation apparatus, an ion doping apparatus, or a plasma treatment apparatus. As a gas for adding oxygen, an oxygen gas of ¹⁶O₂, ¹⁸O₂, or the like, a nitrous oxide gas, an ozone gas, or the like can be used. In this specification, the treatment for adding oxygen is also referred to as oxygen doping treatment. The treatment for adding oxygen may be performed between the deposition of the insulator 402 and the deposition of the film to be the oxide 406a, for example. High-density plasma treatment or the like may also be performed. High-density plasma may be generated using microwaves. For the high-density plasma treatment, an oxidation gas such as oxygen or nitrous oxide may be used, for example. Alternatively, a mixed gas of an oxidation gas and a rare gas such as He, Ar, Kr, or Xe may be used. In the high-density plasma treatment, a bias may be applied to the substrate, in which case oxygen ions or the like in the plasma can be attracted to the substrate side. The high-density plasma treatment may be performed while the substrate is heated. In the case where the high-density plasma treatment is performed instead of the heat treatment, for example, an effect similar to that of the heat treatment can be obtained at lower temperatures. The high-density plasma treatment may be performed between the deposition of the insulator 402 and the deposition of the film to be the oxide 406a, for example.

For example, the deposition of the insulator 402 and the high-density plasma treatment are successively performed without exposure to the air with the use of a multi-chamber apparatus including a treatment chamber for the deposition of the insulator 402, a treatment chamber for the high-density plasma treatment, and a substrate transfer chamber for substrate transfer between the chambers, which is preferable for the following reasons. Entry of impurities into the film and the interface can be reduced. Shorter process time may lead to cost reduction. Moreover, since the process can be simplified, the yield may be improved. Note that the atmosphere in the substrate transfer chamber is preferably a reduced-pressure atmosphere.

In a similar manner, for example, a multi-chamber apparatus including a treatment chamber for the deposition of the insulator 402, a treatment chamber for the deposition of the film to be the oxide 406a, a treatment chamber for the deposition of the film to be the oxide 406b, a treatment chamber for the high-density plasma treatment, and a substrate transfer chamber for substrate transfer between the treatment chambers is preferably used because the deposition of the insulator 402, the high-density plasma treatment, the deposition of the fihn to be the oxide 406a, and the deposition of the film to be the oxide 406b can be successively performed without exposure to the air.

The insulator 402 preferably has a thickness greater than or equal to 1 nm and less than or equal to 50 nm, further preferably greater than or equal to 3 nm and less than or equal to 30 nm, still further preferably greater than or equal to 5 nm and less than or equal to 10 nm. After the oxide 106c is formed, oxygen doping treatment may be performed. After the formation of the insulator 402, oxygen doping treatment may be performed. Furthermore, heat treatment may be performed after the formation of the insulator 402. In this embodiment, for example, silicon oxide is formed as the insulator 402.

The conductor 416a and the conductor 416b preferably function as a source electrode and a drain electrode of the transistor 490. The conductor 404 preferably functions as a gate electrode of the transistor 490. The conductor 413 may also function as a gate electrode of the transistor 490. For example, the conductor 404 may function as a first gate electrode, and the conductor 413 may function as a second gate electrode.

For example, the material of the conductor 511 or the like can be used for the conductor 416a and the conductor 416b.

In the case where a material that is easily bonded to oxygen, such as tungsten or titanium, is used for the conductor 416a and the conductor 416b, an oxide of the material may be formed, so that oxygen vacancies in the oxide 406 are increased in and near a region in which the oxide 406 is in contact with the conductor 416a and the conductor 416b in some cases. When hydrogen is bonded to an oxygen vacancy, the carrier density is increased and the resistivity is decreased in the region.

The semiconductor device 500 of one embodiment of the present invention preferably has the following structure: an element and a compound which are included in a plug, a wiring, or the like and may cause deterioration in characteristics of a semiconductor element are prevented from being diffused into the semiconductor element.

The material of the insulator 571 can be used for the insulator 408. It is preferable that excess oxygen be supplied to an interface between the insulator 408 and a film under the insulator 408 and to the vicinity of the interface when the insulator 408 is deposited.

When the insulator 571 and the insulator 408 are formed using a material with low oxygen permeability, diffusion of oxygen from the transistor 490 to the outside (e.g., diffusion of oxygen into a layer under the insulator 571 or a layer over the insulator 408) can be suppressed. Accordingly, oxygen can be efficiently supplied to the transistor 490 in some cases. For example, in the case where the transistor 490 includes an oxide semiconductor, easy supply of oxygen to the oxide semiconductor may improve transistor characteristics.

### <Transistor 491>

Next, the transistor 491 will be described.

The transistor 491 includes a channel formation region 407, the insulator 462 over the substrate 400, the conductor 454 over the insulator 462, an insulating film 470 in contact with a side surface of the conductor 454, the region 476 which is positioned in the substrate 400 and overlaps with neither the conductor 454 nor the insulating film 470, and a region 474 which overlaps with the insulating film 470. The region 476 is a low-resistance layer and preferably functions as a source region or a drain region of the transistor 491. The region 474 preferably functions as a lightly doped drain (LDD) region.

The transistor 491 may be either a p-channel transistor or an n-channel transistor, and an appropriate transistor may be used depending on the circuit configuration or the driving method.

The substrate 400 preferably contains, for example, a semiconductor such as a silicon-based semiconductor, further preferably single crystal silicon. Alternatively, the substrate 400 may contain germanium (Ge), silicon germanium (SiGe), gallium arsenide (GaAs), gallium aluminum arsenide (GaAlAs), or the like. Alternatively, silicon having crystal lattice distortion may be used. Alternatively, the transistor 491 may be a high-electron-mobility transistor (HEMT) including GaAs and AlGaAs, for example.

The region 476 preferably contains an element that imparts n-type conductivity, such as phosphorus, or an element that imparts p-type conductivity, such as boron.

The conductor 454 can be formed using a semiconductor material such as silicon containing an element that imparts n-type conductivity (e.g., phosphorus) or an element that imparts p-type conductivity (e.g., boron), or a conductive material such as a metal material, an alloy material, or a metal oxide material. It is preferable to use a high-melting-point material which has both heat resistance and conductivity, such as tungsten or molybdenum, and it is particularly preferable to use tungsten.

The transistor 491 in FIG. 20 is an example in which element isolation is performed by a shallow trench isolation (STI) method or the like. Specifically, in FIG. 20, the transistor 491 is electrically isolated by element isolation using an element isolation region 460 formed in the following manner: an insulator containing silicon oxide or the like is embedded in a trench formed in the substrate 400 by etching or the like, and then, the insulator is partly removed by etching or the like.

In a projection of the substrate 400 which is positioned in a region other than the trench, the region 476, the region 474, and the channel formation region 407 of the transistor 491 are provided. Furthermore, the transistor 491 includes the insulator 462 which covers the channel formation region 407 and the conductor 454 which overlaps with the channel formation region 407 with the insulator 462 positioned therebetween.

In the transistor 491, a side portion and a top portion of the projection in the channel formation region 407 overlap with the conductor 454 with the insulator 462 positioned therebetween, so that carriers flow in a wide area including the side portion and the top portion of the channel formation region 407. Thus, the number of carriers transferred in the transistor 491 can be increased while the area over the substrate occupied by the transistor 491 is reduced. As a result, the on-state current and field-effect mobility of the transistor 491 are increased. Suppose the length of the projection in the channel width direction (channel width) in the channel formation region 407 is W, and the thickness of the projection in the channel formation region 407 is T. When the aspect ratio (T/W) of the thickness T to the channel width W is high, a region in which carriers flow becomes larger. Thus, the on-state current and field-effect mobility of the transistor 491 can be further increased.

When the transistor 491 is formed using a bulk semiconductor substrate, the aspect ratio is desirably 0.5 or more, further desirably 1 or more.

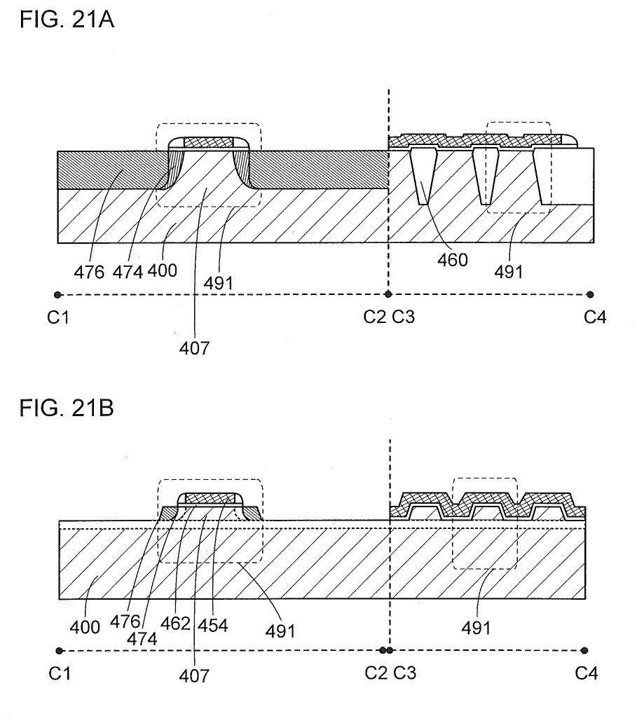

As in the transistor 491 in FIG. 21A, the projection is not necessarily provided in the substrate 400. As illustrated in FIG. 21B, the transistor 491 may be formed using a silicon on insulator (SOI) substrate.

### [Example of Circuit]

Next, examples of a circuit in which the semiconductor device of one embodiment of the present invention can be used will be described.

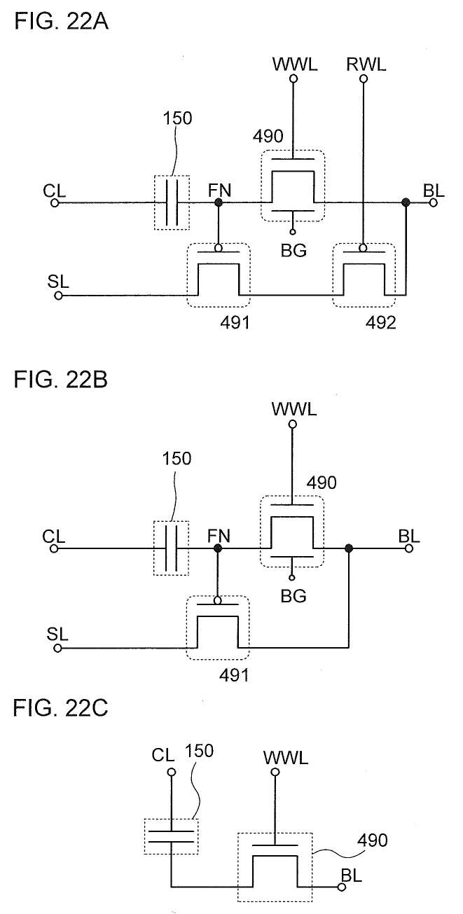

FIG. 22A illustrates an example of a circuit including three transistors and one capacitor. The description of the transistor 491 can be referred to for a transistor 492.

FIG. 22B is different from FIG. 22A in that the transistor 492 is not provided. Since the transistor 492 is not provided, the integration degree of the circuit can be increased in some cases.

As an example, a device including the circuit in FIG. 22B can have the structure in FIG. 20. In FIG. 22B, one of a source electrode and a drain electrode of the transistor 490 is connected to a gate electrode of the transistor 491 and one electrode of the capacitor 150 through a floating node (FN). The other of the source electrode and the drain electrode of the transistor 490 is connected to a terminal BL. One of a source electrode and a drain electrode of the transistor 491 is connected to a terminal SL. The other of the source electrode and the drain electrode of the transistor 491 is connected to the terminal BL.

In FIG. 20, the conductor 454 serving as a gate electrode of the transistor 491 is connected to the conductor 516 of the capacitor 150 through the plug 541, the plug 543, the plug 544, the conductor 511, the conductor 513, the conductor 514, and the like. Through the conductor 514, the plug 544b, and the like, the conductor 516 is connected to the conductor 416b serving as one of the source electrode and the drain electrode of the transistor 490.

### <Circuit Operation>

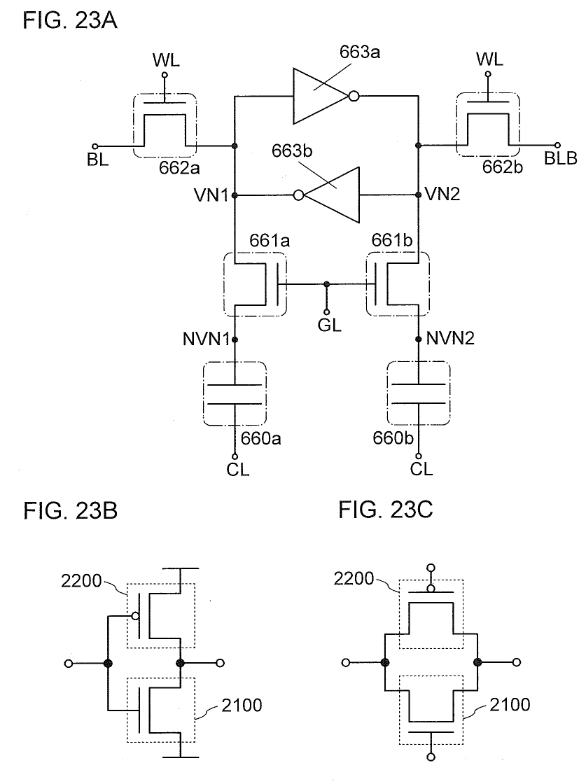

Circuits illustrated in FIGS. 22A to 22C and FIG. 23A can each function as a memory device.

The operation of the circuit in FIG. 22B will be described.

The circuit in FIG. 22B has a feature that the gate potential of the transistor 491 can be held, and thus enables writing, holding, and reading of data as follows.

Writing and holding of data will be described. First, the potential of a terminal WWL is set to a potential at which the transistor 490 is turned on, so that the transistor 490 is turned on. Accordingly, the potential of the terminal BL is supplied to the node FN where the gate of the transistor 491 and the one electrode of the capacitor 150 are electrically connected to each other. That is, predetermined charge is supplied to the gate of the transistor 491 (writing). Here, one of two kinds of charge providing different potential levels (hereinafter referred to as low-level charge and high-level charge) is supplied. After that, the potential of the terminal WWL is set to a potential at which the transistor 490 is turned off. Thus, the charge is held in the node FN (holding).

The transistor 490 in which an oxide semiconductor is used for a semiconductor layer can have extremely low off-state current; therefore, the charge of the node FN is held for a long time.

Next, reading of data will be described. An appropriate potential (a reading potential) is supplied to a terminal CL while a predetermined potential (a constant potential) is supplied to the terminal BL, whereby the potential of the terminal SL changes in accordance with the amount of charge held in the node FN. This is because in the case of using an n-channel transistor as the transistor 491, an apparent threshold voltage Vₜₕ_{_}_{H} at the time when the high-level charge is supplied to the gate of the transistor 491 is lower than an apparent threshold voltage Vₜₕ_{_}_{L} at the time when the low-level charge is supplied to the gate of the transistor 491. Here, the apparent threshold voltage refers to the potential of the terminal CL that is needed to turn on the transistor 491. Thus, the potential of the terminal CL is set to a potential V₀ which is between Vₜₕ_{_}_{H} and Vₜₕ_{_}_{L}, whereby charge supplied to the node FN can be determined. For example, in the case where the high-level charge is supplied to the node FN in writing and the potential of the terminal CL is V₀(>Vₜₕ_{_}_{H}), the transistor 491 is turned on. On the other hand, in the case where the low-level charge is supplied to the node FN in writing, even when the potential of the terminal CL is V₀ (<Vₜₕ_{_}_{L}), the transistor 491 remains off. Thus, the data held in the node FN can be read out by determining the potential of the terminal SL.

In the case where memory cells are arrayed, it is necessary that data of a desired memory cell is read out in read operation. For example, the following configuration may be employed: only data of a desired memory cell is read out by supplying a potential at which the transistor 491 is turned off regardless of the charge supplied to the node FN, that is, a potential lower than Vₜₕ_{_}_{H}, to the terminals CL of memory cells from which data is not read out. Alternatively, the following configuration may be employed: only data of a desired memory cell is read out by supplying a potential at which the transistor 491 is turned on regardless of the charge supplied to the node FN, that is, a potential higher than Vₜₕ_{_}_{L}, to the terminal CL.

In the circuit in FIG. 22A, writing, holding, and reading of data can be carried out in a manner similar to that in FIG. 22B. Note that FIG. 22A includes the transistor 492. To prevent data in the other memory cells from being read out, the transistors 492 are turned off. Thus, leakage current from the terminal BL to the terminal SL can be suppressed in some cases. In read operation of a desired memory cell, to prevent data in the other memory cells from being read out, a potential at which the transistor 492 is turned off may be input to a terminal RWL; this may eliminate the necessity of supplying a high potential to the terminal CL.

With a transistor including an oxide semiconductor and having extremely low off-state current, the above-described semiconductor device can hold stored data for a long time. In other words, the power consumption of the semiconductor device can be reduced because refresh operation becomes unnecessary or the frequency of refresh operation can be extremely low. Moreover, stored data can be held for a long time even when power is not supplied (note that the potential is preferably fixed).

In the semiconductor device, high voltage is not needed for writing data and elements are less likely to deteriorate. Unlike in a conventional nonvolatile memory, for example, it is not necessary to inject and extract electrons into and from a floating gate; thus, a problem such as deterioration of an insulator is not caused. That is, the semiconductor device of one embodiment of the present invention does not have a limit on the number of times data can be rewritten, which is a problem of a conventional nonvolatile memory, and the reliability thereof is drastically improved. Furthermore, data is written depending on the on/off state of the transistor, whereby high-speed operation can be achieved.

The semiconductor device in FIG. 22C is different from the semiconductor device in FIG. 22B in that the transistor 491 is not provided. Also in this case, data can be written and held in a manner similar to that of the semiconductor device in FIG. 22B.

Reading of data in the semiconductor device in FIG. 22C will be described. When the transistor 490 is turned on, the terminal BL which is in a floating state and the capacitor 150 are brought into conduction, and charge is redistributed between the terminal BL and the capacitor 150. As a result, the potential of the terminal BL is changed. The amount of change in the potential of the terminal BL varies depending on the potential of the one electrode of the capacitor 150 (or the charge accumulated in the capacitor 150).

For example, the potential of the terminal BL after the charge redistribution is (C_{B}×V_{B0}+C×V)/(C_{B}+C), where V is the potential of the one electrode of the capacitor 150, C is the capacitance of the capacitor 150, C_{B} is the capacitance component of the terminal BL, and V_{B0} is the potential of the terminal BL before the charge redistribution. Thus, assuming that the memory cell is in either of two states in which a potential V of the one electrode of the capacitor 150 is V₁ and V₀(V₁>V₀), the potential of the terminal BL holding the potential V₁ (=(C_{B}×V_{B0}+C×V₁)/(C_{B}+C)) is higher than the potential of the terminal BL holding the potential V₀(=(C_{B}×V_{B0}+C×V₀)/(C_{B}+C)).

Then, by comparing the potential of the terminal BL with a predetermined potential, data can be read out.

FIG. 23A illustrates an example of a circuit that can be applied to the device of one embodiment of the present invention.

The circuit in FIG. 23A includes a capacitor 660a, a capacitor 660b, a transistor 661a, a transistor 661b, a transistor 662a, a transistor 662b, an inverter 663a, an inverter 663b, a wiring BL, a wiring BLB, a wiring WL, a wiring CL, and a wiring GL.

The circuit in FIG. 23A is a memory cell in which the inverter 663a and the inverter 663b are connected in a ring to form a flip-flop. A node to which an output signal of the inverter 663b is output is referred to as a node VN1, and a node to which an output signal of the inverter 663a is output is referred to as a node VN2. The memory cells are provided in a matrix, whereby a memory device (memory cell array) can be formed.

One of a source and a drain of the transistor 662a is electrically connected to the wiring BL, the other of the source and the drain of the transistor 662a is electrically connected to the node VN1, and a gate of the transistor 662a is electrically connected to the wiring WL. One of a source and a drain of the transistor 662b is electrically connected to the node VN2, the other of the source and the drain of the transistor 662b is electrically connected to the wiring BLB, and a gate of the transistor 662b is electrically connected to the wiring WL.

One of a source and a drain of the transistor 661a is electrically connected to the node VN1, the other of the source and the drain of the transistor 661a is electrically connected to one electrode of the capacitor 660a, and a gate of the transistor 661a is electrically connected to the wiring GL. A node between the other of the source and the drain of the transistor 661a and the one electrode of the capacitor 660a is referred to as a node NVN1. One of a source and a drain of the transistor 661b is electrically connected to the node VN2, the other of the source and the drain of the transistor 661b is electrically connected to one electrode of the capacitor 660b, and a gate of the transistor 661b is electrically connected to the wiring GL. A node between the other of the source and the drain of the transistor 661b and the one electrode of the capacitor 660b is referred to as a node NVN2.

The other electrode of the capacitor 660a is electrically connected to the wiring CL. The other electrode of the capacitor 660b is electrically connected to the wiring CL.

The on/off state of the transistor 662a and that of the transistor 662b can each be selected in accordance with the potential supplied to the wiring WL. The on/off state of the transistor 661a and the transistor 661b can be selected in accordance with the potential supplied to the wiring GL.

Writing, holding, and reading in the memory cell in FIG. 23A will be described below.

In the case where data is written, first, potentials corresponding to data 0 or data 1 are applied to the wiring BL and the wiring BLB.

For example, in the case where data 1 is to be written, a high-level power supply potential (V_{DD}) is applied to the wiring BL and a ground potential is applied to the wiring BLB. Then, a potential (V_{H}) which is higher than or equal to the sum of V_{DD} and the threshold voltage of the corresponding one of the transistors 662a and 662b is applied to the wiring WL.

Next, the potential of the wiring WL is set to be lower than the threshold voltage of the corresponding one of the transistors 662a and 662b, whereby the data 1 written to the flip-flop is held.

In the case where the data is read out, the wiring BL and the wiring BLB are set to V_{DD} in advance. Then, V_{H} is applied to the wiring WL. Accordingly, the wiring BL remains at V_{DD}, whereas the wiring BLB is discharged through the transistor 662a and the inverter 663a to have a ground potential. The potential difference between the wiring BL and the wiring BLB is amplified by a sense amplifier (not illustrated), so that the held data 1 can be read out.

In the case where data 0 is to be written, the wiring BL is set to a ground potential and the wiring BLB is set to V_{DD}; then, V_{H} is applied to the wiring WL. Next, the potential of the wiring WL is set to be lower than the threshold voltage of the corresponding one of the transistors 662a and 662b, whereby the data 0 written to the flip-flop is held. In the case where the data is read out, the wiring BL and the wiring BLB are set to V_{DD} in advance and V_{H} is applied to the wiring WL. Accordingly, the wiring BLB remains at V_{DD}, whereas the wiring BL is discharged through the transistor 662b and the inverter 663b to have a ground potential. The potential difference between the wiring BL and the wiring BLB is amplified by the sense amplifier, so that the held data 0 can be read out.

Accordingly, the semiconductor device in FIG. 23A functions as a so-called static random access memory (SRAM). An SRAM does not require refresh operation because it holds data using a flip-flop. Therefore, the power consumption for data holding can be suppressed. In addition, an SRAM does not require a capacitor in a flip-flop and is therefore suitable for applications for which high speed operation is required.

In the semiconductor device in FIG. 23A, data of the node VN1 can be written to the node NVN1 through the transistor 661a. Similarly, data of the node VN2 can be written to the node NVN2 through the transistor 661b. The written data is held by turning off the transistor 661a or the transistor 661b. For example, even when supply of a power supply potential is stopped, data of the node VN1 and the node VN2 can be held in some cases.

Unlike a conventional SRAM, in which data is lost immediately after supply of a power supply potential is stopped, the semiconductor device in FIG. 23A can hold data even after the supply of a power supply potential is stopped. Therefore, the power consumption of the semiconductor device can be reduced by appropriately supplying or stopping a power supply potential. For example, the semiconductor device in FIG. 23A is used in a memory region of a CPU, whereby the power consumption of the CPU can be reduced.

Note that the length of a period during which data is held in the node NVN1 and the node NVN2 depends on the off-state current of the transistor 661a and the transistor 661b. Therefore, a transistor with low off-state current is preferably used as each of the transistors 661a and 661b in order to hold data for a long time. Alternatively, the capacitance of the capacitor 660a and the capacitor 660b may be increased.

For example, when the transistor 490 and the capacitor 150 are used as the transistor 661a and the capacitor 660a, respectively, data can be held in the node NVN1 for a long time. Similarly, when the transistor 490 and the capacitor 150 are used as the transistor 661b and the capacitor 660b, data can be held in the node NVN2 for a long time. Accordingly, the description of the transistor 490 may be referred to for the transistor 661a and the transistor 661b. Furthermore, the description of the capacitor 150 may be referred to for the capacitor 660a and the capacitor 660b.

The transistor 662a, the transistor 662b, a transistor included in the inverter 663a, and a transistor included in the inverter 663b in FIG. 23A can be formed to overlap with at least part of the transistor 661a, the transistor 661b, the capacitor 660a, and the capacitor 660b. Accordingly, the semiconductor device in FIG. 23A can be manufactured without a significant increase in occupation area in some cases as compared with a conventional SRAM. The description of the transistor 491 may be referred to for the transistor 662a, the transistor 662b, the transistor included in the inverter 663a, and the transistor included in the inverter 663b.

The connection between one of the source electrode and the drain electrode of the transistor 490 and the capacitor 150 in the structure in FIG. 20 may be applied to the connection between one of the source electrode and the drain electrode of the transistor 661a and the capacitor 660a in the circuit in FIG. 23A. Furthermore, the connection between the other of the source electrode and the drain electrode of the transistor 490 and one of the source electrode and the drain electrode of the transistor 491 may be applied to the connection between the other of the source electrode and the drain electrode of the transistor 661a and one of the source electrode and the drain electrode of the transistor 662a in the circuit in FIG. 23A.

A circuit diagram in FIG. 23B illustrates the configuration of a CMOS circuit in which a p-channel transistor 2200 and an n-channel transistor 2100 are connected in series and gates of them are connected to each other. The semiconductor device 500 may include the circuit in FIG. 23B. In this case, for example, it is preferable to use the above-described transistor 490 as the transistor 2200 and the above-described transistor 491 as the transistor 2100.

In a circuit diagram in FIG. 23C, sources of the transistors 2100 and 2200 are connected to each other and drains of the transistors 2100 and 2200 are connected to each other. With such a configuration, the transistors can function as an analog switch. The semiconductor device 500 may include the circuit in FIG. 23C. In this case, for example, it is preferable to use the above-described transistor 490 as the transistor 2200 and the above-described transistor 491 as the transistor 2100.

### <FPGA>

One embodiment of the present invention can also be applied to an LSI such as a field programmable gate array (FPGA).

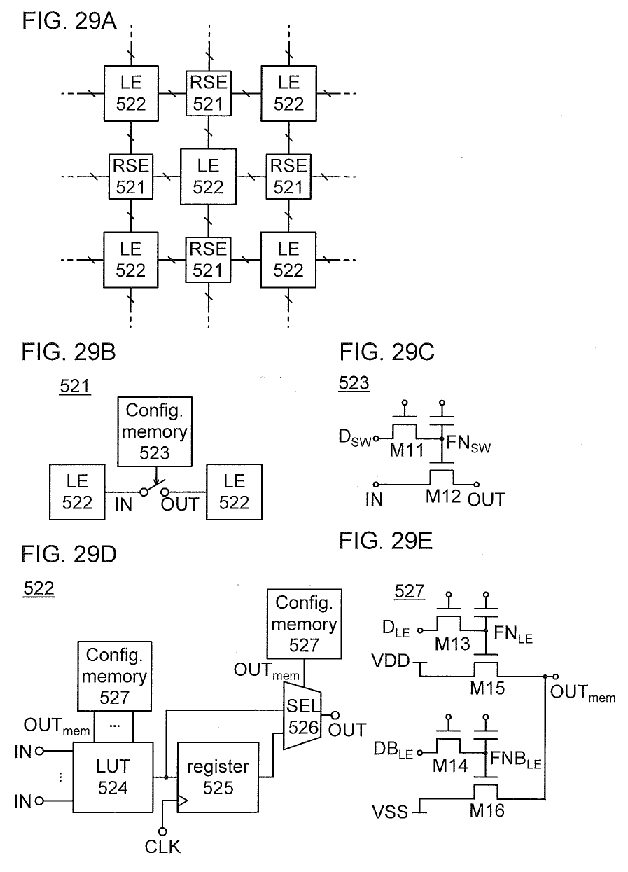

FIG. 29A shows an example of a block diagram of an FPGA. The FPGA includes a routing switch element 521 and a logic element 522. The logic element 522 can switch functions of a logic circuit, such as a combination circuit or a sequential circuit, in accordance with configuration data stored in a configuration memory.

FIG. 29B schematically illustrates a function of the routing switch element 521. The routing switch element 521 can switch a connection between the logic elements 522 in accordance with configuration data stored in a configuration memory 523. Although FIG. 29B illustrates one switch which switches a connection between a terminal IN and a terminal OUT, in an actual FPGA, a plurality of switches are provided between a plurality of the logic elements 522.

FIG. 29C illustrates a configuration example of a circuit functioning as the configuration memory 523. The configuration memory 523 includes a transistor M11 that is an OS transistor and a transistor M12 that is a silicon (Si) transistor. Configuration data D_{SW} is supplied to a node FN_{SW} through the transistor M11. The potential of the configuration data D_{SW} can be held by turning off the transistor M11. The on/off state of the transistor M12 can be switched depending on the potential of the held configuration data D_{SW}, so that the connection between the terminal IN and the terminal OUT can be switched.

FIG. 29D schematically illustrates a function of the logic element 522. The logic element 522 can switch the potential of a terminal OUTₘₑₘ in accordance with configuration data stored in a configuration memory 527. A lookup table 524 can switch functions of a combination circuit that processes a signal of the terminal IN in accordance with the potential of the terminal OUTₘₑₘ. The logic element 522 includes a register 525 that is a sequential circuit and a selector 526 for switching signals of the terminal OUT. The selector 526 can select which signal to output, a signal of the lookup table 524 or a signal of the register 525, in accordance with the potential of the terminal OUTₘₑₘ, which is output from the configuration memory 527.

FIG. 29E illustrates a configuration example of a circuit functioning as the configuration memory 527. The configuration memory 527 includes transistors M13 and M14 that are OS transistors, and transistors M15 and M16 that are Si transistors. Configuration data D_{LE} is supplied to a node FN_{LE} through the transistor M13. Configuration data DB_{LE} is supplied to a node FNB_{LE} through the transistor M14. The configuration data DB_{LE} corresponds to the potential of the configuration data D_{LE} whose logic is inverted. The potential of the configuration data D_{LE} and the potential of the configuration data DB_{LE} can be held by turning off the transistor M13 and the transistor M14, respectively. The on/off state of one of the transistors M15 and M16 is switched in accordance with the held potential of the configuration data D_{LE} or the configuration data DB_{LE}, so that a potential V_{DD} or a potential V_{SS} can be supplied to the terminal OUTₘₑₘ.

For the configuration illustrated in FIGS. 29A to 29E, any of the structures described in this embodiment can be used. For example, Si transistors are used as the transistors M12, M15, and M16, and OS transistors are used as the transistors M11, M13, and M14. In this case, a wiring for connecting the Si transistors provided in a lower layer can be formed using a low-resistance conductive material. Therefore, a circuit with high access speed and low power consumption can be obtained.

### Embodiment 2

### Imaging Device

In this embodiment, an imaging device of one embodiment of the present invention will be described.

### <Configuration Example of Imaging Device 600>

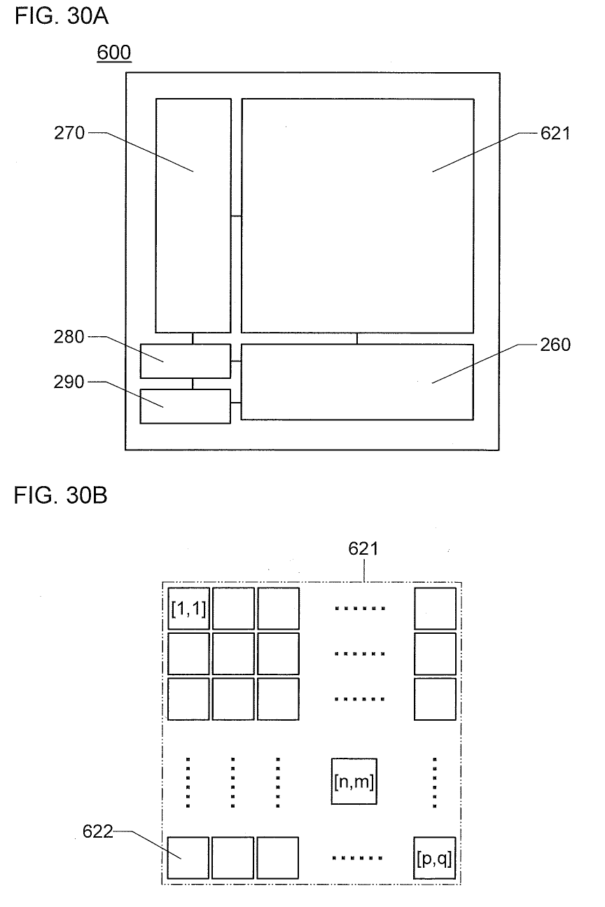

FIG. 30A is a plan view illustrating a configuration example of an imaging device 600. The imaging device 600 includes a pixel portion 621, a first circuit 260, a second circuit 270, a third circuit 280, and a fourth circuit 290. In this specification and the like, the first circuit 260 to the fourth circuit 290 and the like may be referred to as a peripheral circuit or a driving circuit. For example, the first circuit 260 can be regarded as part of a peripheral circuit.

FIG. 30B illustrates a configuration example of the pixel portion 621. The pixel portion 621 includes a plurality of pixels 622 (imaging elements) arranged in a matrix of p rows and q columns (p and q are each a natural number of 2 or more). In FIG. 30B, n is a natural number of 1 or more and p or less, and m is a natural number of 1 or more and q or less.

With the imaging device 600 including the pixels 622 arranged in a matrix of 1920×1080, for example, an image with “full high definition” (also referred to as “2K resolution,” “2K1K,” “2K,” and the like) can be taken. Furthermore, with the imaging device 600 including the pixels 622 arranged in a matrix of 4096×2160, for example, an image with “ultra high definition” (also referred to as “4K resolution,” “4K2K,” “4K,” and the like) can be taken. Furthermore, with the imaging device 600 including the pixels 622 arranged in a matrix of 8192×4320, for example, an image with “super high definition” (also referred to as “8K resolution,” “8K4K,” “8K,” and the like) can be taken. With the imaging device 600 including a larger number of display elements, even an image with 16K or 32K resolution can be taken.

The first circuit 260 and the second circuit 270 are connected to the plurality of pixels 622 and have a function of supplying signals for driving the plurality of pixels 622. The first circuit 260 may have a function of processing an analog signal output from the pixels 622. The third circuit 280 may have a function of controlling the operation timing of the peripheral circuit. For example, the third circuit 280 may have a function of generating a clock signal. Furthermore, the third circuit 280 may have a function of converting the frequency of a clock signal supplied from the outside. Moreover, the third circuit 280 may have a function of supplying a reference potential signal (e.g., a ramp wave signal).

The peripheral circuit includes at least one of a logic circuit, a switch, a buffer, an amplifier circuit, and a converter circuit. Transistors or the like included in the peripheral circuit may be formed using part of a semiconductor used to form a pixel driver circuit 610 described later. A semiconductor device such as an IC may be used as part or the whole of the peripheral circuit.

In the peripheral circuit, at least one of the first circuit 260 to the fourth circuit 290 may be omitted. For example, when one of the first circuit 260 and the fourth circuit 290 additionally has a function of the other of the first circuit 260 and the fourth circuit 290, the other of the first circuit 260 and the fourth circuit 290 may be omitted. As another example, when one of the second circuit 270 and the third circuit 280 additionally has a function of the other of the second circuit 270 and the third circuit 280, the other of the second circuit 270 and the third circuit 280 may be omitted. As another example, when one of the first circuit 260 to the fourth circuit 290 additionally has functions of the other peripheral circuits, the other peripheral circuits may be omitted.

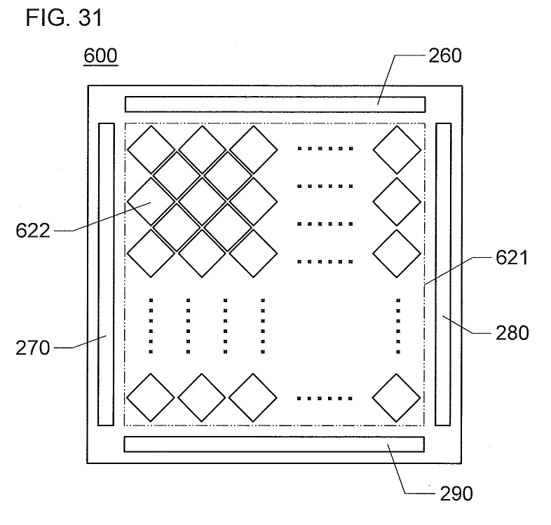

As illustrated in FIG. 31, the first circuit 260 to the fourth circuit 290 may be provided along the periphery of the pixel portion 621. In the pixel portion 621 included in the imaging device 600, the pixels 622 may be obliquely arranged. When the pixels 622 are obliquely arranged, the distance between pixels (pitch) can be shortened in the row direction and the column direction. Accordingly, the quality of an image taken with the imaging device 600 can be improved.

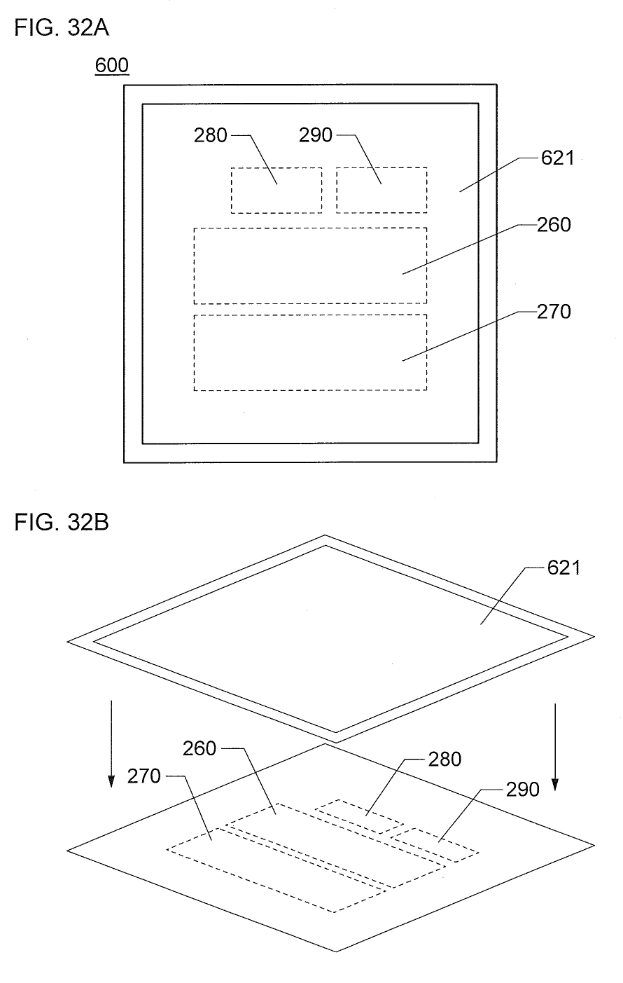

As illustrated in FIGS. 32A and 32B, the pixel portion 621 may be provided over the first circuit 260 to the fourth circuit 290. FIG. 32A is a top view of the imaging device 600 in which the pixel portion 621 is formed over the first circuit 260 to the fourth circuit 290. FIG. 32B is a perspective view illustrating the structure of the imaging device 600 in FIG. 32A.

The provision of the pixel portion 621 over the first circuit 260 to the fourth circuit 290 can increase the area occupied by the pixel portion 621 in the imaging device 600. Accordingly, the light sensitivity, the dynamic range, the resolution, the reproducibility of a taken image, or the integration degree of the imaging device 600 can be improved.

### [Color Filter and the Like]

The pixels 622 included in the imaging device 600 are used as subpixels, and the plurality of pixels 622 are provided with filters (color filters) that transmit light in respective different wavelength ranges, whereby data for color image display can be obtained.

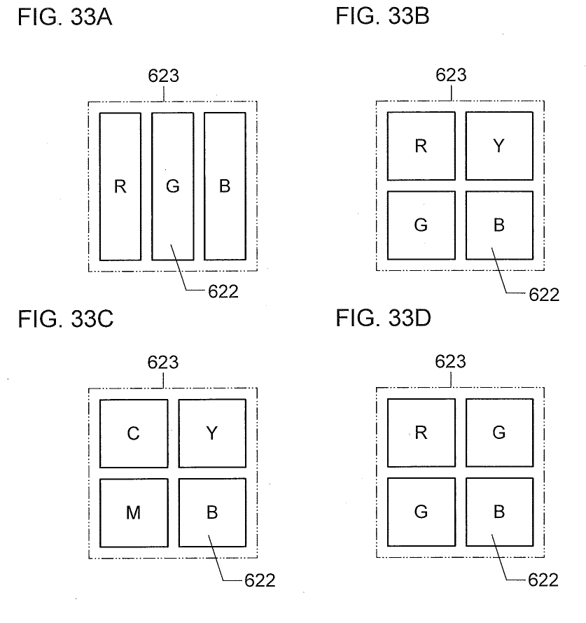

FIG. 33A is a plan view illustrating an example of a pixel 623 with which a color image is obtained. FIG. 33A illustrates the pixel 622 provided with a color filter that transmits light in a red (R) wavelength range (hereinafter also referred to as a pixel 622R), the pixel 622 provided with a color filter that transmits light in a green (G) wavelength range (hereinafter also referred to as a pixel 622G), and the pixel 622 provided with a color filter that transmits light in a blue (B) wavelength range (also referred to as a pixel 622B). The pixel 622R, the pixel 622G, and the pixel 622B collectively function as one pixel 623.

The colors of the color filters used for the pixel 623 are not limited to red (R), green (G), and blue (B), and color filters that transmit cyan (C), yellow (Y), and magenta (M) light may also be used. The pixels 622 that sense light in at least three different wavelength ranges are provided in one pixel 623, whereby a full-color image can be obtained.

FIG. 33B illustrates the pixel 623 including the pixel 622 provided with a color filter that transmits yellow (Y) light, in addition to the pixels 622 provided with the color filters that transmit red (R), green (G), and blue (B) light. FIG. 33C illustrates the pixel 623 including the pixel 622 provided with the color filter that transmits blue (B) light, in addition to the pixels 622 provided with the color filters that transmit cyan (C), yellow (Y), and magenta (M) light. When the pixels 622 that sense light in four or more different wavelength ranges are provided in one pixel 623, the color reproducibility of an obtained image can be further increased.

The pixel number ratio (or the ratio of light receiving area) of the pixel 622R to the pixel 622G and the pixel 622B need not necessarily be 1:1:1. The pixel number ratio (the ratio of light receiving area) of red to green and blue may be 1:2:1 (Bayer arrangement), as illustrated in FIG. 33D. Alternatively, the pixel number ratio (the ratio of light receiving area) of red to green and blue may be 1:6:1.

Although the number of pixels 622 used for the pixel 623 may be one, two or more is preferable. For example, when the number of pixels 622 that sense light in the same wavelength range is two or more, the redundancy can increased, and the reliability of the imaging device 600 can be increased.

When an infrared (IR) filter that transmits infrared light and absorbs or reflects light with a wavelength shorter than or equal to that of visible light is used as the filter, the imaging device 600 can sense infrared light. When an ultraviolet (UV) filter that transmits ultraviolet light and absorbs or reflects light with a wavelength longer than or equal to that of visible light is used as the filter, the imaging device 600 can sense ultraviolet light. When a scintillator that converts a radiant ray into ultraviolet light or visible light is used as the filter, the imaging device 600 can also function as a radiation detector that senses an X-ray or a γ-ray.

When a neutral density (ND) filter (dark filter) is used as the filter, output saturation, which occurs when a large amount of light is incident on a photoelectric conversion element (light-receiving element), can be prevented. With a combination of ND filters with different dimming capabilities, the dynamic range of the imaging device can be increased.

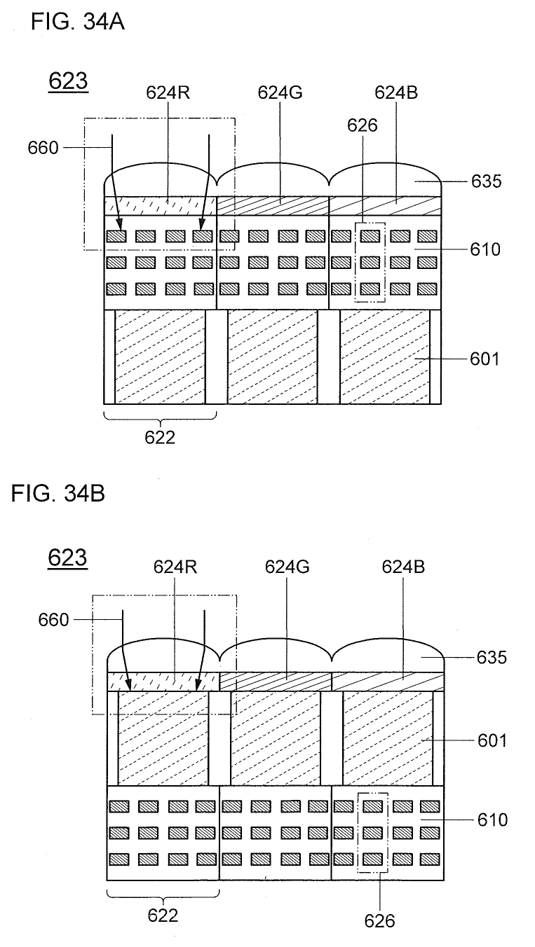

Besides the above-described filter, the pixel 622 may be provided with a lens. An arrangement example of the pixel 622, a filter 624, and a lens 635 will be described using the cross-sectional views in FIGS. 34A and 34B. With the lens 635, incident light can be efficiently received by a photoelectric conversion element. Specifically, as illustrated in FIG. 34A, light 660 can enter a photoelectric conversion element 601 through the lens 635, the filter 624 (a filter 624R, a filter 624G, or a filter 624B), a pixel driver circuit 610, and the like which are formed in the pixel 622.

However, as illustrated in a region surrounded by a two-dot chain line, part of the light 660 indicated by arrows may be blocked by part of a wiring group 626, a transistor, a capacitor and/or the like. Therefore, as illustrated in FIG. 34B, the lens 635 and the filter 624 may be formed on the photoelectric conversion element 601 side, so that the incident light can be efficiently received by the photoelectric conversion element 601. When the light 660 is incident on the photoelectric conversion element 601 side, the imaging device 600 can have high light sensitivity.

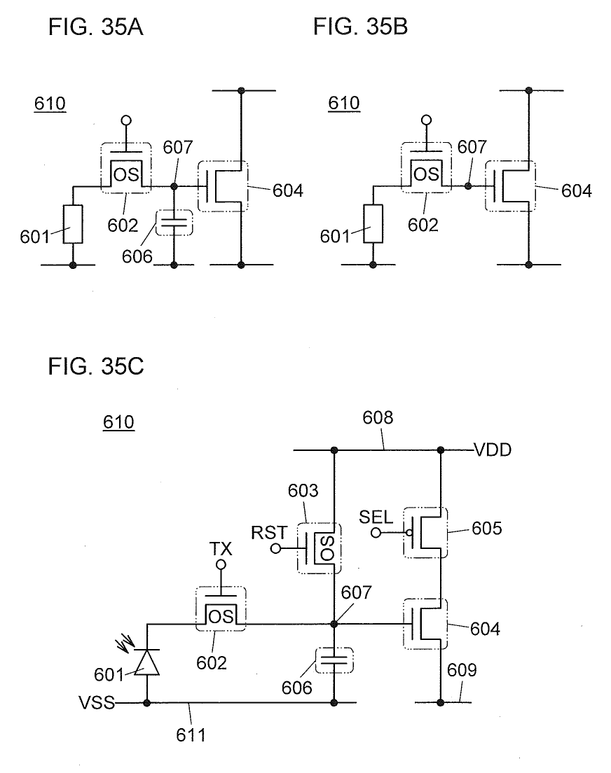

FIGS. 35A to 35C illustrate examples of the pixel driver circuit 610 that can be used for the pixel portion 621. The pixel driver circuit 610 in FIG. 35A includes a transistor 602, a transistor 604, and a capacitor 606 and is connected to a photoelectric conversion element 601. One of a source and a drain of the transistor 602 is electrically connected to the photoelectric conversion element 601, and the other of the source and the drain of the transistor 602 is electrically connected to a gate of the transistor 604 through a node 607 (a charge accumulation portion).

An OS transistor is preferably used as the transistor 602. Since the off-state current of the OS transistor can be extremely low, the capacitor 606 can be small. Alternatively, the capacitor 606 can be omitted as illustrated in FIG. 35B. Furthermore, when the transistor 602 is an OS transistor, the potential of the node 607 is less likely to change. Thus, an imaging device which is less likely to be affected by noise can be provided. Note that the transistor 604 may be an OS transistor.

A diode element formed using a silicon substrate with a PN junction or a PIN junction can be used as the photoelectric conversion element 601. Alternatively, a PIN diode element formed using an amorphous silicon film, a microcrystalline silicon film, or the like may be used. Alternatively, a diode-connected transistor may be used. Alternatively, a variable resistor or the like utilizing a photoelectric effect may be formed using silicon, germanium, selenium, or the like.

The photoelectric conversion element may be formed using a material capable of generating charge by absorbing radiation. Examples of the material capable of generating charge by absorbing radiation include lead iodide, mercury iodide, gallium arsenide, CdTe, and CdZn.

The pixel driver circuit 610 in FIG. 35C includes the transistor 602, a transistor 603, the transistor 604, a transistor 605, and the capacitor 606 and is connected to the photoelectric conversion element 601. In the pixel driver circuit 610 in FIG. 35C, a photodiode is used as the photoelectric conversion element 601. One of a source and a drain of the transistor 602 is electrically connected to a cathode of the photoelectric conversion element 601, and the other of the source and the drain of the transistor 602 is electrically connected to the node 607. An anode of the photoelectric conversion element 601 is electrically connected to a wiring 611. One of a source and a drain of the transistor 603 is electrically connected to the node 607, and the other of the source and the drain of the transistor 603 is electrically connected to a wiring 608. A gate of the transistor 604 is electrically connected to the node 607, one of a source and a drain of the transistor 604 is electrically connected to a wiring 609, and the other of the source and the drain of the transistor 604 is electrically connected to one of a source and a drain of the transistor 605. The other of the source and the drain of the transistor 605 is electrically connected to the wiring 608. One electrode of the capacitor 606 is electrically connected to the node 607, and the other electrode of the capacitor 606 is electrically connected to the wiring 611.

The transistor 602 can function as a transfer transistor. A gate of the transistor 602 is supplied with a transfer signal TX. The transistor 603 can function as a reset transistor. A gate of the transistor 603 is supplied with a reset signal RST. The transistor 604 can function as an amplifier transistor. The transistor 605 can function as a selection transistor. A gate of the transistor 605 is supplied with a selection signal SEL. Moreover, V_{DD} is supplied to the wiring 608 and V_{SS} is supplied to the wiring 611.

Next, the operation of the pixel driver circuit 610 in FIG. 35C will be described. First, the transistor 603 is turned on, so that V_{DD} is supplied to the node 607 (reset operation). Then, the transistor 603 is turned off, so that V_{DD} is held in the node 607. Next, the transistor 602 is turned on, so that the potential of the node 607 is changed in accordance with the amount of light received by the photoelectric conversion element 601 (accumulation operation). After that, the transistor 602 is turned off, so that the potential of the node 607 is held. Then, the transistor 605 is turned on, so that a potential corresponding to the potential of the node 607 is output to the wiring 609 (selection operation). By measuring the potential of the wiring 609, the amount of light received by the photoelectric conversion element 601 can be determined.

An OS transistor is preferably used as each of the transistors 602 and 603. Since the off-state current of the OS transistor can be extremely low as described above, the capacitor 606 can be small or omitted. Furthermore, when the transistors 602 and 603 are OS transistors, the potential of the node 607 is less likely to change. Thus, an imaging device which is less likely to be affected by noise can be provided.

A high-resolution imaging device can be obtained when the pixels 622 including the pixel driver circuits 610 in any of FIGS. 35A to 35C are arranged in a matrix.

With an imaging device including the pixel driver circuits 610 arranged in a matrix of 1920×1080, for example, an image with “full high definition” (also referred to as “2K resolution,” “2K1K,” “2K,” and the like) can be taken. Furthermore, with an imaging device including the pixel driver circuits 610 arranged in a matrix of 4096×2160, for example, an image with “ultra high definition” (also referred to as “4K resolution,” “4K2K,” “4K,” and the like) can be taken. Furthermore, with an imaging device including the pixel driver circuits 610 arranged in a matrix of 8192×4320, for example, an image with “super high definition” (also referred to as “8K resolution,” “8K4K,” “8K,” and the like) can be taken. With an imaging device including a larger number of display elements, even an image with 16K or 32K resolution can be taken.

### <Structural Example>

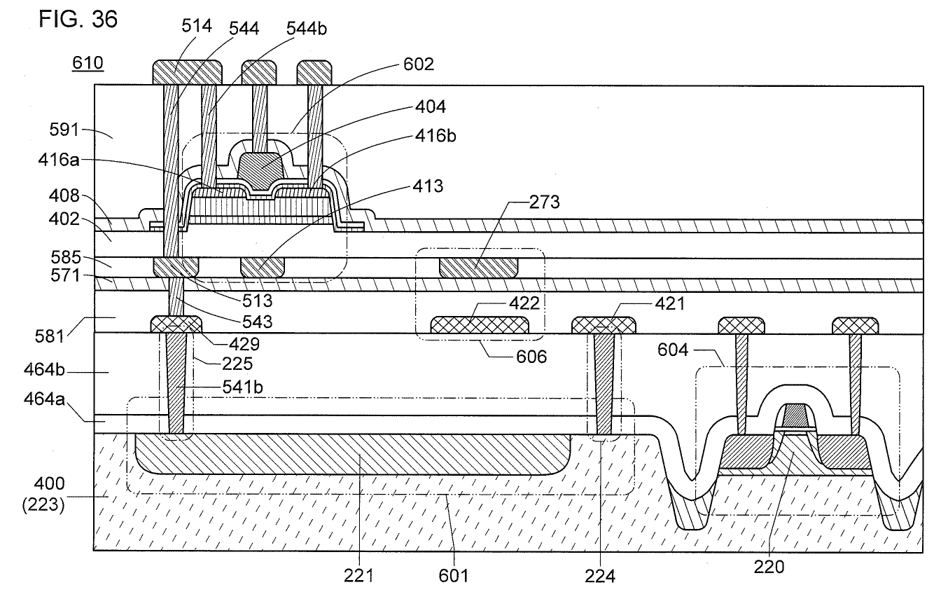

FIG. 36 illustrates a structural example of the pixel 622 including any of the above-described transistors. FIG. 36 is a cross-sectional view illustrating part of the pixel 622.

In the pixel 622 in FIG. 36, an n-type semiconductor is used for the substrate 400. A p-type semiconductor 221 of the photoelectric conversion element 601 is provided in the substrate 400. Part of the substrate 400 functions as an n-type semiconductor 223 of the photoelectric conversion element 601.

The transistor 604 is provided on the substrate 400. The transistor 604 can function as an n-channel transistor. A p-type semiconductor well 220 is provided in part of the substrate 400. The well 220 can be provided by a method similar to that for forming the p-type semiconductor 221. The well 220 and the p-type semiconductor 221 can be formed at the same time. Note that the transistor 490 described above can be used as the transistor 604, for example.

The insulator 464a and the insulator 464b are formed over the photoelectric conversion element 601 and the transistor 604. An opening 224 is formed in regions of the insulators 464a and 464b which overlap with the substrate 400 (the n-type semiconductor 223), and an opening 225 is formed in regions of the insulators 464a and 464b which overlap with the p-type semiconductor 221. Plugs 541b are formed in the opening 224 and the opening 225. The plugs 541b can be provided in a manner similar to that of the plug 541 described above. There is no particular limitation on the number of openings (224 and 225) or their arrangement. Thus, an imaging device with high layout flexibility can be provided.

A conductor 421, a conductor 422, and a conductor 429 are formed over the insulator 464b. The conductor 421 is electrically connected to the n-type semiconductor 223 (the substrate 400) through the plug 541b provided in the opening 224. The conductor 429 is electrically connected to the p-type semiconductor 221 through the plug 541b provided in the opening 225. The conductor 422 can function as one electrode of the capacitor 606.

The insulator 581 is formed to cover the conductor 421, the conductor 429, and the conductor 422. The conductor 421, the conductor 422, and the conductor 429 can be formed using a material and a method similar to those of the above-described conductor 511 or the like.

The insulator 571 is formed over the insulator 581, and the conductor 513, the conductor 413, and an electrode 273 are formed over the insulator 571. The conductor 513 is electrically connected to the conductor 429 through the plug 543. The conductor 413 can function as a back gate of the transistor 602. The electrode 273 can function as the other electrode of the capacitor 606. The transistor 490 described above can be used as the transistor 602, for example.

The conductor 416a included in the transistor 602 is electrically connected to the conductor 513 through the plug 544, the conductor 514, the plug 544b, and the like.

### <Modification Example of Structure>

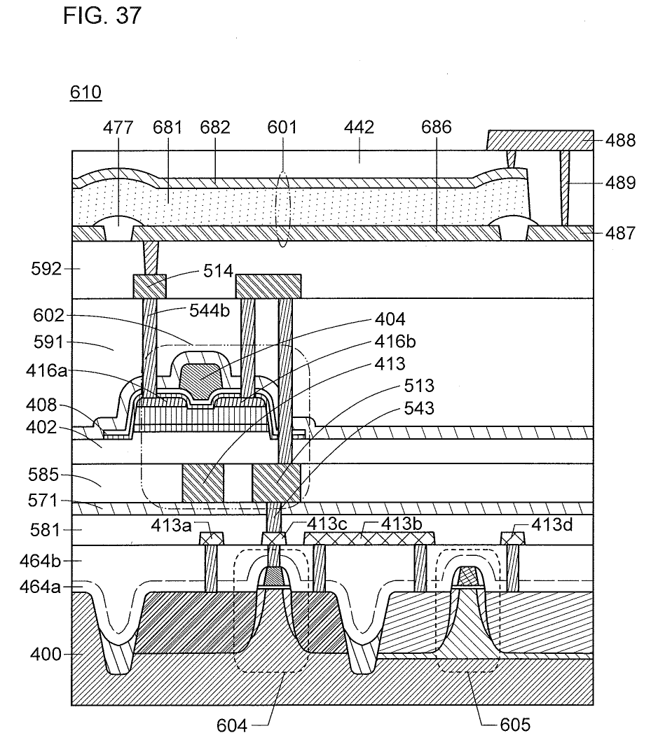

FIG. 37 illustrates a structural example of the pixel 622 which is different from that in FIG. 36. FIG. 37 is a cross-sectional view illustrating part of the pixel 622.

In the pixel 622 in FIG. 37, the transistor 604 and the transistor 605 are provided on the substrate 400. The transistor 604 can function as an n-channel transistor. The transistor 605 can function as a p-channel transistor. Note that the transistor 491 described above can be used as each of the transistors 604 and 605, for example. Here, the transistor 604 is an n-channel transistor, and the transistor 605 is a p-channel transistor; low-resistance layers thereof may contain impurities that impart the respective polarities.

Conductors 413a to 413d are formed over the insulator 464b. The conductor 413a is electrically connected to one of the source and the drain of the transistor 604, and the conductor 413b is electrically connected to the other of the source and the drain of the transistor 604. The conductor 413c is electrically connected to the gate of the transistor 604. The conductor 413b is electrically connected to one of the source and the drain of the transistor 605, and the conductor 413d is electrically connected to the other of the source and the drain of the transistor 605.

The insulator 581 is formed over the insulator 464b. The insulator 571 is formed over the insulator 581. The insulator 585, the conductor 413, and the conductor 513 are formed over the insulator 571. The conductor 513 is connected to the conductor 413c through the plug 543.

The transistor 602 is formed over the conductor 513, the conductor 413, and the insulator 585. The insulator 408 is formed over the transistor 602, and the insulator 591 is formed over the insulator 408. The conductor 514 and the insulator 592 are fonned over the insulator 591.

One of the source and the drain of the transistor 602 is connected to the conductor 513 through a plug and a conductor. The other of the source and the drain of the transistor 602 is connected to a conductor 686 included in the photoelectric conversion element 601 through the plug 544b, the conductor 514, and the like.

In the pixel 622 in FIG. 37, the photoelectric conversion element 601 is provided over the insulator 592. An insulator 442 is provided over the photoelectric conversion element 601, and a conductor 488 is provided over the insulator 442. The insulator 442 can be formed using a material and a method similar to those of the insulator 591.

The photoelectric conversion element 601 in FIG. 37 includes a photoelectric conversion layer 681 between the conductor 686 formed of a metal material or the like and a light-transmitting conductive layer 682. In FIG. 37, a selenium-based material is used for the photoelectric conversion layer 681. The photoelectric conversion element 601 including a selenium-based material has high external quantum efficiency with respect to visible light. The use of the photoelectric conversion element can achieve a highly sensitive sensor in which the amplification of electrons with respect to the amount of incident light is large owing to an avalanche phenomenon. Furthermore, the selenium-based material has a high light-absorption coefficient, which leads to an advantage that the thickness of the photoelectric conversion layer 681 can be easily reduced.

Amorphous selenium or crystalline selenium can be used as the selenium-based material. Crystalline selenium can be obtained by, for example, depositing amorphous selenium and then performing heat treatment. When the crystal grain size of crystalline selenium is smaller than a pixel pitch, variation in characteristics between pixels can be reduced. Moreover, crystalline selenium has higher spectral sensitivity to and a higher absorption coefficient for visible light than amorphous selenium.

Although the photoelectric conversion layer 681 is illustrated as a single layer, gallium oxide, cerium oxide, or the like serving as a hole-blocking layer may be provided on the light-receiving surface side of the selenium-based material, and nickel oxide, antimony sulfide, or the like serving as an electron-blocking layer may be provided on the conductor 686 side.

Alternatively, the photoelectric conversion layer 681 may be a layer containing a compound of copper, indium, and selenium (CIS). Alternatively, a layer containing a compound of copper, indium, gallium, and selenium (CIGS) may be used. With CIS or CIGS, a photoelectric conversion element that can utilize an avalanche phenomenon as in the case of using a single layer of selenium can be formed.

Furthermore, CIS and CIGS are p-type semiconductors, and an n-type semiconductor such as cadmium sulfide or zinc sulfide may be provided in contact with the p-type semiconductor in order to form a junction.

It is preferable to apply relatively high voltage (e.g., 10 V or higher) to the photoelectric conversion element in order to cause the avalanche phenomenon. Since an OS transistor has higher drain withstand voltage than a Si transistor, comparatively high voltage can be easily applied to the photoelectric conversion element. Thus, by combination of the OS transistor having high drain withstand voltage and the photoelectric conversion element including a selenium-based material in the photoelectric conversion layer, a highly sensitive and highly reliable imaging device can be obtained.

For the light-transmitting conductive layer 682, the following material can be used: for example, indium tin oxide, indium tin oxide containing silicon, indium oxide containing zinc, zinc oxide, zinc oxide containing gallium, zinc oxide containing aluminum, tin oxide, tin oxide containing fluorine, tin oxide containing antimony, or graphene. The light-transmitting conductive layer 682 is not limited to a single layer and may be a stack of different films. Although the light-transmitting conductive layer 682 and a wiring 487 are electrically connected to each other through the conductor 488 and a plug 489 in FIG. 37, the light-transmitting conductive layer 682 and the wiring 487 may be in direct contact with each other.

The conductor 686, the wiring 487, and the like may each have a structure in which a plurality of conductive layers is stacked. For example, the conductor 686 can include two layers, and the wiring 487 can include two layers. For example, lower layers of the conductor 686 and the wiring 487 are preferably formed of a low-resistance metal or the like, and upper layers of the conductor 686 and the wiring 487 are preferably formed of a metal or the like that exhibits an excellent contact property with the photoelectric conversion layer 681. Such a structure can improve the electrical characteristics of the photoelectric conversion element. Note that some kinds of metal may cause electrochemical corrosion by being in contact with the light-transmitting conductive layer 682. Even when the lower layer of the wiring 487 is formed using such metal, electrochemical corrosion can be prevented because the upper layer of the wiring 487 is positioned between the lower layer of the wiring 487 and the light-transmitting conductive layer 682.

The upper layers of the conductor 686 and the wiring 487 can be formed using, for example, molybdenum or tungsten. The lower layers of the conductor 686 and the wiring 487 can be formed using, for example, aluminum, titanium, or a stack of titanium, aluminum, and titanium.

The insulator 442 may have a multilayer structure. A partition wall 477 can be formed using an inorganic insulator, an insulating organic resin, or the like. The partition wall 477 may be colored black or the like in order to shield the transistors and the like from light and/or to determine the area of a light-receiving portion in each pixel.

Alternatively, a PIN diode element or the like formed using an amorphous silicon film, a microcrystalline silicon film, or the like may be used as the photoelectric conversion element 601. In the photodiode, an n-type semiconductor layer, an i-type semiconductor layer, and a p-type semiconductor layer are stacked in this order. The i-type semiconductor layer is preferably formed using amorphous silicon. The p-type semiconductor layer and the n-type semiconductor layer can each be formed using amorphous silicon, microcrystalline silicon, or the like which includes a dopant that imparts the corresponding conductivity type. A photodiode in which a photoelectric conversion layer is formed using amorphous silicon has high sensitivity in a visible wavelength range, and therefore can easily sense weak visible light.

Note that a PN or PIN diode element is preferably provided such that the p-type semiconductor layer serves as a light-receiving surface. When the p-type semiconductor layer serves as a light-receiving surface, the output current of the photoelectric conversion element 601 can be increased.

The photoelectric conversion element 601 including the above-described selenium-based material, amorphous silicon, or the like can be formed through a general semiconductor manufacturing process including a deposition step, a lithography step, an etching step, and the like.

### Embodiment 3

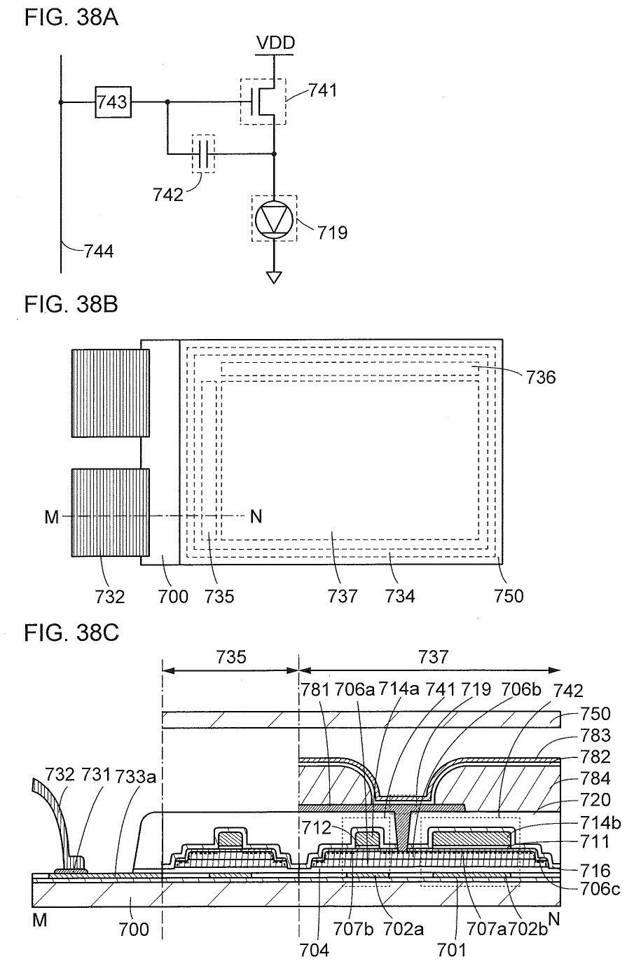

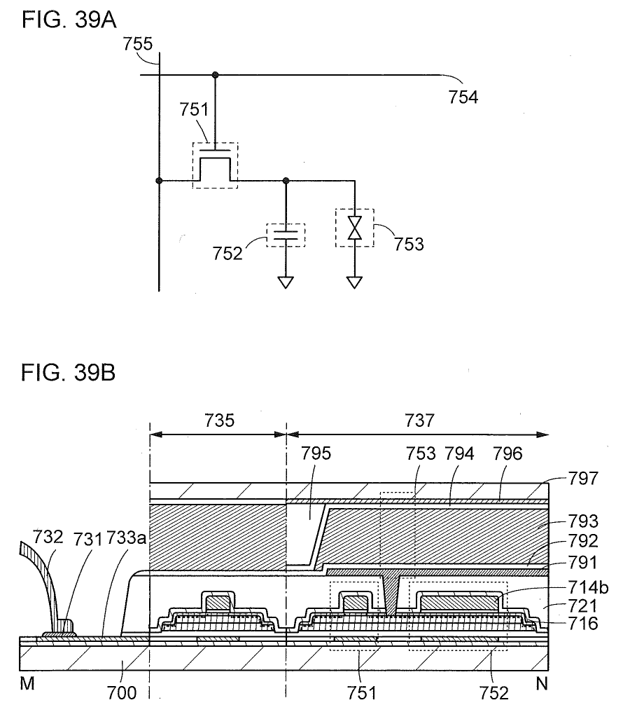

In this embodiment, display devices each including the transistor or the like of one embodiment of the present invention will be described with reference to FIGS. 38A to 38C and FIGS. 39A and 39B.

### <Structure of Display Device>

Examples of a display element provided in the display device include a liquid crystal element (also referred to as a liquid crystal display element) and a light-emitting element (also referred to as a light-emitting display element). The category of the light-emitting element includes an element whose luminance is controlled by current or voltage and specifically includes an inorganic electroluminescent (EL) element, an organic EL element, and the like. A display device including an EL element (EL display device) and a display device including a liquid crystal element (liquid crystal display device) will be described below as examples of the display device.

Note that the display device described below includes, in its category, a panel in which a display element is sealed and a module in which an IC including a controller or the like is mounted on the panel.

The display device described below refers to an image display device or a light source (including a lighting device). The display device includes any of the following modules: a module provided with a connector such as an FPC or a TCP, a module in which a printed wiring board is provided at the end of a TCP, and a module in which an integrated circuit (IC) is mounted directly on a display element by a COG method.

FIGS. 38A to 38C illustrate an example of an EL display device of one embodiment of the present invention. FIG. 38A shows a circuit diagram of a pixel in the EL display device. FIG. 38B is a top view illustrating the whole EL display device. FIG. 38C shows a cross section M-N corresponding to part taken along dashed-dotted line M-N in FIG. 38B.

FIG. 38A is an example of a circuit diagram of a pixel used in the EL display device.

In this specification and the like, it may be possible for those skilled in the art to constitute one embodiment of the invention even when portions to which all the terminals of an active element (e.g., a transistor or a diode), a passive element (e.g., a capacitor or a resistor), or the like are connected are not specified. In other words, one embodiment of the invention can be clear even when connection portions are not specified. Furthermore, in the case where a connection portion is disclosed in this specification and the like, it may be possible to determine that one embodiment of the invention in which a connection portion is not specified is disclosed in this specification and the like. Particularly in the case where the number of portions to which a terminal is connected may be more than one, it is not necessary to specify the portions to which the terminal is connected. Therefore, it may be possible to constitute one embodiment of the invention by specifying only portions to which some terminals of an active element (e.g., a transistor or a diode), a passive element (e.g., a capacitor or a resistor), or the like are connected.

In this specification and the like, it may be possible for those skilled in the art to specify the invention when at least the connection portion of a circuit is specified. Alternatively, it may be possible for those skilled in the art to specify the invention when at least a function of a circuit is specified. In other words, when a function is specified, one embodiment of the present invention can be clear. Furthermore, it may be possible to determine that one embodiment of the invention whose function is specified is disclosed in this specification and the like. Therefore, when a connection portion of a circuit is specified, the circuit is disclosed as one embodiment of the invention even when a function is not specified, and one embodiment of the invention can be constituted. Alternatively, when a function of a circuit is specified, the circuit is disclosed as one embodiment of the invention even when a connection portion is not specified, and one embodiment of the invention can be constituted.

The EL display device in FIG. 38A includes a switching element 743, a transistor 741, a capacitor 742, and a light-emitting element 719.

Note that FIG. 38A and the like each illustrate an example of a circuit configuration; therefore, a transistor can be additionally provided. In contrast, it is also possible not to add a transistor, a switch, a passive element, or the like to each node in FIG. 38A.

A gate of the transistor 741 is electrically connected to one terminal of the switching element 743 and one electrode of the capacitor 742. A source of the transistor 741 is electrically connected to the other electrode of the capacitor 742 and one electrode of the light-emitting element 719. A power supply potential V_{DD} is supplied to a drain of the transistor 741. The other terminal of the switching element 743 is electrically connected to a signal line 744. A constant potential is supplied to the other electrode of the light-emitting element 719. The constant potential is a ground potential GND or a potential lower than the ground potential GND.

It is preferable to use a transistor as the switching element 743. When a transistor is used as the switching element, the area of a pixel can be reduced, so that the EL display device can have high resolution. As the switching element 743, a transistor formed through the same process as the transistor 741 may be used, so that the EL display device can be manufactured with high productivity. As the transistor 741 and/or the switching element 743, any of the above-described transistors can be used, for example.

FIG. 38B is a top view of the EL display device. The EL display device includes a substrate 700, a substrate 750, a sealant 734, a driver circuit 735, a driver circuit 736, a pixel 737, and an FPC 732. The sealant 734 is provided between the substrate 700 and the substrate 750 so as to surround the pixel 737, the driver circuit 735, and the driver circuit 736. Note that the driver circuit 735 and/or the driver circuit 736 may be provided outside the sealant 734.

FIG. 38C is a cross-sectional view illustrating part of the EL display device taken along dashed-dotted line M-N in FIG. 38B.

FIG. 38C illustrates the transistor 741 that includes an insulator 701 over the substrate 700, a conductor 702a over the insulator 701, an insulator 704 over the conductor 702a, an insulator 706a which is over the insulator 704 and overlaps with the conductor 702a, a semiconductor 706b over the insulator 706a, an insulator 706c over the semiconductor 706b, a region 707a and a region 707b which are provided in the insulator 706c and the semiconductor 706b, an insulator 712 over the insulator 706c, a conductor 714a over the insulator 712, and an insulator 716 over the insulator 706c and the conductor 714a. Note that the structure of the transistor 741 is just an example; the transistor 741 may have a structure different from that in FIG. 38C.

In the transistor 741 in FIG. 38C, the conductor 702a functions as a gate electrode, the region 707a functions as a source, the region 707b functions as a drain, the insulator 712 functions as a gate insulator, and the conductor 714a functions as a gate electrode. In some cases, electrical characteristics of the semiconductor 706b change if light enters the semiconductor 706b. To prevent this, the conductor 702a and/or the conductor 714a preferably have/has a light-blocking property.

FIG. 38C illustrates the capacitor 742 that includes a conductor 702b over the insulator 701, the insulator 704 over the conductor 702b, the region 707a which is over the insulator 704 and overlaps with the conductor 702b, an insulator 711 over the region 707a, and a conductor 714b which is over the insulator 711 and overlaps with the region 707a.

In the capacitor 742, the conductor 702b and the conductor 714b each function as one electrode, and the region 707a functions as the other electrode.

Thus, the capacitor 742 can be formed using a film in the transistor 741. The conductor 702a and the conductor 702b are preferably formed using the same kind of conductor. In this case, the conductor 702a and the conductor 702b can be formed in the same step. The conductor 714a and the conductor 714b are preferably formed using the same kind of conductor. In this case, the conductor 714a and the conductor 714b can be formed in the same step. The insulator 711 and the insulator 712 are preferably formed using the same kind of insulator. In this case, the insulator 711 and the insulator 712 can be formed in the same step.

The capacitor 742 in FIG. 38C has a large capacitance per unit area occupied by the capacitor. Therefore, the EL display device in FIG. 38C has high display quality.

An insulator 720 is provided over the transistor 741 and the capacitor 742. Here, the insulator 706c, the insulator 716, and the insulator 720 may have an opening reaching the region 707a which functions as a source of the transistor 741. A conductor 781 is provided over the insulator 720. The conductor 781 is electrically connected to the transistor 741 through the opening in the insulator 706c, the insulator 716, and the insulator 720.

A partition wall 784 having an opening reaching the conductor 781 is provided over the conductor 781. A light-emitting layer 782 which is in contact with the conductor 781 through the opening in the partition wall 784 is provided over the partition wall 784. A conductor 783 is provided over the light-emitting layer 782. A region in which the conductor 781, the light-emitting layer 782, and the conductor 783 overlap with each other serves as the light-emitting element 719.

So far, an example of the EL display device has been described. Next, an example of a liquid crystal display device will be described.

FIG. 39A is a circuit diagram illustrating a configuration example of a pixel of a liquid crystal display device. The pixel in FIGS. 39A and 39B includes a transistor 751, a capacitor 752, and an element (liquid crystal element) 753 in which a space between a pair of electrodes is filled with liquid crystal.

One of a source and a drain of the transistor 751 is electrically connected to a signal line 755, and a gate of the transistor 751 is electrically connected to a scan line 754.

One electrode of the capacitor 752 is electrically connected to the other of the source and the drain of the transistor 751, and the other electrode of the capacitor 752 is electrically connected to a wiring for supplying a common potential.

One electrode of the liquid crystal element 753 is electrically connected to the other of the source and the drain of the transistor 751, and the other electrode of the liquid crystal element 753 is electrically connected to a wiring for supplying a common potential. The common potential supplied to the wiring electrically connected to the other electrode of the capacitor 752 may be different from that supplied to the other electrode of the liquid crystal element 753.

Note that the top view of the liquid crystal display device is similar to that of the EL display device. A cross-sectional view of the liquid crystal display device taken along dashed-dotted line M-N in FIG. 38B is illustrated in FIG. 39B. In FIG. 39B, the FPC 732 is connected to a wiring 733a through a terminal 731. Note that the wiring 733a may be formed using a conductor or semiconductor of the same kind as a conductor or semiconductor included in the transistor 751.

For the transistor 751, refer to the description of the transistor 741. For the capacitor 752, refer to the description of the capacitor 742. Note that the structure of the capacitor 752 in FIG. 39B corresponds to, but is not limited to, the structure of the capacitor 742 in FIG. 38C.

In the case where an oxide semiconductor is used as the semiconductor of the transistor 751, the off-state current of the transistor 751 can be extremely low. Therefore, charge held in the capacitor 752 is unlikely to leak, so that the voltage applied to the liquid crystal element 753 can be maintained for a long time. Accordingly, the transistor 751 can be kept off during a period in which moving images with few motions or a still image is displayed, whereby power for operating the transistor 751 can be saved; accordingly a liquid crystal display device with low power consumption can be provided. Furthermore, the area occupied by the capacitor 752 can be reduced; thus, a liquid crystal display device with a high aperture ratio or a high-resolution liquid crystal display device can be provided.

An insulator 721 is provided over the transistor 751 and the capacitor 752. The insulator 721 has an opening reaching the transistor 751. A conductor 791 is provided over the insulator 721. The conductor 791 is electrically connected to the transistor 751 through the opening in the insulator 721.

An insulator 792 functioning as an alignment film is provided over the conductor 791. A liquid crystal layer 793 is provided over the insulator 792. An insulator 794 functioning as an alignment film is provided over the liquid crystal layer 793. A spacer 795 is provided over the insulator 794. A conductor 796 is provided over the spacer 795 and the insulator 794. A substrate 797 is provided over the conductor 796.

Note that the following mode can be used as a driving method of liquid crystal: a twisted nematic (TN) mode, a super twisted nematic (STN) mode, an in-plane-switching (IPS) mode, a fringe field switching (FFS) mode, a multi-domain vertical alignment (MVA) mode, a patterned vertical alignment (PVA) mode, an Advanced Super View (ASV) mode, an axially symmetric aligned microcell (ASM) mode, an optically compensated birefringence (OCB) mode, an electrically controlled birefringence (ECB) mode, a ferroelectric liquid crystal (FLC) mode, an anti-ferroelectric liquid crystal (AFLC) mode, a polymer-dispersed liquid crystal (PDLC) mode, a guest-host mode, a blue phase mode, or the like. The driving method is not limited to these examples, and a variety of driving methods can be used.

With the above-described structure, a display device including a capacitor occupying a small area, a display device with high display quality, or a high-resolution display device can be provided.

For example, in this specification and the like, a display element, a display device which is a device including a display element, a light-emitting element, and a light-emitting device which is a device including a light-emitting element can employ various modes or can include various elements. For example, the display element, the display device, the light-emitting element, or the light-emitting device includes at least one of a light-emitting diode (LED) for white, red, green, blue, or the like, a transistor (a transistor that emits light depending on current), an electron emitter, a liquid crystal element, electronic ink, an electrophoretic element, a grating light valve (GLV), a plasma display panel (PDP), a display element using micro electro mechanical systems (MEMS), a digital micromirror device (DMD), a digital micro shutter (DMS), an interferometric modulator display (IMOD) element, a MEMS shutter display element, an optical-interference-type MEMS display element, an electrowetting element, a piezoelectric ceramic display, a display element including a carbon nanotube, and the like. Other than the above, a display medium whose contrast, luminance, reflectance, transmittance, or the like is changed by an electrical or magnetic effect may be included.

An example of a display device including an EL element is an EL display. Examples of a display device including an electron emitter include a field emission display (FED) and an SED-type flat panel display (SED: surface-conduction electron-emitter display). Examples of a display device including a liquid crystal element include liquid crystal displays (e.g., a transmissive liquid crystal display, a transflective liquid crystal display, a reflective liquid crystal display, a direct-view liquid crystal display, and a projection liquid crystal display). An example of a display device including electronic ink or an electrophoretic element is electronic paper. In a transflective liquid crystal display or a reflective liquid crystal display, some or all of pixel electrodes may function as reflective electrodes. For example, some or all of pixel electrodes may contain aluminum, silver, or the like. In this case, a memory circuit such as an SRAM can be provided under the reflective electrodes, leading to lower power consumption.

In the case where an LED is used, graphene or graphite may be provided under an electrode or a nitride semiconductor of the LED. Graphene or graphite may be a multilayer fihn in which a plurality of layers is stacked. The provision of graphene or graphite enables easy deposition of a nitride semiconductor thereover, such as an n-type GaN semiconductor including crystals. Furthermore, a p-type GaN semiconductor including crystals or the like can be provided thereover, and thus, the LED can be formed. Note that an AlN layer may be provided between the n-type GaN semiconductor including crystals and graphene or graphite. The GaN semiconductors included in the LED may be deposited by MOCVD. When graphene is provided, the GaN semiconductors included in the LED can also be deposited by a sputtering method.

The structure described in this embodiment can be used in appropriate combination with any of the structures described in the other embodiments.

### Embodiment 4

In this embodiment, a CPU in which at least the transistor described in the above embodiment can be used and the memory device described in the above embodiment is included will be described.

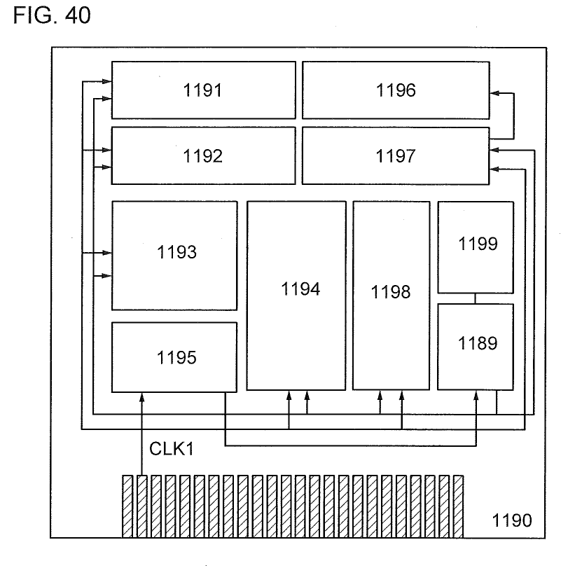

FIG. 40 is a block diagram illustrating a configuration example of a CPU at least part of which includes the memory device described in the above embodiment.

The CPU in FIG. 40 includes, over a substrate 1190, an arithmetic logic unit (ALU) 1191, an ALU controller 1192, an instruction decoder 1193, an interrupt controller 1194, a timing controller 1195, a register 1196, a register controller 1197, a bus interface (Bus I/F) 1198, a rewritable ROM 1199, and a ROM interface (ROM I/F) 1189. A semiconductor substrate, an SOI substrate, a glass substrate, or the like is used as the substrate 1190. The ROM 1199 and the ROM interface 1189 may be provided over a separate chip. Needless to say, FIG. 40 illustrates just an example of a CPU with a simplified configuration, and an actual CPU may have various configurations depending on the application. For example, a CPU may have the following configuration: a plurality of cores, each of which includes the CPU or the arithmetic circuit in FIG. 40, operates in parallel. The number of bits that the CPU can process in an internal arithmetic circuit or a data bus can be 8, 16, 32, or 64, for example.

An instruction that is input to the CPU through the bus interface 1198 is input to the instruction decoder 1193 and decoded therein, and then input to the ALU controller 1192, the interrupt controller 1194, the register controller 1197, and the timing controller 1195.

The ALU controller 1192, the interrupt controller 1194, the register controller 1197, and the timing controller 1195 conduct various controls in accordance with the decoded instruction. Specifically, the ALU controller 1192 generates signals for controlling the operation of the ALU 1191. While the CPU is executing a program, the interrupt controller 1194 processes an interrupt request from an external input/output device or a peripheral circuit, depending on its priority or a mask state. The register controller 1197 generates an address of the register 1196, and reads/writes data from/to the register 1196, depending on the state of the CPU.

The timing controller 1195 generates signals for controlling the operation timings of the ALU 1191, the ALU controller 1192, the instruction decoder 1193, the interrupt controller 1194, and the register controller 1197. For example, the timing controller 1195 includes an internal clock generator for generating an internal clock signal CLK2 on the basis of a reference clock signal CLK1, and supplies the internal clock signal CLK2 to the above circuits.

In the CPU in FIG. 40, a memory cell is provided in the register 1196.

In the CPU in FIG. 40, the register controller 1197 selects a holding operation in the register 1196 in accordance with an instruction from the ALU 1191. That is, the register controller 1197 selects whether data is held by a flip-flop or by a capacitor in the memory cell included in the register 1196. When data holding by the flip-flop is selected, power supply voltage is supplied to the memory cell in the register 1196. When data holding by the capacitor is selected, the data is rewritten in the capacitor, and the supply of power supply voltage to the memory cell in the register 1196 can be stopped.

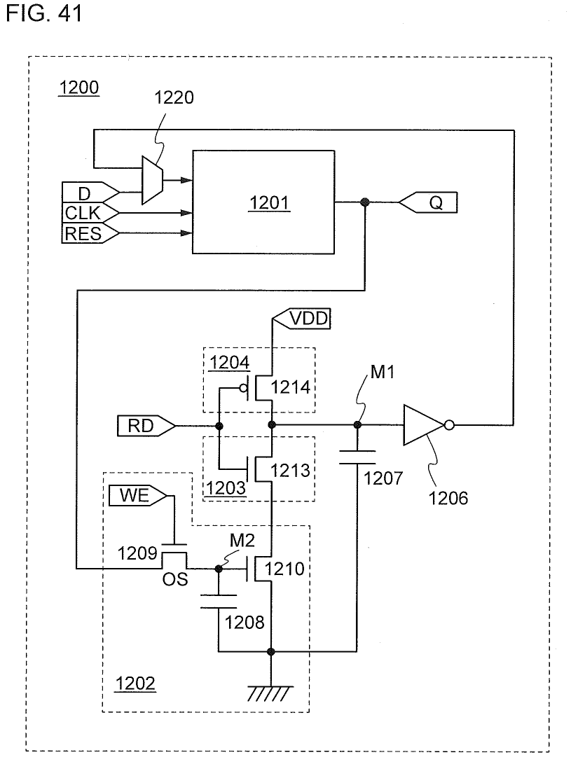

FIG. 41 is an example of a circuit diagram of a memory device that can be used as the register 1196. A memory device 1200 includes a circuit 1201 in which stored data is volatile when power supply is stopped, a circuit 1202 in which stored data is nonvolatile even when power supply is stopped, a switch 1203, a switch 1204, a logic element 1206, a capacitor 1207, and a circuit 1220 having a selecting function. The circuit 1202 includes a capacitor 1208, a transistor 1209, and a transistor 1210. Note that the memory device 1200 may further include another element such as a diode, a resistor, or an inductor, as needed. The transistor 1209 is preferably a transistor in which a channel is formed in an oxide semiconductor layer. For the transistor 1209, the description of the transistor 490 in the above embodiment can be referred to.

Here, the memory device described in the above embodiment can be used as the circuit 1202. When supply of power supply voltage to the memory device 1200 is stopped, a ground potential (0 V) or a potential at which the transistor 1209 in the circuit 1202 is turned off continues to be input to a gate of the transistor 1209. For example, the gate of the transistor 1209 is grounded through a load such as a resistor.

Shown here is an example in which the switch 1203 is a transistor 1213 having one conductivity type (e.g., an n-channel transistor) and the switch 1204 is a transistor 1214 having a conductivity type opposite to the one conductivity type (e.g., a p-channel transistor). A first terminal of the switch 1203 corresponds to one of a source and a drain of the transistor 1213, a second terminal of the switch 1203 corresponds to the other of the source and the drain of the transistor 1213, and conduction or non-conduction between the first terminal and the second terminal of the switch 1203 (i.e., the on/off state of the transistor 1213) is selected by a control signal RD input to a gate of the transistor 1213. A first terminal of the switch 1204 corresponds to one of a source and a drain of the transistor 1214, a second termnninal of the switch 1204 corresponds to the other of the source and the drain of the transistor 1214, and conduction or non-conduction between the first terminal and the second terminal of the switch 1204 (i.e., the on/off state of the transistor 1214) is selected by the control signal RD input to a gate of the transistor 1214.

One of a source and a drain of the transistor 1209 is electrically connected to one of a pair of electrodes of the capacitor 1208 and a gate of the transistor 1210. Here, the connection portion is referred to as a node M2. One of a source and a drain of the transistor 1210 is electrically connected to a wiring which can supply a low power supply potential (e.g., a GND line), and the other thereof is electrically connected to the first terminal of the switch 1203 (one of the source and the drain of the transistor 1213). The second terminal of the switch 1203 (the other of the source and the drain of the transistor 1213) is electrically connected to the first terminal of the switch 1204 (one of the source and the drain of the transistor 1214). The second terminal of the switch 1204 (the other of the source and the drain of the transistor 1214) is electrically connected to a wiring which can supply a power supply potential V_{DD}. The second terminal of the switch 1203 (the other of the source and the drain of the transistor 1213), the first terminal of the switch 1204 (the one of the source and the drain of the transistor 1214), an input terminal of the logic element 1206, and one of a pair of electrodes of the capacitor 1207 are electrically connected to each other. Here, the connection portion is referred to as a node M1. The other of the pair of electrodes of the capacitor 1207 can be supplied with a constant potential such as a low power supply potential (e.g., GND) or a high power supply potential (e.g., V_{DD}). The other of the pair of electrodes of the capacitor 1207 is electrically connected to the wiring which can supply a low power supply potential (e.g., a GND line). The other of the pair of electrodes of the capacitor 1208 can be supplied with a constant potential such as a low power supply potential (e.g., GND) or a high power supply potential (e.g., V_{DD}). The other of the pair of electrodes of the capacitor 1208 is electrically connected to the wiring which can supply a low power supply potential (e.g., a GND line).

The capacitor 1207 and the capacitor 1208 are not necessarily provided as long as the parasitic capacitance of the transistor, the wiring, or the like is actively utilized.

A control signal WE is input to a first gate (a first gate electrode) of the transistor 1209. The conduction or non-conduction between the first terminal and the second terminal of each of the switches 1203 and 1204 is selected by the control signal RD which is different from the control signal WE. When one of the switches is in the conduction state between the first terminal and the second terminal, the other of the switches is in the non-conduction state between the first terminal and the second terminal.

A signal corresponding to data held in the circuit 1201 is input to the other of the source and the drain of the transistor 1209. FIG. 41 illustrates an example in which an output signal of the circuit 1201 is input to the other of the source and the drain of the transistor 1209. The logic value of a signal output from the second terminal of the switch 1203 (the other of the source and the drain of the transistor 1213) is inverted by the logic element 1206, and the inverted signal is input to the circuit 1201 through the circuit 1220.

In FIG. 41, the signal output from the second terminal of the switch 1203 (the other of the source and the drain of the transistor 1213) is input to the circuit 1201 through the logic element 1206 and the circuit 1220; however, one embodiment of the present invention is not limited to this example. The signal output from the second terminal of the switch 1203 (the other of the source and the drain of the transistor 1213) may be input to the circuit 1201 without its logic value being inverted. For example, in the case where the circuit 1201 includes a node in which a signal obtained by inversion of the logic value of a signal input from the input terminal is held, the signal output from the second terminal of the switch 1203 (the other of the source and the drain of the transistor 1213) can be input to the node.

In FIG. 41, the transistors used for the memory device 1200 except for the transistor 1209 can each be a transistor in which a channel is formed in a layer including a semiconductor other than an oxide semiconductor or in the substrate 1190. For example, a transistor in which a channel is formed in a silicon layer or a silicon substrate can be used. Alternatively, all the transistors used for the memory device 1200 may each be a transistor in which a channel is formed in an oxide semiconductor layer. Alternatively, the memory device 1200 may include a transistor in which a channel is formed in an oxide semiconductor layer in addition to the transistor 1209, and a transistor in which a channel is formed in a layer formed using a semiconductor other than an oxide semiconductor or in the substrate 1190 can be used as each of the other transistors.

As the circuit 1201 in FIG. 41, for example, a flip-flop circuit can be used. As the logic element 1206, for example, an inverter or a clocked inverter can be used.

In the semiconductor device of one embodiment of the present invention, in a period during which the memory device 1200 is not supplied with the power supply voltage, data stored in the circuit 1201 can be held by the capacitor 1208 provided in the circuit 1202.

The off-state current of the transistor in which a channel is formed in an oxide semiconductor layer is extremely low. For example, the off-state current of the transistor in which a channel is formed in an oxide semiconductor layer is much lower than that of a transistor in which a channel is formed in crystalline silicon. Thus, when the former transistor is used as the transistor 1209, a signal is held by the capacitor 1208 for a long time also in a period during which the power supply voltage is not supplied to the memory device 1200. The memory device 1200 can accordingly hold the stored content (data) also in a period during which the supply of the power supply voltage is stopped.

Since the memory element performs pre-charge operation with the switch 1203 and the switch 1204, the time from the restart of the supply of the power supply voltage until original data is restored in the circuit 1201 can be shortened.

In the circuit 1202, a signal held by the capacitor 1208 is input to the gate of the transistor 1210. Thus, after the supply of the power supply voltage to the memory device 1200 is restarted, the signal held by the capacitor 1208 can be converted into the one corresponding to the state (the on/off state) of the transistor 1210 to be read out from the circuit 1202. Consequently, an original signal can be accurately read out even when a potential corresponding to the signal held by the capacitor 1208 varies to some degree.

By using the above-described memory device 1200 as a memory device such as a register or a cache memory included in a processor, data in the memory device can be prevented from being lost when the supply of the power supply voltage is stopped. Furthermore, shortly after the supply of the power supply voltage is restarted, the memory element can be returned to the same state as before the power supply is stopped. Therefore, the power supply can be stopped even for a short time in the processor or one or a plurality of logic circuits included in the processor. Accordingly, power consumption can be suppressed.

Although the memory device 1200 is used in a CPU in this embodiment, the memory device 1200 can also be used in an LSI such as a digital signal processor (DSP), a custom LSI, or a programmable logic device (PLD), and a radio frequency identification (RF-ID).

At least part of this embodiment can be implemented in appropriate combination with any of the other embodiments described in this specification.

### Embodiment 5

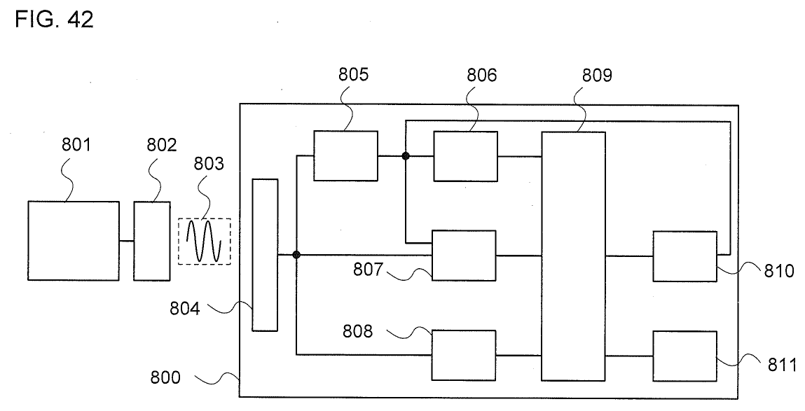

In this embodiment, an RF tag which includes the memory device described in the above embodiment will be described with reference to FIG. 42.

The RF tag of this embodiment includes a memory circuit, stores necessary data in the memory circuit, and transmits and receives data to/from the outside through contactless means, for example, wireless communication. With these features, the RF tag can be used for an individual authentication system in which an object or the like is identified by reading the individual information, for example. Note that the RF tag is required to have extremely high reliability in order to be used for this purpose.

The configuration of the RF tag will be described with reference to FIG. 42. FIG. 42 is a block diagram illustrating a configuration example of the RF tag.

As illustrated in FIG. 42, an RF tag 800 includes an antenna 804 which receives a radio signal 803 that is transmitted from an antenna 802 connected to a communication device 801 (also referred to as an interrogator, a reader/writer, or the like). The RF tag 800 includes a rectifier circuit 805, a constant voltage circuit 806, a demodulation circuit 807, a modulation circuit 808, a logic circuit 809, a memory circuit 810, and a ROM 811. A transistor which is included in the demodulation circuit 807 and has a rectifying function may be formed using a material which enables sufficiently low reverse current, for example, an oxide semiconductor. This can suppress the phenomenon of a rectifying function becoming weaker due to generation of reverse current and prevent saturation of the output from the demodulation circuit. In other words, the input to the demodulation circuit and the output from the demodulation circuit can have a relation closer to a linear relation. Note that data transmission methods are roughly classified into the following three methods: an electromagnetic coupling method in which a pair of coils is provided so as to face each other and communicates by mutual induction, an electromagnetic induction method in which communication is performed using an induction field, and an electric wave method in which communication is performed using an electric wave. Any of these methods can be used in the RF tag 800 described in this embodiment.

Next, the configuration of each circuit will be described. The antenna 804 exchanges the radio signal 803 with the antenna 802 connected to the communication device 801. The rectifier circuit 805 generates an input potential by rectification, for example, half-wave voltage doubler rectification of an input alternating signal generated from a radio signal received by the antenna 804 and smoothing of the rectified signal with a capacitor provided in a later stage. Note that a limiter circuit may be provided on the input side or the output side of the rectifier circuit 805. The limiter circuit controls electric power so that electric power which is higher than or equal to certain electric power is not input to a circuit in a later stage if the amplitude of the input alternating signal and internal generation voltage are high.

The constant voltage circuit 806 generates stable power supply voltage from an input potential and supplies it to each circuit. Note that the constant voltage circuit 806 may include a reset signal generation circuit. The reset signal generation circuit generates a reset signal of the logic circuit 809 by utilizing rise of the stable power supply voltage.

The demodulation circuit 807 demodulates the input alternating signal by envelope detection to generate a demodulated signal. The modulation circuit 808 performs modulation in accordance with data to be output from the antenna 804.

The logic circuit 809 analyzes and processes the demodulated signal. The memory circuit 810 holds input data and includes a row decoder, a column decoder, a memory region, and the like. The ROM 811 stores an identification number (ID) or the like and outputs it in accordance with processing.

Note that whether each circuit described above is provided or not can be determined as appropriate and as needed.

Here, the memory device described in the above embodiment can be used as the memory circuit 810. When the memory device described in the above embodiment is used as the memory circuit 810, data can be held even when power is not supplied; accordingly, the memory circuit can be favorably used for an RF tag. Furthermore, the power (voltage) needed for data writing in the memory device of one embodiment of the present invention is much lower than that needed in a conventional nonvolatile memory; thus, it is possible to prevent a difference between the maximum communication range in data reading and that in data writing. It is also possible to suppress malfunction or incorrect writing which is caused by power shortage in data writing.

Since the memory device of one embodiment of the present invention can be used as a nonvolatile memory, it can also be used as the ROM 811. In this case, it is preferable that a manufacturer separately prepare a command for writing data to the ROM 811 so that a user cannot rewrite data freely. The manufacturer gives identification numbers before shipment of products, instead of putting identification numbers to all the manufactured RF tags; thus, it is possible to put identification numbers only to good products to be shipped. Therefore, the identification numbers of the shipped products are in series and customer management corresponding to the shipped products is easily performed.

At least part of this embodiment can be implemented in appropriate combination with any of the other embodiments described in this specification.

### Embodiment 6

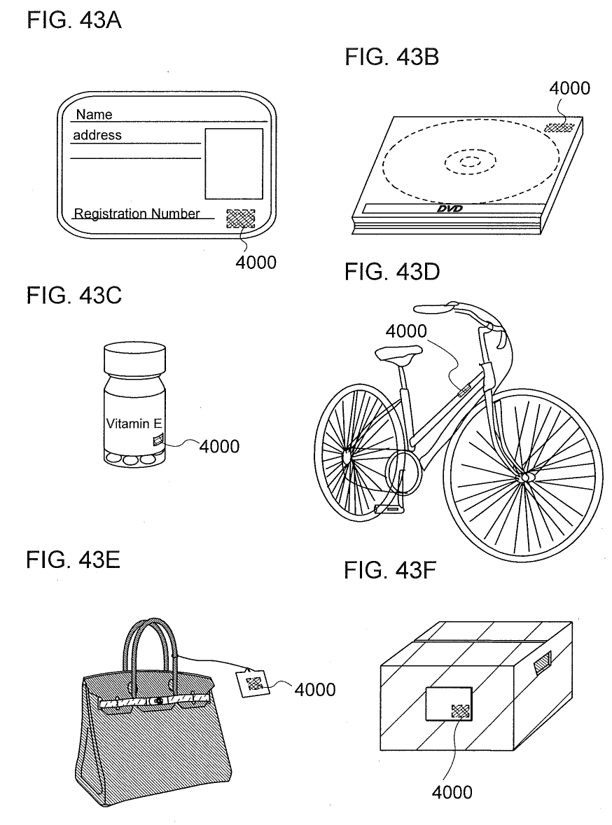

In this embodiment, application examples of the RF tag of one embodiment of the present invention will be described with reference to FIGS. 43A to 43F. The RF tag can be widely used and attached to objects such as bills, coins, securities, bearer bonds, documents (e.g., driver's licenses or resident cards, see FIG. 43A), packaging containers (e.g., wrapping paper or bottles, see FIG. 43C), recording media (e.g., DVD or video tapes, see FIG. 43B), vehicles (e.g., bicycles, see FIG. 43D), personal belongings (e.g., bags or glasses), foods, plants, animals, human bodies, clothing, household goods, medical supplies such as medicine and chemicals, and electronic devices (e.g., liquid crystal display devices, EL display devices, television sets, or mobile phones), tags on objects (see FIGS. 43E and 43F), and the like.

An RF tag 4000 of one embodiment of the present invention is fixed to an object by being attached to a surface thereof or embedded therein. For example, when the object is a book, the RF tag 4000 is embedded in paper; when the object is a package made of an organic resin, the RF tag 4000 is embedded in the organic resin. The RF tag 4000 of one embodiment of the present invention, which can be reduced in size, thickness, and weight, can be fixed to an object without spoiling its design. Furthermore, bills, coins, securities, bearer bonds, documents, or the like provided with the RF tag 4000 of one embodiment of the present invention can have an identification function to prevent counterfeiting. Moreover, the efficiency of a system such as an inspection system can be improved by providing the RF tag of one embodiment of the present invention for packaging containers, recording media, personal belongings, foods, clothing, household goods, electronic devices, or the like. Vehicles provided with the RF tag of one embodiment of the present invention can also have higher security against theft or the like.

As described above, by using the RF tag of one embodiment of the present invention for each application described in this embodiment, power for operation such as writing or reading of data can be reduced, which leads to an increase in maximum communication distance. Moreover, data can be held for an extremely long period even in the state in which power is not supplied; thus, the RF tag can be favorably used for application in which data is not frequently written or read out.

At least part of this embodiment can be implemented in appropriate combination with any of the other embodiments described in this specification.

### Embodiment 7

Examples of an electronic device including the semiconductor device of one embodiment of the present invention are display devices such as televisions and monitors, lighting devices, desktop personal computers, laptop personal computers, word processors, image reproducing devices which reproduce still images and moving images stored in recording media such as digital versatile discs (DVDs), portable CD players, radios, tape recorders, headphone stereos, stereos, table clocks, wall clocks, cordless phone handsets, transceivers, car phones, mobile phones, portable information terminals, tablet terminals, portable game consoles, stationary game machines such as pin-ball machines, calculators, electronic notebooks, e-book readers, electronic translators, audio input devices, video cameras, digital still cameras, electric shavers, high-frequency heating appliances such as microwave ovens, electric rice cookers, electric washing machines, electric vacuum cleaners, water heaters, electric fans, hair dryers, air-conditioning systems such as air conditioners, humidifiers, and dehumidifiers, dishwashers, dish dryers, clothes dryers, futon dryers, electric refrigerators, electric freezers, electric refrigerator-freezers, freezers for preserving DNA, flashlights, electric power tools such as chain saws, smoke detectors, and medical equipment such as dialyzers. Furthermore, industrial equipment such as guide lights, traffic lights, belt conveyors, elevators, escalators, industrial robots, power storage systems, and power storage devices for leveling the amount of power supply and smart grid can be given. In addition, moving objects and the like driven by fuel engines and electric motors using power from power storage units may also be included in the category of the electronic device. Examples of the moving object are electric vehicles (EV), hybrid electric vehicles (HEV) which include both an internal-combustion engine and a motor, plug-in hybrid electric vehicles (PHEV), tracked vehicles in which caterpillar tracks are substituted for wheels of these vehicles, motorized bicycles including motor-assisted bicycles, motorcycles, electric wheelchairs, golf carts, boats, ships, submarines, helicopters, aircrafts, rockets, artificial satellites, space probes, planetary probes, and spacecrafts.

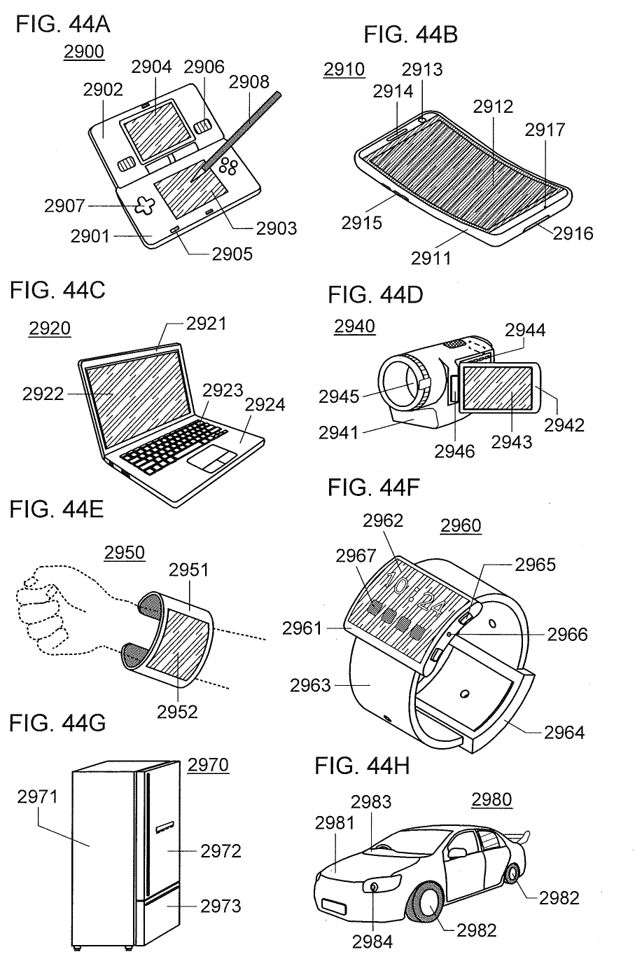

A portable game console 2900 illustrated in FIG. 44A includes a housing 2901, a housing 2902, a display portion 2903, a display portion 2904, a microphone 2905, a speaker 2906, an operation key 2907, and the like. Although the portable game console in FIG. 44A includes the two display portions 2903 and 2904, the number of display portions is not limited to two. The display portion 2903 is provided with a touch screen as an input device, which can be handled with a stylus 2908 or the like.

An information terminal 2910 illustrated in FIG. 44B includes a housing 2911, a display portion 2912, a microphone 2917, a speaker portion 2914, a camera 2913, an external connection portion 2916, an operation button 2915, and the like. A display panel formed using a flexible substrate and a touch screen are provided in the display portion 2912. The information terminal 2910 can be used as, for example, a smartphone, a mobile phone, a tablet information terminal, a tablet personal computer, or an e-book reader.

A laptop personal computer 2920 illustrated in FIG. 44C includes a housing 2921, a display portion 2922, a keyboard 2923, a pointing device 2924, and the like.

A video camera 2940 illustrated in FIG. 44D includes a housing 2941, a housing 2942, a display portion 2943, an operation key 2944, a lens 2945, a joint 2946, and the like. The operation key 2944 and the lens 2945 are provided in the housing 2941, and the display portion 2943 is provided in the housing 2942. The housing 2941 and the housing 2942 are connected to each other with the joint 2946, and the angle between the housing 2941 and the housing 2942 can be changed with the joint 2946. The orientation of an image on the display portion 2943 can be changed and display and non-display of an image can be switched depending on the angle between the housing 2941 and the housing 2942.

FIG. 44E illustrates an example of a bangle-type information terminal. An information terminal 2950 includes a housing 2951, a display portion 2952, and the like. The display portion 2952 is supported by the housing 2951 having a curved surface. A display panel formed using a flexible substrate is provided in the display portion 2952, whereby the information terminal 2950 can be a user-friendly information terminal that is flexible and lightweight.

FIG. 44F illustrates an example of a watch-type information terminal. An information terminal 2960 includes a housing 2961, a display portion 2962, a band 2963, a buckle 2964, an operation button 2965, an input/output terminal 2966, and the like. The information terminal 2960 is capable of executing a variety of applications such as mobile phone calls, e-mails, viewing and editing texts, music reproduction, Internet communication, and computer games.

The display surface of the display portion 2962 is curved, and images can be displayed on the curved display surface. Furthermore, the display portion 2962 includes a touch sensor, and operation can be performed by touching the screen with a finger, a stylus, or the like. For example, by touching an icon 2967 displayed on the display portion 2962, an application can be started. With the operation button 2965, a variety of functions such as time setting, power ON/OFF, ON/OFF of wireless communication, setting and cancellation of silent mode, and setting and cancellation of power saving mode can be performed. For example, the functions of the operation button 2965 can be set by the operating system incorporated in the information terminal 2960.

The information terminal 2960 can employ near field communication that is a communication method based on an existing communication standard. In this case, for example, mutual communication between the information terminal 2960 and a headset capable of wireless communication can be performed, and thus, hands-free calling is possible. Moreover, since the information terminal 2960 includes the input/output terminal 2966, data can be directly transmitted to and received from another information terminal via a connector. Power charging through the input/output terminal 2966 is also possible. Note that the charging operation may be performed by wireless power feeding without using the input/output terminal 2966.

FIG. 44G illustrates an electric refrigerator-freezer as an example of a home electric appliance. An electric refrigerator-freezer 2970 includes a housing 2971, a refrigerator door 2972, a freezer door 2973, and the like.

FIG. 44H is an external view illustrating an example of a motor vehicle. A motor vehicle 2980 includes a car body 2981, wheels 2982, a dashboard 2983, lights 2984, and the like.

The electronic devices described in this embodiment include any of the above-described transistors, semiconductor devices, and the like.

At least part of this embodiment can be implemented in appropriate combination with any of the other embodiments described in this specification. For example, when the electronic device described in this embodiment includes the semiconductor device described in another embodiment, the performance of the electronic device can be improved in some cases. In other cases, the power consumption of the electronic device can be reduced.

(Notes on the description in this specification and the like)

The following are notes on the description of the above embodiments and structures in the embodiments.

### <Notes on One Embodiment of the Present Invention Described in Embodiments>

One embodiment of the present invention can be constituted by appropriately combining the structure described in an embodiment with any of the structures described the other embodiments. In addition, in the case where a plurality of structural examples is described in one embodiment, some of the structural examples can be combined as appropriate.

Note that a content (or part of the content) described in an embodiment can be applied to, combined with, or replaced by a different content (or part of the different content) described in the embodiment and/or a content (or part of the content) described in another embodiment.

In each embodiment, a content described in the embodiment is a content described with reference to a variety of diagrams or a content described with text in the specification.

By combining a diagram (or part thereof) illustrated in one embodiment with another part of the diagram, a different diagram (or part thereof) illustrated in the embodiment, and/or a diagram (or part thereof) illustrated in another embodiment, much more diagrams can be created.

One embodiment of the present invention is not limited to the embodiments described in Embodiments 1 to 7. For example, in Embodiment 1, a structure in which an OS transistor is used as a transistor with low off-state current is described as one embodiment of the present invention; however, a transistor used in one embodiment of the present invention is not limited to an OS transistor as long as it has low off-state current. Accordingly, for example, a structure without an OS transistor may be one embodiment of the present invention under some circumstances.

### <Notes on the Description of Drawings>

In this specification and the like, terms for describing arrangement, such as “over” and “under,” are used for convenience to describe a positional relation between components with reference to drawings. The positional relation between components is changed as appropriate in accordance with the direction in which the components are described. Therefore, terms for describing arrangement are not limited to those used in the specification and can be appropriately reworded depending on the situation.

The term “over” or “under” does not necessarily mean that a component is placed directly above or directly below and directly in contact with another component. For example, the expression “an electrode B over an insulating layer A” does not necessarily mean that the electrode B is above and in direct contact with the insulating layer A and can mean the case where another component is provided between the insulating layer A and the electrode B.

In a block diagram in this specification and the like, components are classified into independent blocks in accordance with their functions. In an actual circuit or the like, however, it may be difficult to separate components in accordance with their functions; thus, one circuit may be associated with a plurality of functions or several circuits may be associated with one function. Therefore, the segmentation of blocks in a block diagram is not limited by components described in the specification and can be differently determined as appropriate depending on the situation.

In the drawings, the size, the layer thickness, or the region is determined arbitrarily for description convenience. Therefore, one embodiment of the present invention is not limited to such a scale. Note that the drawings are schematically illustrated for clarity, and shapes or values are not limited to those illustrated in the drawings. For example, the following can be included: variation in signal, voltage, or current due to noise or difference in timing.

In drawings such as a top view (also referred to as a plan view or a layout view) and a perspective view, some components are not illustrated for clarity of the drawings in some cases.

<Notes on Expressions that can be Rephrased>

In this specification and the like, the expressions “one of a source and a drain” (or a first electrode or a first terminal) and “the other of the source and the drain” (or a second electrode or a second terminal) are used to describe the connection relation of a transistor. This is because a source and a drain of a transistor are interchangeable depending on the structure, operation conditions, or the like of the transistor. Note that the source or the drain of the transistor can also be referred to as a source (or drain) terminal, a source (or drain) electrode, or the like as appropriate depending on the situation.

In this specification and the like, the term such as “electrode” or “wiring” does not limit a function of a component. For example, an “electrode” is used as part of a “wiring” in some cases, and vice versa. Furthermore, the term “electrode” or “wiring” can also mean a combination of a plurality of “electrodes” or “wirings.”

In this specification and the like, “voltage” and “potential” can be replaced with each other as appropriate. The term “voltage” refers to a potential difference from a reference potential. When the reference potential corresponds to ground voltage, for example, the term “voltage” can be replaced with the term “potential.” The ground voltage does not necessarily mean 0 V. Since a potential is a relative value, a potential applied to a wiring or the like is changed depending on the reference potential in some cases.

In this specification and the like, the terms “film” and “layer” can be interchanged with each other depending on the situation or circumstances. For example, in some cases, the term “conductive film” can be used instead of the term “conductive layer,” and the term “insulating layer” can be used instead of the term “insulating film.”

### <Notes on Definitions of Terms>

The following are definitions of the terms mentioned in the above embodiments.

### <<Switch>>

In this specification and the like, a switch is conducting or not conducting (is turned on or off) to determine whether current flows therethrough or not. Alternatively, a switch has a function of selecting and changing a current path.

For example, an electrical switch or a mechanical switch can be used. That is, any element can be used as a switch as long as it can control current, without limitation to a certain element.

Examples of the electrical switch are a transistor (e.g., a bipolar transistor or a MOS transistor), a diode (e.g., a PN diode, a PIN diode, a Schottky diode, a metal-insulator-metal (MIM) diode, a metal-insulator-semiconductor (MIS) diode, or a diode-connected transistor), and a logic circuit in which such elements are combined.

In the case of using a transistor as a switch, the “on state” of the transistor refers to a state in which a source and a drain of the transistor are electrically short-circuited. The “off state” of the transistor refers to a state in which the source and the drain of the transistor are electrically disconnected. In the case where a transistor operates just as a switch, the polarity (conductivity type) of the transistor is not particularly limited to a certain type.

An example of the mechanical switch is a switch formed using a micro electro mechanical system (MEMS) technology, such as a digital micromirror device (DMD). Such a switch includes a mechanically movable electrode whose movement controls conduction and non-conduction of the switch.

### <<Channel Length>>

The channel length in this specification and the like refers to, for example, in a top view of a transistor, the distance between a source and a drain in a region in which a semiconductor (or a portion of the semiconductor in which current flows when the transistor is in the on state) and a gate electrode overlap with each other or in a region in which a channel is formed.

The channel length of a transistor is not necessarily constant in all regions. In other words, the channel length of a transistor is not limited to one value in some cases. Therefore, in this specification, the channel length is any one value, the maximum value, the minimum value, or the average value in a region in which a channel is formed.

### <<Channel Width>>

The channel width in this specification and the like refers to, for example, the length of a portion where a source and a drain face each other in a region in which a semiconductor (or a portion of the semiconductor in which current flows when a transistor is in the on state) and a gate electrode overlap with each other or in a region in which a channel is formed.

The channel width of a transistor is not necessarily constant in all regions. In other words, the channel width of a transistor is not limited to one value in some cases. Therefore, in this specification, the channel width is any one value, the maximum value, the minimum value, or the average value in a region in which a channel is formed.

Depending on the transistor structure, the channel width in a region in which a channel is actually formed (hereinafter referred to as an effective channel width) is different from the channel width shown in a top view of the transistor (hereinafter referred to as an apparent channel width) in some cases. For example, in a transistor with a three-dimensional structure, the effective channel width is larger than the apparent channel width shown in a top view of the transistor, and an influence of the effective channel width cannot be ignored in some cases. For example, in a miniaturized transistor with a three-dimensional structure, the proportion of a channel region formed on a side surface of a semiconductor is high in some cases. In this case, the effective channel width, that is, the width of an actually formed channel is larger than the apparent channel width shown in a top view.

In some cases, the effective channel width of a transistor with a three-dimensional structure is difficult to estimate on the basis of measurement. For example, estimation of the effective channel width from a design value requires an assumption that the shape of a semiconductor is known. Therefore, in the case where the shape of the semiconductor is uncertain, it is difficult to measure the effective channel width accurately.

Therefore, in this specification, in a top view of a transistor, an apparent channel width that is the length of a portion where a source and a drain face each other in a region in which a semiconductor and a gate electrode overlap with each other may be referred to as a surrounded channel width (SCW). In this specification, the simple term “channel width” may denote the surrounded channel width or the apparent channel width. Alternatively, in this specification, the simple term “channel width” may denote the effective channel width. Note that the values of the channel length, the channel width, the effective channel width, the apparent channel width, the surrounded channel width, and the like can be determined by obtaining and analyzing a cross-sectional TEM image or the like.

Note that the surrounded channel width may be used to calculate the field-effect mobility, the current value per channel width, and the like of a transistor. In this case, the values may be different from those calculated using the effective channel width.

### <<Connection>>

In this specification and the like, the expression “A and B are connected” means the case where A and B are electrically connected to each other in addition to the case where A and B are directly connected to each other. Here, the expression “A and B are electrically connected” indicates that electric signals can be transmitted and received between A and B when an object having any electrical function exists between A and B.

For example, any of the following expressions can be used for the case where a source (or a first terminal or the like) of a transistor is electrically connected to X through (or not through) Z1 and a drain (or a second terminal or the like) of the transistor is electrically connected to Y through (or not through) Z2, or the case where a source (or a first terminal or the like) of a transistor is directly connected to one part of Z1 and another part of Z1 is directly connected to X while a drain (or a second terminal or the like) of the transistor is directly connected to one part of Z2 and another part of Z2 is directly connected to Y.

Examples of the expression include “X, Y, a source (or a first terminal or the like) of a transistor, and a drain (or a second terminal or the like) of the transistor are electrically connected to each other, and X, the source (or the first terminal or the like) of the transistor, the drain (or the second terminal or the like) of the transistor, and Y are electrically connected in this order,” “a source (or a first terminal or the like) of a transistor is electrically connected to X, a drain (or a second terminal or the like) of the transistor is electrically connected to Y, and X, the source (or the first terminal or the like) of the transistor, the drain (or the second terminal or the like) of the transistor, and Y are electrically connected in this order,” and “X is electrically connected to Y through a source (or a first terminal or the like) and a drain (or a second terminal or the like) of a transistor, and X, the source (or the first terminal or the like) of the transistor, the drain (or the second terminal or the like) of the transistor, and Y are provided to be connected in this order.” When the connection order in a circuit configuration is defined by an expression similar to these examples, a source (or a first terminal or the like) and a drain (or a second terminal or the like) of a transistor can be distinguished from each other to specify the technical scope.

Other examples of the expression include “a source (or a first terminal or the like) of a transistor is electrically connected to X through at least a first connection path, the first connection path does not include a second connection path, the second connection path is a path between the source (or the first terminal or the like) of the transistor and a drain (or a second terminal or the like) of the transistor, Z1 is on the first connection path, the drain (or the second terminal or the like) of the transistor is electrically connected to Y through at least a third connection path, the third connection path does not include the second connection path, and Z2 is on the third connection path” and “a source (or a first terminal or the like) of a transistor is electrically connected to Xthrough at least Z1 on a first connection path, the first connection path does not include a second connection path, the second connection path includes a connection path on which the transistor is provided, a drain (or a second terminal or the like) of the transistor is electrically connected to Y at least through Z2 on a third connection path, and the third connection path does not include the second connection path.” Still another example of the expression is “a source (or a first terminal or the like) of a transistor is electrically connected to X through at least Z1 on a first electrical path, the first electrical path does not include a second electrical path, the second electrical path is an electrical path from the source (or the first terminal or the like) of the transistor to a drain (or a second terminal or the like) of the transistor, the drain (or the second terminal or the like) of the transistor is electrically connected to Y through at least Z2 on a third electrical path, the third electrical path does not include a fourth electrical path, and the fourth electrical path is an electrical path from the drain (or the second terminal or the like) of the transistor to the source (or the first terminal or the like) of the transistor.” When the connection path in a circuit configuration is defined by an expression similar to these examples, a source (or a first terminal or the like) and a drain (or a second terminal or the like) of a transistor can be distinguished from each other to specify the technical scope.

Note that one embodiment of the present invention is not limited to these expressions which are just examples. Here, X, Y, Z1, and Z2 each denote an object (e.g., a device, an element, a circuit, a wiring, an electrode, a terminal, a conductive layer, or a layer).

### REFERENCE NUMERALS

11: region, 15: region, 16: region, 17: region, 18: region, 19: region, 20: region, 21: perpendicular line, 22: perpendicular line, 23: perpendicular line, 100: layer, 101: insulator, 102: conductor, 103: insulator, 104: insulator, 106a: oxide, 106b: oxide, 106c: oxide, 107a: low-resistance region, 107b: low-resistance region, 108a: conductor, 108b: conductor, 109a: conductor, 109b: conductor, 112: insulator, 114: conductor, 116: insulator, 118: insulator, 119: dopant, 122: hydrogen, 126a: region, 126b: region, 126c: region, 150: capacitor, 220: well, 221: p-type semiconductor, 223: n-type semiconductor, 224: opening, 225: opening, 260: circuit, 270: circuit, 273: electrode, 280: circuit, 290: circuit, 382: Ec, 383a: Ec, 383b: Ec, 383c: Ec, 386: Ec, 390: trap state, 400: substrate, 401: substrate, 402: insulator, 404: conductor, 406: oxide, 406a: oxide, 406b: oxide, 406c: oxide, 407: channel formation region, 408: insulator, 412: insulator, 413: conductor, 413a: conductor, 413b: conductor, 413c: conductor, 413d: conductor, 416a: conductor, 416b: conductor, 418: insulating film, 421: conductor, 422: conductor, 429: conductor, 442: insulator, 454: conductor, 460: element isolation region, 462: insulator, 464: insulator, 464a: insulator, 464b: insulator, 470: insulating film, 474: region, 476: region, 477: partition wall, 487: wiring, 488: conductor, 489: plug, 490: transistor, 491: transistor, 491b: insulator, 492: transistor, 500: semiconductor device, 511: conductor, 513: conductor, 514: conductor, 516: conductor, 517: conductor, 521: routing switch element, 522: logic element, 523: configuration memory, 524: lookup table, 525: register, 526: selector, 527: configuration memory, 541: plug, 541b: plug, 543: plug, 544: plug, 544b: plug, 545: plug, 571: insulator, 571a: insulator, 572: insulator, 581: insulator, 581a: insulator, 581b: insulator, 584: insulator, 585: insulator, 591: insulator, 591b: insulator, 592: insulator, 593: insulator, 600: imaging device, 601: photoelectric conversion element, 602: transistor, 603: transistor, 604: transistor, 605: transistor, 606: capacitor, 606a: semiconductor, 606b: semiconductor, 606c: semiconductor, 607: node, 608: wiring, 609: wiring, 610: pixel driver circuit, 611: wiring, 612: insulator, 613: conductor, 614: conductive layer, 616a: conductive layer, 616b: conductive layer, 618: insulating film, 619: insulating film, 621: pixel portion, 622: pixel, 622B: pixel, 622G: pixel, 622R: pixel, 623: pixel, 624: filter, 624B: filter, 624G: filter, 624R: filter, 625: layer, 626: wiring group, 635: lens, 660: light, 660a: capacitor, 660b: capacitor, 661a: transistor, 661b: transistor, 662a: transistor, 662b: transistor, 663a: inverter, 663b: inverter, 681: photoelectric conversion layer, 682: light-transmitting conductive layer, 686: conductor, 700: substrate, 701: insulator, 702a: conductor, 702b: conductor, 704: insulator, 706a: insulator, 706b: semiconductor, 706c: insulator, 707a: region, 707b: region, 711: insulator, 712: insulator, 714a: conductor, 714b: conductor, 716: insulator, 719: light-emitting element, 720: insulator, 721: insulator, 731: terminal, 732: FPC, 733a: wiring, 734: sealant, 735: driver circuit, 736: driver circuit, 737: pixel, 741: transistor, 742: capacitor, 743: switching element, 744: signal line, 750: substrate, 751: transistor, 752: capacitor, 753: liquid crystal element, 754: scan line, 755: signal line, 781: conductor, 782: light-emitting layer, 783: conductor, 784: partition wall, 791: conductor, 792: insulator, 793: liquid crystal layer, 794: insulator, 795: spacer, 796: conductor, 797: substrate, 800: RF tag, 801: communication device, 802: antenna, 803: radio signal, 804: antenna, 805: rectifier circuit, 806: constant voltage circuit, 807: demodulation circuit, 808: modulation circuit, 809: logic circuit, 810: memory circuit, 811: ROM, 1189: ROM interface, 1190: substrate, 1191: ALU, 1192: ALU controller, 1193: instruction decoder, 1194: interrupt controller, 1195: timing controller, 1196: register, 1197: register controller, 1198: bus interface, 1199: rewritable ROM, 1200: memory device, 1201: circuit, 1202: circuit, 1203: switch, 1204: switch, 1206: logic element, 1207: capacitor, 1208: capacitor, 1209: transistor, 1210: transistor, 1213: transistor, 1214: transistor, 1220: circuit, 2100: transistor, 2200: transistor, 2900: portable game console, 2901: housing, 2902: housing, 2903: display portion, 2904: display portion, 2905: microphone, 2906: speaker, 2907: operation key, 2908: stylus, 2910: information terminal, 2911: housing, 2912: display portion, 2913: camera, 2914: speaker portion, 2915: button, 2916: external connection portion, 2917: microphone, 2920: laptop personal computer, 2921: housing, 2922: display portion, 2923: keyboard, 2924: pointing device, 2940: video camera, 2941: housing, 2942: housing, 2943: display portion, 2944: operation key, 2945: lens, 2946: joint, 2950: information terminal, 2951: housing, 2952: display portion, 2960: information terminal, 2961: housing, 2962: display portion, 2963: band, 2964: buckle, 2965: operation button, 2966: input/output terminal, 2967: icon, 2970: electric refrigerator-freezer, 2971: housing, 2972: refrigerator door, 2973: freezer door, 2980: motor vehicle, 2981: car body, 2982: wheel, 2983: dashboard, 2984: light, 4000: RF tag, 5100: pellet, 5120: substrate, 5161: region

This application is based on Japanese Patent Application serial No. 2015-066660 filed with Japan Patent Office on Mar. 27, 2015, the entire contents of which are hereby incorporated by reference.

1. A transistor comprising a first oxide film,
wherein the first oxide film comprises indium, an element M, and zinc,
wherein the first oxide film comprises a region in which an atomic ratio of indium to the element M and zinc satisfies indium:element M:zinc=x_{b}:y_{b}:z_{b},
wherein x_{b}:y_{b}:z_{b} satisfies one of the following equations (1) to (5):
x_{b}:y_{b}:z_{b}=(1−α₁):(1+α₁):m₁ (1);
x_{b}:y_{b}:z_{b}=(1−α₂):(1+α₂):2m₂ (2);
x_{b}:y_{b}:z_{b}=(1−α₃):(1+α₃):3m₃ (3);
x_{b}:y_{b}:z_{b}=(1−α₄):(1+α₄):4m₄ (4); and
x_{b}:y_{b}:z_{b}=(1−α₅):(1+α₅):5mₙ (5), and
wherein, in the equations (1) to (5), ac is greater than or equal to −0.43 and less than or equal to 0.18, α₂ is greater than or equal to −0.78 and less than or equal to 0.42, α₃ is greater than or equal to −1 and less than or equal to 0.56, α₄ is greater than or equal to −1 and less than or equal to 0.64, α₅ is greater than or equal to −1 and less than or equal to 0.82, and m₁ to m₅ are each greater than 0.7 and less than or equal to 1.

2. A transistor comprising a first oxide film,
wherein the first oxide film comprises indium, an element M, and zinc,
wherein the first oxide film comprises a region in which an atomic ratio of indium to the element M and zinc satisfies indium:element M:zinc=x_{b}:y_{b}:z_{b}, and
wherein x_{b} is 4, y_{b} is greater than or equal to 1.8 and less than or equal to 2.2, and z_{b} is greater than 2.1 and less than or equal to 3.

3. A transistor comprising a first oxide film,
wherein the first oxide film comprises indium, an element M, and zinc,
wherein the first oxide film comprises a region in which an atomic ratio of indium to the element M and zinc satisfies indium:element M:zinc=x_{b}:y_{b}:z_{b}, and
wherein x_{b} is 5, y_{b} is greater than or equal to 0.9 and less than or equal to 1.1, and z_{b} is greater than 4.2 and less than or equal to 6.

4. A transistor comprising a first oxide film,
wherein the first oxide film comprises a first region and a second region,
wherein the first region has c-axis alignment,
wherein the c-axis is parallel to a normal vector of a top surface or a formation surface of the first oxide film,
wherein the second region does not have the c-axis alignment,
wherein the second region comprises indium, an element M, and zinc,
wherein the second region comprises a region in which an atomic ratio of indium to the element M and zinc satisfies indium:element M:zinc=x_{b}:y_{b}:z_{b},
wherein x_{b}:y_{b}:z_{b} satisfies one of the following equations (6) to (10):
x_{b}:y_{b}:z_{b}=(1−α₁):(1+α₁):m₁ (6);
x_{b}:y_{b}:z_{b}=(1−α₂):(1+α₂):2m₂ (7);
x_{b}:y_{b}:z_{b}=(1−α₃):(1+α₃):3m₃ (8);
x_{b}:y_{b}:z_{b}=(1−α₄):(1+α₄):4m₄ (9); and
x_{b}:y_{b}:z_{b}=(1−α₅):(1+α₅):5m₅ (10), and
wherein, in the equations (6) to (10), α₁ is greater than or equal to −0.43 and less than or equal to 0.18, α₂ is greater than or equal to −0.78 and less than or equal to 0.42, α₃ is greater than or equal to −1 and less than or equal to 0.56, α₄ is greater than or equal to −1 and less than or equal to 0.64, α₅ is greater than or equal to −1 and less than or equal to 0.82, and m₁ to m₅ are each greater than 0.7 and less than or equal to 1.

5. A transistor comprising a first oxide film,
wherein the first oxide film comprises a first region and a second region,
wherein the first region has c-axis alignment,
wherein the c-axis is parallel to a normal vector of a top surface or a formation surface or the first oxide film,
wherein the second region does not have the c-axis alignment,
wherein the second region comprises indium, an element M, and zinc,
wherein the second region comprises a region in which an atomic ratio of indium to the element M and zinc satisfies indium:element M:zinc=x_{b}:y_{b}:z_{b}, and
wherein x_{b} is 4, y_{b} is greater than or equal to 1.8 and less than or equal to 2.2, and z_{b} is greater than 2.1 and less than or equal to 3.

6. A transistor comprising a first oxide film,
wherein the first oxide film comprises a first region and a second region,
wherein the first region has c-axis alignment,
wherein the second region does not have the c-axis alignment,
wherein the second region comprises indium, an element M, and zinc,
wherein the second region comprises a region in which an atomic ratio of indium to the element M and zinc satisfies indium:element M:zinc=x_{b}:y_{b}:z_{b}, and
wherein x_{b} is 5, y_{b} is greater than or equal to 0.9 and less than or equal to 1.1, and z_{b} is greater than 4.2 and less than or equal to 6.

7. A transistor comprising a first oxide film,
wherein the first oxide film is deposited by a sputtering method,
wherein a target used in the sputtering method comprises indium, an element M, and zinc,
wherein the target comprises a region in which an atomic ratio of indium to the element M and zinc satisfies indium:element M:zinc=x_{b}:y_{b}:z_{b}, and
wherein x_{b} is 5, y_{b} is greater than or equal to 0.9 and less than or equal to 1.1, and z_{b} is greater than 6.3 and less than or equal to 7.7.

8. The transistor according to any one of claims 1 to 7,
wherein the transistor comprises a second oxide film,
wherein the second oxide film comprises a region in contact with the top surface of the first oxide film,
wherein the second oxide film comprises indium, the element M, and zinc,
wherein the second oxide film comprises a region in which an atomic ratio of indium to the element M and zinc satisfies indium:element M:zinc=xₑ:y_{c}:z_{c}, and
wherein x_{c} is 1, y_{c} is greater than or equal to 2.7 and less than or equal to 3.3, and z is greater than or equal to 1 and less than or equal to 3.

9. The transistor according to claim 8,
wherein the transistor comprises a third oxide film,
wherein the third oxide film comprises a region in contact with a bottom surface of the first oxide film,
wherein the third oxide film comprises indium, the element M, and zinc,
wherein the third oxide film comprises a region in which an atomic ratio of indium to the element M and zinc satisfies indium:element M:zinc=xₐ:yₐ:zₐ, and
wherein xₐ is 1, yₐ is greater than or equal to 2.7 and less than or equal to 3.3, and zₐ is greater than or equal to 1 and less than or equal to 3.

10. The transistor according to any one of claims 1 to 7, wherein the element M is at least one element selected from gallium, aluminum, yttrium, and tin.

11. The transistor according to any one of claims 1 to 7, wherein the element M is gallium.

12. An electronic device comprising the transistor according to any one of claims 1 to 7.
